(19) United States
(12) Patent Application Publication
(10) Pub. No.: US 2025/0256353 A1
(43) Pub. Date: Aug. 14, 2025

(54) LASER PROCESSING APPARATUS, LASER PROCESSING METHOD, LASER PROCESSING PROGRAM, RECORDING MEDIUM, SEMICONDUCTOR CHIP MANUFACTURING METHOD AND SEMICONDUCTOR CHIP

(71) Applicant: YAMAHA HATSUDOKI KABUSHIKI KAISHA, Iwata-shi, Shizuoka (JP)

(72) Inventor: Yoshikuni SUZUKI, Iwata-shi, Shizuoka (JP)

(73) Assignee: YAMAHA HATSUDOKI KABUSHIKI KAISHA, Iwata-shi, Shizuoka (JP)

(21) Appl. No.: 18/857,426

(22) PCT Filed: Apr. 18, 2022
(86) PCT No.: PCT/JP2022/018064

§ 371 Date: Oct. 16, 2024

(51) Int. Cl. B23K 26/08

(52) U.S. Cl. CPC B23K 26/0876

(57) ABSTRACT

The image of the part of the semiconductor substrate overlapping the imaging range is obtained by imaging the imaging range relatively moving with respect to the semiconductor substrate during the execution of the line processing of processing the planned dividing line by irradiating the laser beam to the laser irradiation position while moving the laser irradiation position along the planned dividing line. That is, the execution period of the line processing is effectively utilized to image the semiconductor substrate. In this way, the semiconductor substrate can be efficiently imaged in the laser processing technique for processing the planned dividing line by irradiating the laser beam to the planned dividing line.

### CROSS-REFERENCE TO RELATED APPLICATION

This application is a National Stage of International Patent Application No. PCT/JP2022/018064, filed Apr. 18, 2022, the entire contents of which is incorporated herein by reference.

### BACKGROUND

### Technical Field

This disclosure relates to a technique for processing a processing line by irradiating a laser beam to the processing line provided on a processing object.

### Background Art

A Publication of Japanese Patent No. 5804716, a Publication of Japanese Patent No. 5554593 and a Publication of Japanese Patent No. 5037082 describe a laser processing technique for processing a planned dividing line by relatively moving a laser beam with respect to a semiconductor substrate while irradiating the laser beam to the planned dividing line provided on the semiconductor substrate. For example, as shown in Publication of Japanese Patent No. 5804716, a plurality of planned dividing lines are processed in turn by reciprocating a laser beam while changing the planned dividing line, to which the laser beam is irradiated, on forward and return paths in this laser processing technique. At this time, the laser beam can be precisely irradiated to the planned dividing line by adjusting the position of the laser beam according to a result of an alignment processing of recognizing the position of the planned dividing line based on an image obtained by imaging a predetermined part of the semiconductor substrate as described, for example, in the Publication of Japanese Patent No. 5554593. Further, as pointed out in the Publication of Japanese Patent No. 5037082, a width of the planned dividing line may be expanded by processing the planned dividing line by the laser beam and the position of the unprocessed planned dividing line may be shifted in a feeding direction orthogonal to a processing direction. To deal with such a position shift of the planned dividing line, it is appropriate to image the semiconductor substrate as appropriate.

### SUMMARY

In the laser processing technique as described above, it is required to efficiently image a processing object (semiconductor substrate) to recognize an influence of processing by the irradiation of a laser beam on a processing line (planned dividing line).

This disclosure was developed in view of the above problem and aims to provide a technique for enabling a processing object to be efficiently imaged in a laser processing technique for processing a processing line by irradiating a laser beam to the processing line.

A laser processing apparatus according to the disclosure, comprises a supporting member supporting a processing object having a plurality of processing lines parallel to each other such that the processing lines are parallel to a predetermined processing direction; a processing head irradiating a laser beam to a predetermined laser irradiation position; and a processing-axis driver relatively moving the laser irradiation position in the processing direction with respect to the processing object by driving at least one of the supporting member and the processing head in the processing direction. The laser processing apparatus also comprises a control unit performing a line processing of processing the processing line by irradiating the laser beam to the laser irradiation position by the processing head while moving the laser irradiation position along the processing line by the processing-axis driver; and an imaging part imaging a predetermined imaging range relatively moving with respect to the processing object integrally with the laser irradiation position as the laser irradiation position relatively moves with respect to the processing object, the imaging part obtaining an image of a part of the processing object overlapping the imaging range by imaging the imaging range relatively moving with respect to the processing object during execution of the line processing.

A laser processing method according to the disclosure, comprises supporting a processing object having a plurality of processing lines parallel to each other by a supporting member such that the processing lines are parallel to a predetermined processing direction; and performing a line processing of processing the processing line by irradiating a laser beam to a laser irradiation position by a processing head for irradiating the laser beam to a predetermined laser irradiation position while moving the laser irradiation position along the processing line by a processing-axis driver for relatively moving the laser irradiation position in the processing direction with respect to the processing object by driving at least one of the processing head and the supporting member in the processing direction. The laser processing method further comprises obtaining an image of a part of the processing object overlapping an imaging range by an imaging part imaging the imaging range relatively moving with respect to the processing object during execution of the line processing, the imaging part imaging a predetermined imaging range relatively moving with respect to the processing object integrally with the laser irradiation position as the laser irradiation position relatively moves with respect to the processing object.

In the disclosure (laser processing apparatus and laser processing method) thus configured, the image of the part of the processing object overlapping the imaging range is obtained by imaging the imaging range relatively moving with respect to the processing object during the execution of the line processing of processing the processing line by irradiating the laser beam to the laser irradiation position while moving the laser irradiation position along the processing line. That is, an execution period of the line processing is effectively utilized to image the processing object. In this way, the processing object can be efficiently imaged in a laser processing technique for processing the processing line by irradiating the laser beam to the processing line.

The laser processing apparatus may be configured so that the imaging part images the imaging range provided on a downstream side in a moving direction of the laser irradiation position with respect to the processing line in the line processing. In such a configuration, the image of an unprocessed side of the position being processed by the laser beam (i.e. the laser irradiation position) can be obtained. Therefore, an influence of the processing by the laser beam on the unprocessed part of the processing object can be recognized based on this image.

The laser processing apparatus may be configured so that the imaging part images the imaging range a plurality of times during a period of performing the line processing once. In such a configuration, a plurality of images of the processing object can be obtained by effectively utilizing the execution period of the line processing.

The laser processing apparatus may further comprises a feeding-axis driver relatively moving the laser irradiation position in a feeding direction orthogonal to the processing direction with respect to the processing object by driving at least one of the supporting member and the processing head in the feeding direction. The processing line to be line processed, out of the plurality of processing lines, is changed by the feeding-axis driver moving the laser irradiation position in the feeding direction with respect to the processing object. The control unit performs in turn a first line processing of processing a first processing line, out of the plurality of processing lines, by the line processing of moving the laser irradiation position toward a first side in the processing direction and a second line processing of processing a second processing line different from the first processing line, out of the plurality of processing lines, by the line processing of moving the laser irradiation position toward a second side opposite to the first side in the processing direction. The processing-axis driver performs reverse drive for bringing the laser irradiation position to the second processing line by accelerating the laser irradiation position toward the second side after decelerating and stopping the laser irradiation position, which has passed through the first processing line toward the first side, toward the first side in the processing direction and the feeding-axis driver performs continuous feed drive for continuously moving the laser irradiation position in the feeding direction from a first virtual straight line extended in the processing direction to outside of the first processing line along the first processing line to a second virtual straight line extended in the processing direction to outside of the second processing line along the second processing line in a switching period from end of the first line processing to start of the second line processing. Also, the control unit causes the feeding-axis driver to move the laser irradiation position in the feeding direction throughout the before and after the time at which a movement of the laser irradiation position in the processing direction is stopped due to the reverse drive by controlling the processing-axis driver and the feeding-axis driver such that the feeding-axis driver starts the continuous feed drive before the processing-axis driver stops the laser irradiation position by the reverse drive and the feeding-axis driver finishes the continuous feed drive after the processing-axis driver stops the laser irradiation position by the reverse drive.

In such a configuration, the first line processing of processing the first processing line and the second line processing of processing the second processing line are performed, using the processing-axis driver for relatively moving the laser irradiation position in the processing direction with respect to the processing object and the feeding-axis driver for relatively moving the laser irradiation position in the feeding direction with respect to the processing object. Further, the processing-axis driver and the feeding-axis driver perform the following operation to move the laser irradiation position having passed through the first processing line toward the second processing line in the switching period between the first line processing and the second line processing. That is, the processing-axis driver performs the reverse drive for bringing the laser irradiation position to the second processing line by accelerating the laser irradiation position toward the second side after decelerating and stopping the laser irradiation position, which has passed through the first processing line toward the first side, toward the first side in the processing direction. Further, the feeding-axis driver moves the laser irradiation position in the feeding direction from the first virtual straight line extended in the processing direction to the outside of the first processing line along the first processing line to the second virtual straight line extended in the processing direction to the outside of the second processing line along the second processing line.

Particularly, the feeding-axis driver performs the continuous feed drive for continuously moving the laser irradiation position in the feeding direction from the first virtual straight line to the second virtual straight line. The control unit causes the feeding-axis driver to move the laser irradiation position in the feeding direction throughout the before and after the time at which a movement of the laser irradiation position in the processing direction is stopped due to the reverse drive by controlling the processing-axis driver and the feeding-axis driver such that the feeding-axis driver starts the continuous feed drive before the processing-axis driver stops the laser irradiation position by the reverse drive and the feeding-axis driver finishes the continuous feed drive after the processing-axis driver stops the laser irradiation position by the reverse drive. That is, in the switching period, both a period of decelerating the laser processing toward the first side in the processing direction and a period of accelerating the laser irradiation position toward the second side in the processing direction are effectively utilized to move the laser irradiation position in the feeding direction. As a result, it is possible to suppress an influence of the switching period of switching a moving direction of the laser beam on a time required to complete the processing of the processing object. Moreover, since the execution period of the line processing is effectively utilized to image the processing object as described above, it is possible to suppress a time required to switch the processing line to be line processed, efficiently image the processing object and quickly complete the processing of the processing object.

The laser processing apparatus may be configured so that the imaging part images the imaging range including at least the processing line during the execution of the line processing. A part equivalent to the processing line appears to extend in the processing direction due to contrast between both sides of the processing line and the processing line in the feeding direction in the image obtained by such imaging. Therefore, an influence of the laser processing on the position in the feeding direction of the processing line can be precisely recognized based on the position in the feeding direction of this part.

The laser processing apparatus may be configured so that a center of the imaging range of the imaging part and a focus of the laser beam to be irradiated to the laser irradiation position are arranged in the processing direction. In such a configuration, a state immediately before the laser beam is irradiated can be precisely grasped by the image of the imaging range.

The laser processing apparatus may be configured so that the imaging part obtains the image by whole period imaging for causing a camera to continue exposure through a crossing period during which an unprocessed part not processed with irradiation of the laser beam in one target line crosses the imaging range during the execution of the line processing for the one target line, out of the plurality of processing lines. In such a configuration, information obtained by accumulating a luminance of the image of the imaging range in the processing direction can be obtained.

The laser processing apparatus may be configured so that an exposure time Tc and an illumination intensity Lc in the whole period imaging satisfy the following relational expression for an exposure time TO and an illumination intensity L0 when the camera images the processing object stationary with respect to the camera:

Lc=T0×L0/Tc.

In such a configuration, the luminance saturation of the image can be suppressed.

The laser processing apparatus may be configured so that the control unit determines whether or not the laser irradiation position for the processing line is proper based on the image obtained by the whole period imaging. In such a configuration, whether or not the laser irradiation position is proper can be confirmed.

The laser processing apparatus may be configured so that the control unit determines whether or not the laser irradiation position for the processing line is proper based on a central part of the image except both end parts in an orthogonal direction orthogonal to the processing direction. In such a configuration, whether or not the laser irradiation position is proper can be confirmed with unnecessary information appearing in the both end parts in the orthogonal direction of the image excluded.

The laser processing apparatus may be configured so that the control unit obtains a position deviation amount in the orthogonal direction of the laser irradiation position from the one target line and corrects the laser irradiation position in the orthogonal direction based on the position deviation amount when the line processing is performed after the one target line if an occurrence of a position deviation of the laser irradiation position from the one target line in an orthogonal direction orthogonal to the processing direction is confirmed based on the image. In such a configuration, the line processing can be properly performed by correcting the position deviation of the laser irradiation position.

The laser processing apparatus may be configured so that the control unit performs an alignment of correcting the inclination if inclination of a trace of the laser irradiation position with respect to the one target line is confirmed based on the image. In such a configuration, the line processing can be properly performed by correcting the inclination of the laser irradiation position with respect to the processing line.

A semiconductor chip manufacturing method according to the disclosure, comprises processing a semiconductor substrate, having a plurality of semiconductor chips demarcated by processing lines and arrayed, by the laser processing method described above; and separating each of the plurality of semiconductor chips by expanding a tape, holding the semiconductor substrate by an adhesive force, processed by the laser processing method.

A semiconductor chip, according to the disclosure is manufactured by: processing a semiconductor substrate, having a plurality of semiconductor chips demarcated by processing lines and arrayed, by the laser processing method described above; and separating each of the plurality of semiconductor chips by expanding a tape, holding the semiconductor substrate by an adhesive force, processed by the laser processing method.

A laser processing program according to the disclosure causes a computer to carry out the laser processing method described above.

A recording medium according to the disclosure computer-readably stores the laser processing program described above.

According to the disclosure, a processing object can be efficiently imaged in a laser processing technique for processing a processing line by irradiating a laser beam to the processing line.

### BRIEF DESCRIPTION OF THE DRAWINGS

FIG. 1 is a front view schematically showing an example of a laser processing apparatus according to the disclosure;

FIG. 2 is a plan view schematically showing the laser processing apparatus of FIG. 1;

FIG. 3 is a block diagram showing the electrical configuration of the laser processing apparatus of FIG. 1;

FIG. 4 is a flow chart showing an example of a method for producing a laser processed substrate, for which the laser processing has been already performed;

FIG. 5 is a flow chart showing an example of the take-out of the ring frame;

FIG. 6 is a flow chart showing an example of the transfer of the ring frame;

FIG. 7A is a plan view schematically showing an example of an operation performed in accordance with the flow charts of FIGS. 5 and 6;

FIG. 7B is a plan view schematically showing an example of an operation performed in accordance with the flow charts of FIGS. 5 and 6;

FIG. 7C is a plan view schematically showing an example of an operation performed in accordance with the flow charts of FIGS. 5 and 6;

FIG. 7D is a plan view schematically showing an example of an operation performed in accordance with the flow charts of FIGS. 5 and 6;

FIG. 7E is a plan view schematically showing an example of an operation performed in accordance with the flow charts of FIGS. 5 and 6;

FIG. 8 is a flow chart showing an example of the storage of the ring frame;

FIG. 9 is flow chart showing an example of the ring frame alignment;

FIG. 10 is plan views schematically showing an example of an operation performed in the ring frame alignment;

FIG. 11 is flow chart showing an example of the substrate processing;

FIG. 12 is plan view schematically showing an example of an operation performed in accordance with the flow chart of FIG. 11;

FIG. 13A is flow chart showing an example of the calibration;

FIG. 13B is flow chart showing an example of stage plane specification performed in the calibration of FIG. 13A;

FIG. 13C is flow chart showing an example of substrate plane specification performed in the calibration of FIG. 13A;

FIG. 14 is a flow chart showing a basic process of the line processing for each planned dividing line;

FIG. 15A is chart schematically showing a first example of an operation performed in accordance with the flow chart of FIG. 14;

FIG. 15B is a chart schematically showing a second example of the operation performed in accordance with the flow chart of FIG. 14;

FIG. 15C is a chart schematically showing a third example of the operation performed in accordance with the flow chart of FIG. 14;

FIG. 15D is a chart schematically showing a fourth example of the operation performed in accordance with the flow chart of FIG. 14;

FIG. 15E is a chart schematically showing a fifth example of the operation performed in accordance with the flow chart of FIG. 14;

FIG. 15F is a chart schematically showing a sixth example of the operation performed in accordance with the flow chart of FIG. 14;

FIG. 15G is a chart schematically showing a seventh example of the operation performed in accordance with the flow chart of FIG. 14;

FIG. 16 is a flow chart showing a first application example of the line processing for each planned dividing line;

FIG. 17 is a chart schematically showing an example of an operation performed in accordance with the flow chart of FIG. 16;

FIG. 18 is a flow chart showing a second application example of the line processing for each planned dividing line;

FIG. 19A is a chart schematically showing a first example of an operation performed in accordance with the flow chart of FIG. 18;

FIG. 19B is a chart schematically showing a second example of the operation performed in accordance with the flow chart of FIG. 18;

FIG. 20 is a diagram schematically showing an example of an image of the semiconductor substrate obtained in Step S1008 of FIG. 16 or Step S1104 of FIG. 18;

FIG. 21 is a flow chart showing an example of a determination method of laser processing conditions in the line processing;

FIG. 22A is a chart showing parameters relating to the determination of laser processing conditions;

FIG. 22B is a graph showing a time impact of the laser processing condition;

FIG. 22C it a Table showing an example of a table to be referred to in the determination of the laser processing conditions of FIG. 21;

FIG. 23 is a plan view schematically showing a positional relationship of the laser irradiation position and the imaging ranges in the detailed operation of imaging the imaging ranges;

FIG. 24 is a plan view schematically showing an imaging object in the detailed operation of imaging the imaging range;

FIG. 25 is a flow chart showing an example of a camera exposure control;

FIG. 26 is a Table schematically showing information obtainable from panned images captured by the panning operation;

FIG. 27 is a flow chart showing an example of image determination performed for the panned image; and

FIG. 28 is a diagram schematically showing a mask used in the image determination of FIG. 27.

### DETAILED DESCRIPTION

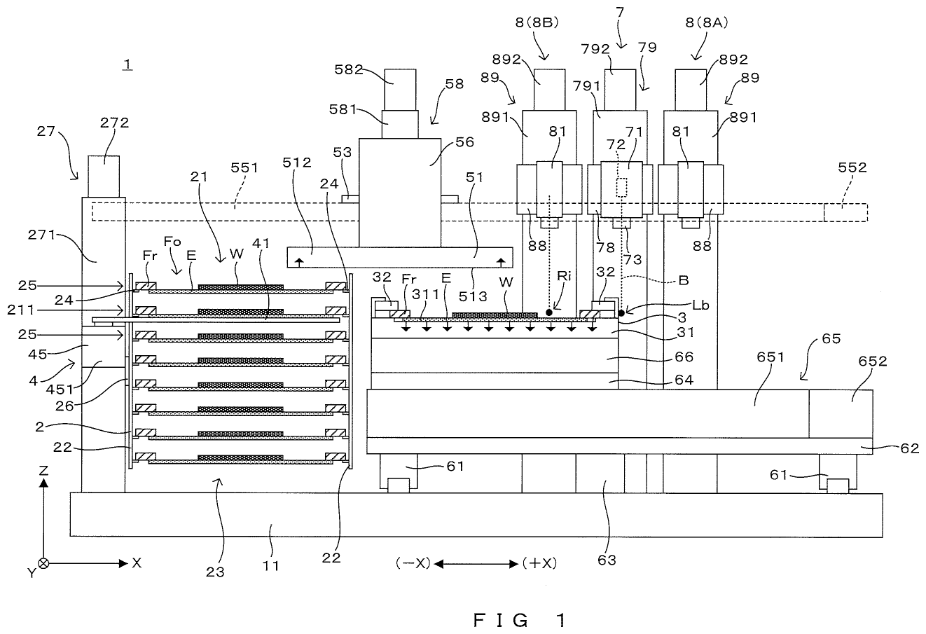

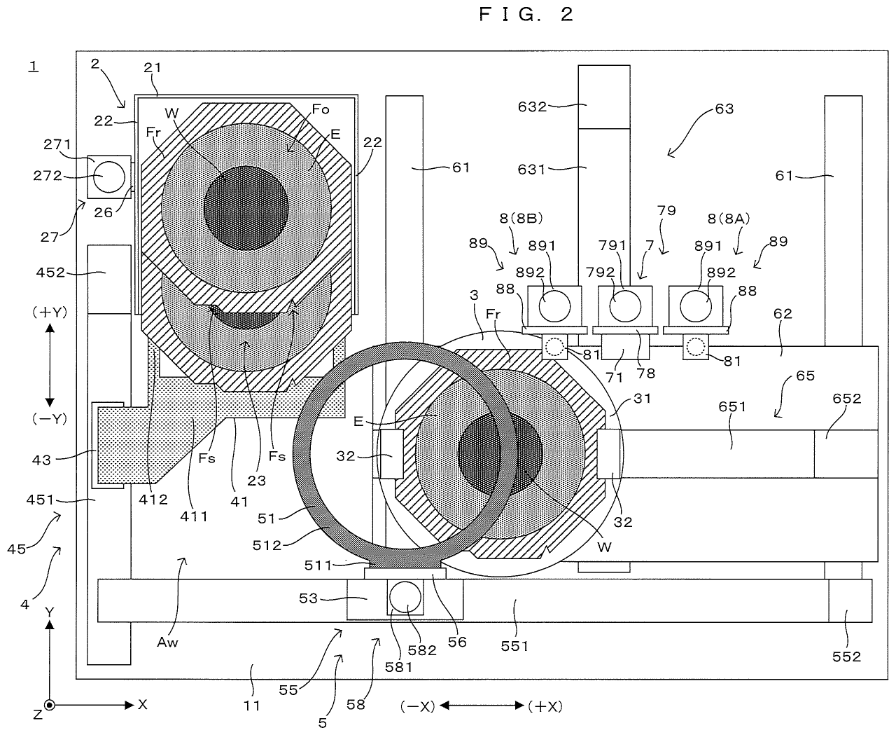

FIG. 1 is a front view schematically showing an example of a laser processing apparatus according to the disclosure, and FIG. 2 is a plan view schematically showing the laser processing apparatus of FIG. 1. In both figures and subsequent figures, an X direction, which is a horizontal direction, a Y direction, which is a horizontal direction orthogonal to the X direction, and a Z direction, which is a vertical direction, are shown as appropriate. Further, a (+X) side in the X direction (right side in FIG. 2) and a (−X) side (left side in FIG. 2) opposite to the (+X) side in the X direction are shown as appropriate, and a (+Y) side in the Y direction (upper side in FIG. 2) and a (−Y) side (lower side in FIG. 2) opposite to the (+Y) side in the Y direction are shown as appropriate.

The laser processing apparatus 1 processes a semiconductor substrate W by irradiating a laser beam to the semiconductor substrate W (processing object). This semiconductor substrate W is held by a ring frame Fr via a tape E. The tape E is a dicing tape or a bonding tape, and the front surface (upper surface) of the tape E is adhesive. The ring frame Fr has an outer shape obtained by cutting parts of a regular octagon shape to provide slits Fs, and a circular opening Fo is provided in a center of the ring frame Fr. The front surface of the tape E is facing the ring frame Fr from below to overlap the entire opening Fo, and the peripheral edge of the front surface of the tape E is bonded to the bottom surface of the ring frame Fr by an adhesive force. Further, the semiconductor substrate W is bonded to the front surface of the tape E by an adhesive force. The semiconductor substrate W is conveyed in the laser processing apparatus 1 while being held by the ring frame Fr via the tape E in this way. Note that the semiconductor substrate W has a front surface and a back surface opposite to the front surface, and an electronic circuit is formed on the front surface of the semiconductor substrate W, whereas the back surface of the semiconductor substrate W is flat. The downward facing front surface of the semiconductor substrate W is bonded to the front surface of the tape E. That is, the semiconductor substrate W is held with the back surface of the semiconductor substrate W facing upward.

The laser processing apparatus 1 is provided with a substrate storage part 2 for storing the semiconductor substrate W and a chuck stage 3 (supporting member) for holding the semiconductor substrate W taken out from the substrate storage part 2. The laser processing apparatus 1 is provided with a base plate 11 having a flat plate shape, and the substrate storage part 2 and the chuck stage 3 are supported by the base plate 11. The chuck stage 3 is arranged on the (+X) side of the substrate storage part 2 in the λ direction, and arranged on the (−Y) side of the substrate storage part 2 in the Y direction. A space on the (−X) side of the chuck stage 3 in the X direction and on the (−Y) side of the substrate storage part 2 in the Y direction is a substrate transfer region Aw.

The substrate storage part 2 includes a substrate storage cassette 21. The substrate storage cassette 21 includes a pair of side walls 22 provided on both sides in the λ direction and an opening 23 provided between the side walls 22, and the opening 23 is facing toward the (−Y) side (i.e. toward the substrate transfer region Aw). The pair of side walls 22 are flat plates provided perpendicular to the X direction and facing each other in the X direction. Further, supporting projections 24 are provided inside each of the pair of side walls 22. A pair of the supporting projections 24 facing each other in the X direction are provided at the same height. The ring frame Fr holding the semiconductor substrate W can be inserted to a position above the pair of supporting projections 24 from the (−Y) side via the opening 23. Both ends in the X direction of the ring frame Fr inserted in this way are supported from below by the pair of supporting projections 24. That is, a side above the pair of supporting projections 24 functions as a slot 25 for storing the ring frame Fr, and the ring frame Fr inserted into the slot 25 from the (−Y) side via the opening 23 is supported by the pair of supporting projections 24 corresponding to this slot 25. Therefore, the semiconductor substrate W supported on the ring frame Fr can be stored into the substrate storage cassette 21 by inserting the ring frame Fr into the slot 25 of the substrate storage cassette 21, and the semiconductor substrate W can be taken out from the substrate storage cassette 21 by withdrawing the ring frame Fr from the slot 25 of the substrate storage cassette 21.

Further, the substrate storage cassette 21 includes a Z-axis slider 26 for supporting the substrate storage cassette 21 and a Z-axis driving mechanism 27 for driving the Z-axis slider 26 in the Z direction. The Z-axis driving mechanism 27 is a single-axis robot mounted on the base plate 11 and includes a Z-axis drive transmitter 271 for supporting the Z-axis slider 26 movably in the Z direction and a Z-axis cassette motor 272 for driving the Z-axis slider 26 supported on the Z-axis drive transmitter 271 in the Z direction. The Z-axis drive transmitter 271 includes a ball screw to be driven by the Z-axis cassette motor 272, and the Z-axis slider 26 is attached to a nut of the ball screw. However, a specific configuration of the Z-axis driving mechanism 27 is not limited to this example and may be a linear motor. Such a Z-axis driving mechanism 27 moves the substrate storage cassette 21 supported on the Z-axis slider 26 in the Z direction by driving the Z-axis slider 26 supported on the Z-axis drive transmitter 271 by the Z-axis cassette motor 272.

A substrate insertion height 211 is set for the substrate storage cassette 21, and the semiconductor substrate W can be inserted into and withdrawn from the slot 25 located at the substrate insertion height 211. Therefore, the slot 25, into which and from which the semiconductor substrate W is inserted and withdrawn, can be changed by moving the substrate storage cassette 21 in the Z direction by the Z-axis driving mechanism 27 to change the slot 25 located at the substrate insertion height 211, out of a plurality of the slots 25.

In contrast, the laser processing apparatus 1 is provided with a Y-axis conveying mechanism 4 for conveying the ring frame Fr in the Y direction between the slot 25 at the substrate insertion height 211 and the substrate transfer region Aw. The Y-axis conveying mechanism 4 includes a lift hand 41, a Y-axis slider 43 for supporting the lift hand 41 and a Y-axis driving mechanism 45 for driving the Y-axis slider 43 in the Y direction. The Y-axis driving mechanism 45 is a single-axis robot mounted on the base plate 11 by an unillustrated frame and includes a Y-axis drive transmitter 451 for supporting the Y-axis slider 43 movably in the Y direction and a Y-axis lift hand motor 452 for driving the Y-axis slider 43 supported on the Y-axis drive transmitter 451 in the Y direction. The Y-axis drive transmitter 451 includes a ball screw to be driven by the Y-axis lift hand motor 452, and the Y-axis slider 43 is attached to a nut of the ball screw. However, a specific configuration of the Y-axis driving mechanism 45 is not limited to this example and may be a linear motor. Such a Y-axis driving mechanism 45 moves the lift hand 41 supported on the Y-axis slider 43 in the Y direction by driving the Y-axis slider 43 supported on the Y-axis drive transmitter 451 by the Y-axis lift hand motor 452.

The lift hand 41 includes a base part 411 supported on the Y-axis slider 43 and a fork 412 projecting toward the (+Y) side from the base part 411. The fork 412 is located at the substrate insertion height 211 and can hold the ring frame Fr from below. The Y-axis conveying mechanism 4 moves the ring frame Fr held by the fork 412 of the lift hand 41 between the substrate storage cassette 21 and the substrate transfer region Aw by driving the lift hand 41 in the Y direction by the Y-axis driving mechanism 45 as described later.

Further, the laser processing apparatus 1 is provided with an XZ-axis conveying mechanism 5 for conveying the ring frame Fr in the X direction between the lift hand 41 located in the substrate transfer region Aw and the chuck stage 3. The XZ-axis conveying mechanism 5 includes a suction hand 51, an X-axis slider 53 for supporting the suction hand 51 and an X-axis driver 55 for driving the X-axis slider 53 in the X direction. The X-axis driver 55 is a single-axis robot mounted on the base plate 11 by an unillustrated frame and includes an X-axis drive transmitter 551 for supporting the X-axis slider 53 movably in the X direction and an X-axis suction hand motor 552 for driving the X-axis slider 53 supported on the X-axis drive transmitter 551 in the X direction. The X-axis drive transmitter 551 includes a ball screw to be driven by the X-axis suction hand motor 552, and the X-axis slider 53 is attached to a nut of the ball screw. However, a specific configuration of the X-axis driver 55 is not limited to this example and may be a linear motor. Such an X-axis driver 55 moves the suction hand 51 supported on the X-axis slider 53 in the X direction by driving the X-axis slider 53 supported on the X-axis drive transmitter 551 by the X-axis suction hand motor 552.

Further, the XZ-axis conveying mechanism 5 includes a Z-axis slider 56 attached to the suction hand 51 and a Z-axis driver 58 for driving the Z-axis slider 56 in the Z direction with respect to the X-axis slider 53. That is, the suction hand 51 is supported on the X-axis slider 53 via the Z-axis slider 56 and the Z-axis driver 58. The Z-axis driver 58 is a single-axis robot mounted on the X-axis slider 53 and includes a Z-axis drive transmitter 581 for supporting the Z-axis slider 56 movably in the Z direction and a Z-axis suction hand motor 582 for driving the Z-axis slider 56 supported on the Z-axis drive transmitter 581 in the Z direction. The Z-axis drive transmitter 581 includes a ball screw to be driven by the Z-axis suction hand motor 582, and the Z-axis slider 56 is attached to a nut of the ball screw. However, a specific configuration of the Z-axis driver 58 is not limited to this example and may be a linear motor. The Z-axis slider 56 extends to a side below the X-axis drive transmitter 551 from the Z-axis driver 58 and the suction hand 51 is attached to the lower end of the Z-axis slider 56. Such a Z-axis driver 58 moves the suction hand 51 supported on the Z-axis slider 56 in the Z direction by driving the Z-axis slider 56 supported on the Z-axis drive transmitter 581 by the Z-axis suction hand motor 582.

The suction hand 51 includes a base part 511 supported on the Z-axis slider 56 and an annular suction member 512 projecting toward the (+Y) side from the base part 511. The annular suction member 512 has a circular annular shape, and a plurality of suction holes are open in a bottom surface 513 of the annular suction member 512. The ring frame Fr can be held from above by the suction hand 51 by sucking the ring frame Fr by a negative pressure generated in each suction hole of the bottom surface 513 while bringing the bottom surface 513 of this annular suction member 512 into contact with the ring frame Fr from above. The XZ-axis conveying mechanism 5 moves the ring frame Fr held by the annular suction member 512 of the suction hand 51 between the substrate transfer region Aw and the chuck stage 3 by driving the suction hand 51 in the X direction by the X-axis driver 55 and driving the suction hand 51 in the Z direction by the Z-axis driver 58 as described later.

The chuck stage 3 includes a suction plate 31, on which the ring frame Fr supporting the semiconductor substrate W via the tape E is placed. The suction plate 31 has a circular shape, and a plurality of suction holes are open in an upper surface 311 of the suction plate 31. The tape E can be fixed to the suction plate 31 by sucking the tape E in contact with the upper surface 311 by a negative pressure generated in each suction hole of the upper surface 311 of the suction plate 31. Further, the chuck stage 3 includes a plurality of clampers 32 provided on the peripheral edge of the suction plate 31. This chuck stage 3 fixes the ring frame Fr to the suction plate 31 by causing the clampers 32 to face the ring frame Fr placed on the suction plate 31 from above and sandwiching the ring frame Fr between the clampers 32 and the suction plate 31. Further, the chuck stage 3 releases the fixing of the ring frame Fr to the suction plate 31 by laterally retracting the clampers 32 from the ring frame Fr.

As just described, the chuck stage 3 holds the semiconductor substrate W supported on the ring frame Fr via the tape E by sucking the tape E by the suction plate 31 and fixing the ring frame Fr by the clampers 32. By using the clampers 32 in combination in this way, the tape E can be sucked to the suction plate 31 with a weak suction force and an influence of the suction of the tape E on the semiconductor substrate W can be mitigated as compared to the case where the semiconductor substrate W is held only by the suction of the tape E to the suction plate 31.

Further, the laser processing apparatus 1 is provided with an XYθ drive table 6 for supporting the chuck stage 3. The XYθ drive table 6 is arranged on the base plate 11 and drives the chuck stage 3 in the X direction, the Y direction and a θ direction with respect to the base plate 11. Here, the θ direction is a rotation direction about an axis of rotation parallel to the Z direction. That is, the XYθ drive table 6 includes a Y-axis guide 61 mounted on the base plate 11 in parallel to the Y direction, a Y-axis slider 62 supported movably in the Y direction by the Y-axis guide 61 and a Y-axis driver 63 for driving the Y-axis slider 62 in the Y direction. The Y-axis driver 63 is a single-axis robot mounted on the base plate 11 and includes a Y-axis drive transmitter 631 for supporting the Y-axis slider 62 movably in the Y direction and a Y-axis table motor 632 for driving the Y-axis slider 62 supported on the Y-axis drive transmitter 631 in the Y direction. The Y-axis drive transmitter 631 includes a ball screw to be driven by the Y-axis table motor 632, and the Y-axis slider 62 is attached to a nut of the ball screw. However, a specific configuration of the Y-axis driver 63 is not limited to this example and may be a linear motor.

Further, the XYθ drive table 6 includes an X-axis slider 64 and an X-axis driver 65 for driving the X-axis slider 64 in the X direction with respect to the Y-axis slider 62. The X-axis driver 65 is a single-axis robot mounted on the Y-axis slider 62 and includes an X-axis drive transmitter 651 for supporting the X-axis slider 64 movably in the X direction and an X-axis table motor 652 for driving the X-axis slider 64 supported on the X-axis drive transmitter 651 in the X direction. The X-axis drive transmitter 651 includes a ball screw to be driven by the X-axis table motor 652, and the X-axis slider 64 is attached to a nut of the ball screw. However, a specific configuration of the X-axis driver 65 is not limited to this example and may be a linear motor.

Furthermore, the XYθ drive table 6 includes a θ-axis table motor 66 mounted on the X-axis slider 64. This θ-axis table motor 66 drives the chuck stage 3 in the 0 direction with respect to the X-axis slider 64.

Such an XYθ drive table 6 can drive the chuck stage 3 in the Y direction by the Y-axis table motor 632, drive the chuck stage 3 in the X direction by the X-axis table motor 652 and drive the chuck stage 3 in the θ direction by the θ-axis table motor 66.

Further, the laser processing apparatus 1 is provided with a laser processing part 7 for executing a laser processing for the semiconductor substrate W held on the chuck stage 3. The laser processing part 7 includes a processing head 71 facing the semiconductor substrate W held on the chuck stage 3 from above. The processing head 71 includes a laser light source 72 for generating a laser beam B having a predetermined frequency and an optical system 73 (a lens, a diaphragm and the like) for irradiating the laser beam B emitted from the laser light source 72 to the semiconductor substrate W. This processing head 71 has a predetermined laser irradiation position Lb and faces the laser irradiation position Lb from above in the Z direction. The processing head 71 condenses the laser beam B emitted from the laser light source 72 on the laser irradiation position Lb by the optical system 73, thereby forming a modified layer in a part of the semiconductor substrate W overlapping the laser irradiation position Lb.

Further, the laser processing part 7 includes a Z-axis slider 78 for supporting the processing head 71 and a Z-axis driver 79 for driving the Z-axis slider 78 in the Z direction. The Z-axis driver 79 is a single-axis robot mounted on the base plate and includes a Z-axis drive transmitter 791 for supporting the Z-axis slider 78 movably in the Z direction and a Z-axis head motor 792 for driving the Z-axis slider 78 supported on the Z-axis drive transmitter 791 in the Z direction. The Z-axis drive transmitter 791 includes a ball screw to be driven by the Z-axis head motor 792, and the Z-axis slider 78 is attached to a nut of the ball screw. However, a specific configuration of the Z-axis driver 79 is not limited to this example and may be a linear motor. Such a Z-axis driver 79 moves the laser irradiation position Lb of an infrared camera 81 in the Z direction by driving the Z-axis slider 78 supported on the Z-axis drive transmitter 791 by the Z-axis head motor 792 to move the processing head 71 supported on the Z-axis slider 78 in the Z direction.

Further, the laser processing apparatus 1 is provided with imaging parts 8 for imaging the semiconductor substrate W held on the chuck stage 3. Particularly, two imaging parts 8 are arranged across the laser processing part 7 in the X direction. In distinguishing these two imaging parts 8, the imaging part 8 on the (+X) side of the laser processing part 7 is referred to as the imaging part 8A and the imaging part 8 on the (−X) side of the laser processing part 7 is referred to as the imaging part 8B. In this way, the imaging part 8A, the laser processing part 7 and the imaging part 8B are arrayed in the X direction. Note that each of the imaging parts 8A, 8B has a common basic configuration. Therefore, components common to the imaging parts 8A, 8B are described without being distinguished.

The imaging part 8 includes the infrared camera 81 facing the semiconductor substrate W held on the chuck stage 3 from above. This infrared camera 81 has a predetermined imaging range Ri (in other words, a field of view) and faces this imaging range Ri from above in the Z direction. The infrared camera 81 images the imaging range Ri by detecting infrared rays emitted from the imaging range Ri and obtains an image of the imaging range Ri.

Further, the imaging part 8 includes a Z-axis slider 88 for supporting the infrared camera 81 and a Z-axis driver 89 for driving the Z-axis slider 88 in the Z direction. The Z-axis driver 89 is a single-axis robot mounted on the base plate and includes a Z-axis drive transmitter 891 for supporting the Z-axis driver 88 movably in the Z direction and a Z-axis camera motor 892 for driving the Z-axis slider 88 supported on the Z-axis drive transmitter 891 in the Z direction. The Z-axis drive transmitter 891 includes a ball screw to be driven by the Z-axis camera motor 892, and the Z-axis slider 88 is attached to a nut of the ball screw. However, a specific configuration of the Z-axis driver 89 is not limited to this example and may be a linear motor. Such a Z-axis driver 89 moves the imaging range Ri of the infrared camera 81 in the Z direction by driving the Z-axis slider 88 supported on the Z-axis drive transmitter 891 by the Z-axis camera motor 892 to move the infrared camera 81 supported on the Z-axis slider 88 in the Z direction.

Note that the infrared camera 81 of the imaging part 8A and the infrared camera 81 of the imaging part 8B have mutually different resolutions. Specifically, the infrared camera 81 of the imaging part 8A has a higher resolution, i.e. a narrower field of view, than the infrared camera 81 of the imaging part 8B. However, the resolutions of the infrared cameras 81 need not be different between the imaging parts 8A and 8B, and these infrared cameras 81 may have the same resolution. Further, in this example, centers of each of the imaging range Ri of the imaging part 8A, the laser irradiation position Lb of the processing head 71 and the imaging range Ri of the imaging part 8B are arranged in parallel to the X direction. However, these need not necessarily be parallel to the X direction, and the imaging range Ri of the imaging part 8A only have to be located on the (+X) side and the imaging range Ri of the imaging part 8B only have to be located on the (−X) side with respect to the laser irradiation position Lb of the processing head 71.

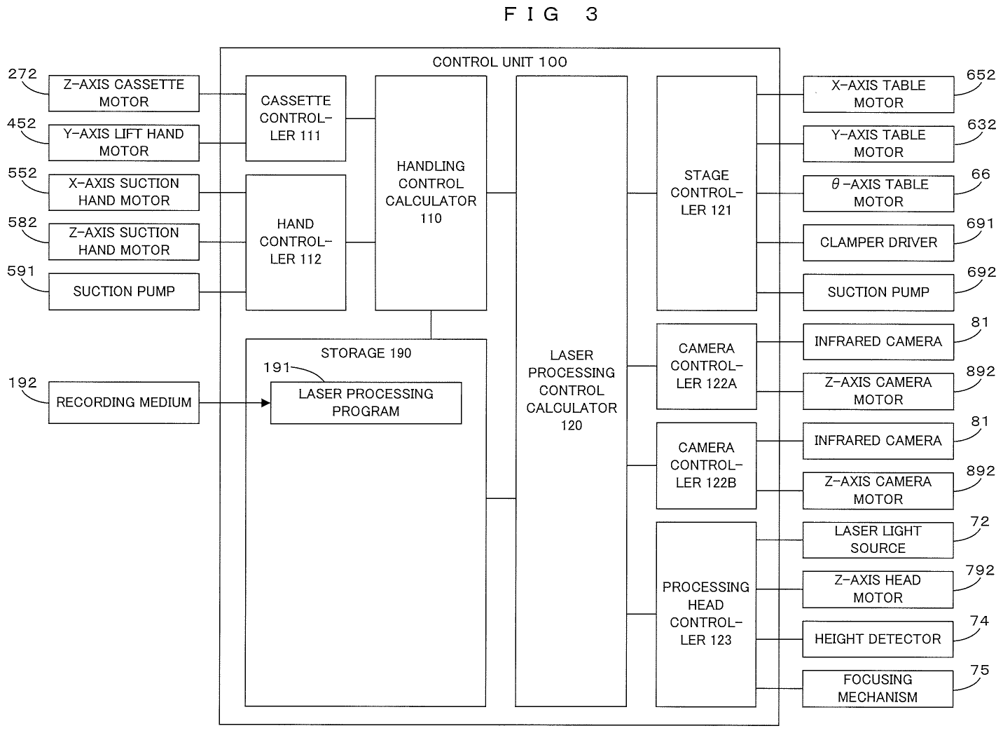

FIG. 3 is a block diagram showing the electrical configuration of the laser processing apparatus of FIG. 1. As shown in FIG. 3, the laser processing apparatus 1 is provided with a control unit 100 for controlling the components shown in FIGS. 1 and 2. The control unit 100 includes a handling control calculator 110 in charge of controlling a substrate conveying system (substrate storage part 2, Y-axis conveying mechanism 4 and XZ-axis conveying mechanism 5) relating to the conveyance of the semiconductor substrate W in the laser processing apparatus 1 and a laser processing control calculator 120 in charge of controlling a laser processing system (chuck stage 3, XYθ drive table 6, laser processing part 7 and imaging parts 8) relating to laser processing for the semiconductor substrate W.

Further, the control unit 100 includes a cassette controller 111 for controlling inserting and withdrawing operations of the semiconductor substrate W into and from the substrate storage cassette 21 in response to a command from the handling control calculator 110. This cassette controller 111 adjusts the position in the Z direction of the substrate storage cassette 21 by controlling the Z-axis cassette motor 272 and adjusts the position in the Y direction of the lift hand 41 by controlling the Y-axis lift hand motor 452.

Further, the control unit 100 includes a hand controller 112 for controlling a conveying operation of the semiconductor substrate W by the suction hand 51 in response to a command from the handling control calculator 110. The hand controller 112 adjusts the position in the X direction of the suction hand 51 by controlling the X-axis suction hand motor 552 and adjusts the position in the Z direction of the suction hand 51 by controlling the Z-axis suction hand motor 582. Further, the hand controller 112 controls a suction pump 591 for sucking the suction holes open in the bottom surface 513 of the annular suction member 512 of the suction hand 51. That is, the hand controller 112 sucks the ring frame Fr by the suction hand 51 by supplying a negative pressure to the suction holes by the suction pump 591 and separates the ring frame Fr from the suction hand 51 by stopping the supply of the negative pressure to the suction holes by the suction pump 591.

Further, the control unit 100 includes a stage controller 121 for controlling a substrate fixing operation by the chuck stage 3 and the drive of the chuck stage 3 in response to a command from the laser processing control calculator 120. The stage controller 121 adjusts the positions in the X direction, the Y direction and the θ direction of the chuck stage 3 by controlling each of the X-axis table motor 652, the Y-axis table motor 632 and the θ-axis table motor 66. Further, the stage controller 121 executes fixation of the ring frame Fr to the suction plate 31 and releasing the fixation by a clamper driver 691 by controlling the clamper driver 691 for driving the clampers 32. Furthermore, the stage controller 121 controls a suction pump 692 for sucking the suction holes open in the upper surface 311 of the suction plate 31. That is, the stage controller 121 sucks the tape E by the suction plate 31 by supplying the negative pressure to the suction holes by the suction pump 692 and releases the suction of the tape E by the suction plate 31 by stopping the supply of the negative pressure to the suction holes by the suction pump 692.

Further, the control unit 100 includes a camera controller 122A for controlling the imaging part 8A and a camera controller 122B for controlling the imaging part 8B. These hand controllers 112A, 112B execute the following controls for the infrared cameras 81 and the Z-axis camera motors 892 of the imaging parts 8A, 8B which are these targets respectively. That is, each of the camera controllers 122A, 122B causes the infrared camera 81 to image the semiconductor substrate W to obtain an image of the semiconductor substrate W, and drives the infrared camera 81 in the Z direction by the Z-axis camera motor 892 to adjust a distance in the Z direction from the infrared camera 81 to the semiconductor substrate W.

Further, the control unit 100 includes a processing head controller 123 for controlling the laser processing part 7. The processing head controller 123 drives the laser light source 72 to emit a laser beam B from the laser light source 72 and drives the processing head 71 in the Z direction by the Z-axis head motor 792 to adjust a distance in the Z direction from the processing head 71 to the semiconductor substrate W. Further, the processing head 71 includes a height detector 74 for detecting a height (distance in the Z direction) from the semiconductor substrate W. This height detector 74 is a so-called distance sensor. Furthermore, the optical system 73 of the processing head 71 includes a focusing mechanism 75. The focusing mechanism 75 adjusts a position to which the laser beam B is condensed by displacing a focus of the optical system 73 in the Z direction. Particularly, the processing head controller 123 condenses the laser beam B at a predetermined position inside the semiconductor substrate W by controlling the focusing mechanism 75 based on the height of the processing head 71 from the semiconductor substrate W detected by the height detector 74.

Note that each function of the control unit 100 described above can be realized by a processer such as a CPU (Central Processing Unit), an FPGA (Field Programmable Gate Array), etc.

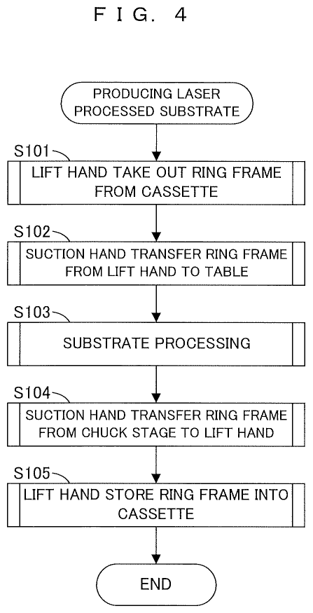

Further, the control unit 100 includes a storage 190, which is a storage device such as a HDD (Hard Disk Drive) or an SDD (Solid State Drive). A laser processing program 191 for specifying later-described operations performed in the laser processing apparatus 1 for laser processing the semiconductor substrate W is stored in this storage 190. That is, the control unit 100 executes each control to be described later using FIGS. 4 to 22C by implementing the laser processing program 191. Note that the laser processing program 191 is provided by a recording medium 192 external of the laser processing apparatus 1, and the control unit 100 (computer) reads the laser processing program 191 recorded in the recording medium 192 and stores the laser processing program 191 in the storage 190. Examples of such a recording medium 192 includes a USB (Universal Serial Bus) memory, a storage device of an external computer and the like.

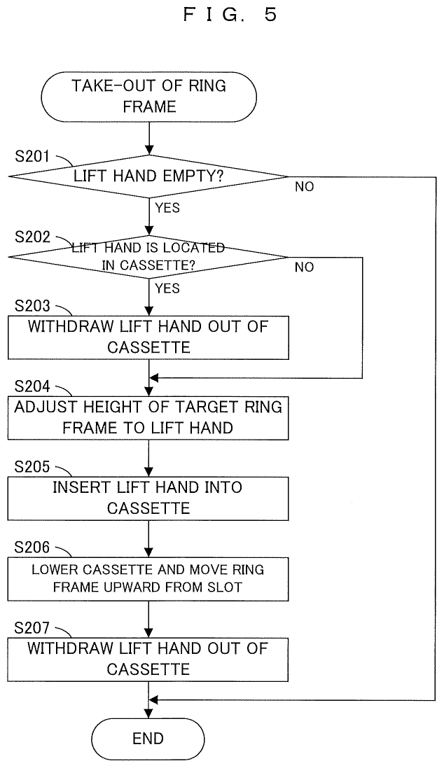

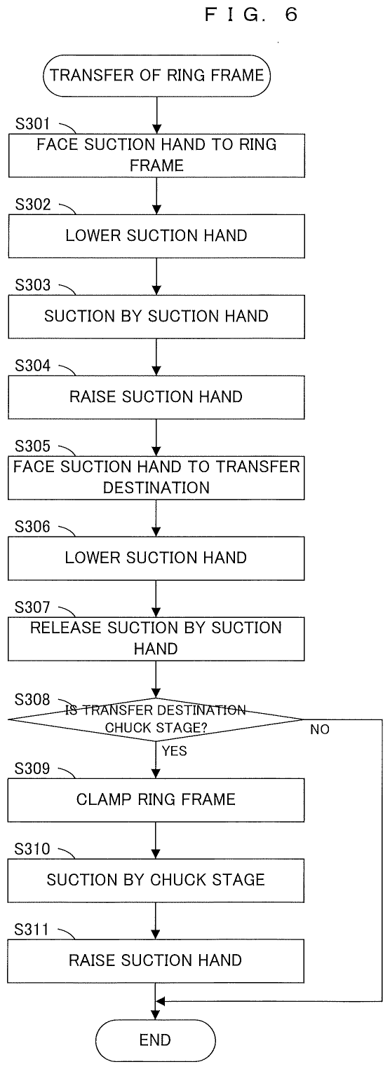

FIG. 4 is a flow chart showing an example of a method for producing a laser processed substrate, for which the laser processing has been already performed. The flow chart of FIG. 4 is carried out in accordance with a control of the control unit 100 based on the laser processing program 191. In Step S101, the lift hand 41 takes out the ring frame Fr from the substrate storage cassette 21 to the substrate transfer region Aw. In Step S102, the suction hand 51 in the substrate transfer region Aw transfers the ring frame Fr from the lift hand 41 to the chuck stage 3. In this way, the semiconductor substrate W held by the ring frame Fr is taken out from the substrate storage cassette 21 to the substrate transfer region AW and then transferred to the chuck stage 3 from the substrate transfer region Aw. Specifically, the take-out of the ring frame of FIG. 5 is performed in Step S101, and the transfer of the ring frame of FIG. 6 is performed in Step S102.

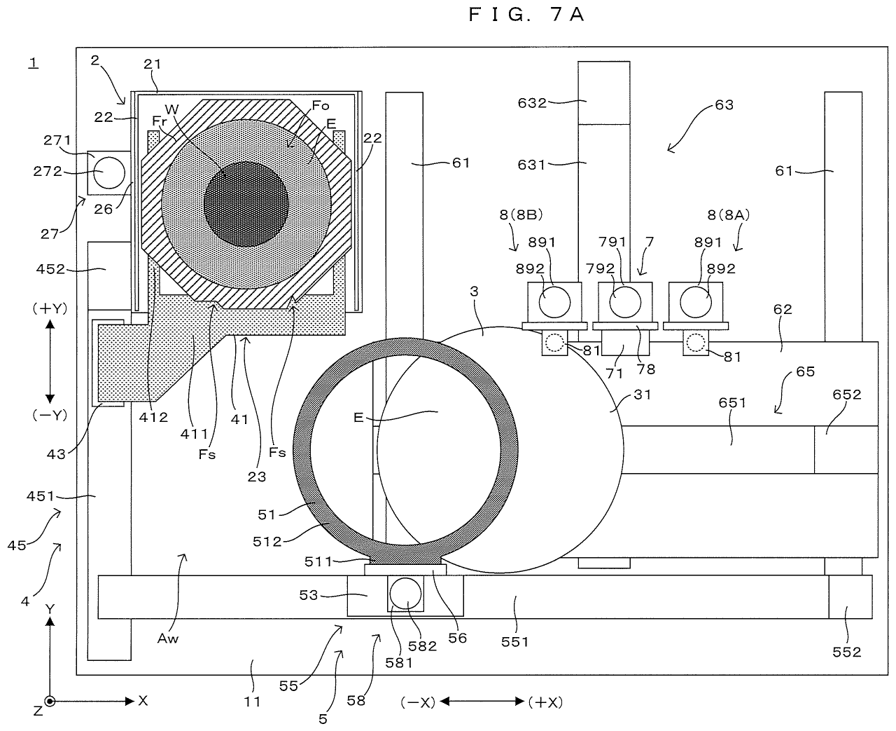

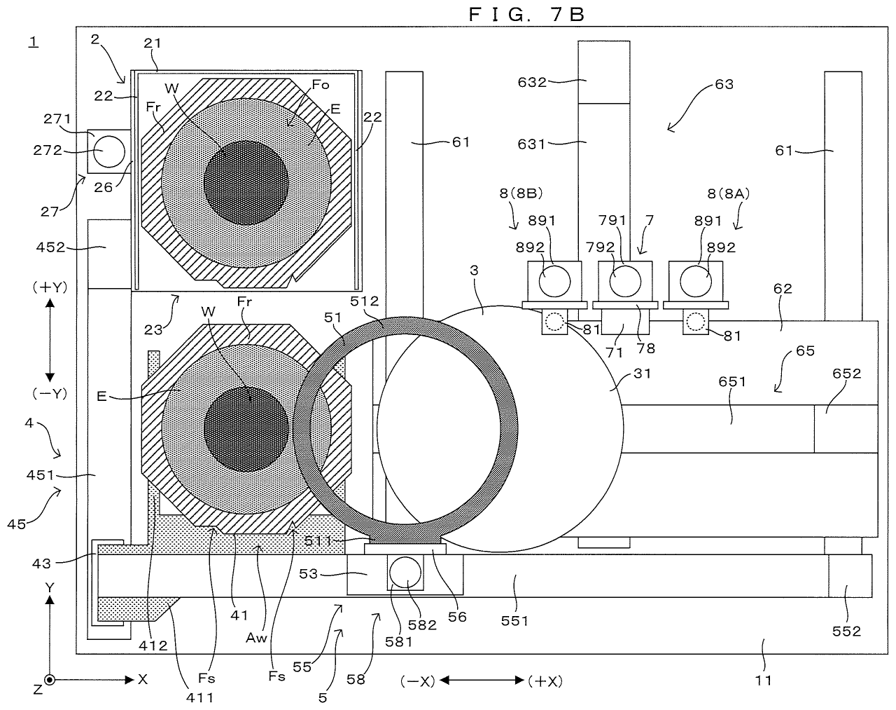

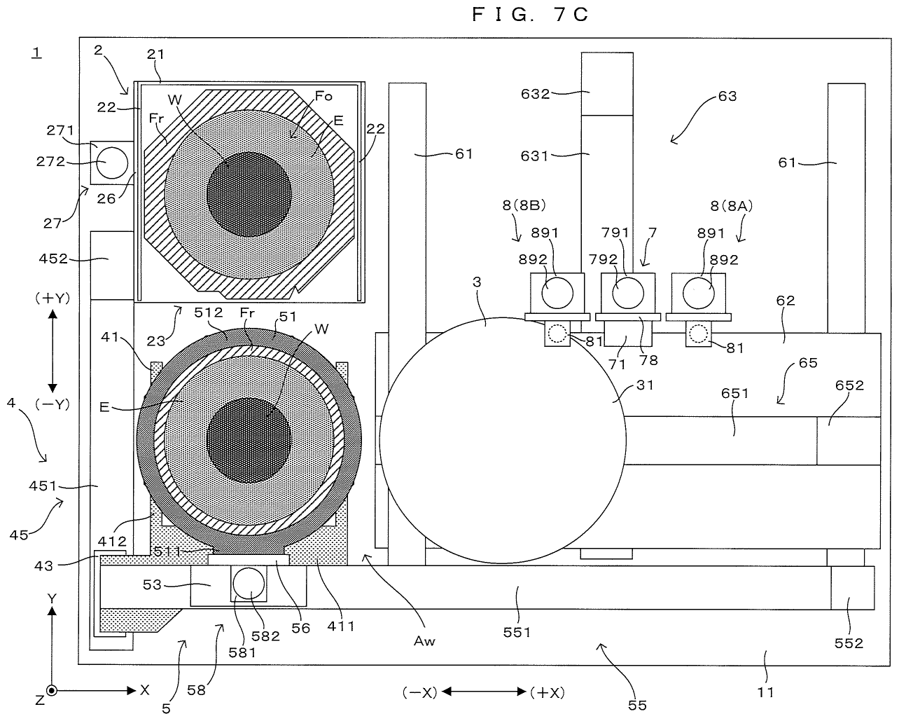

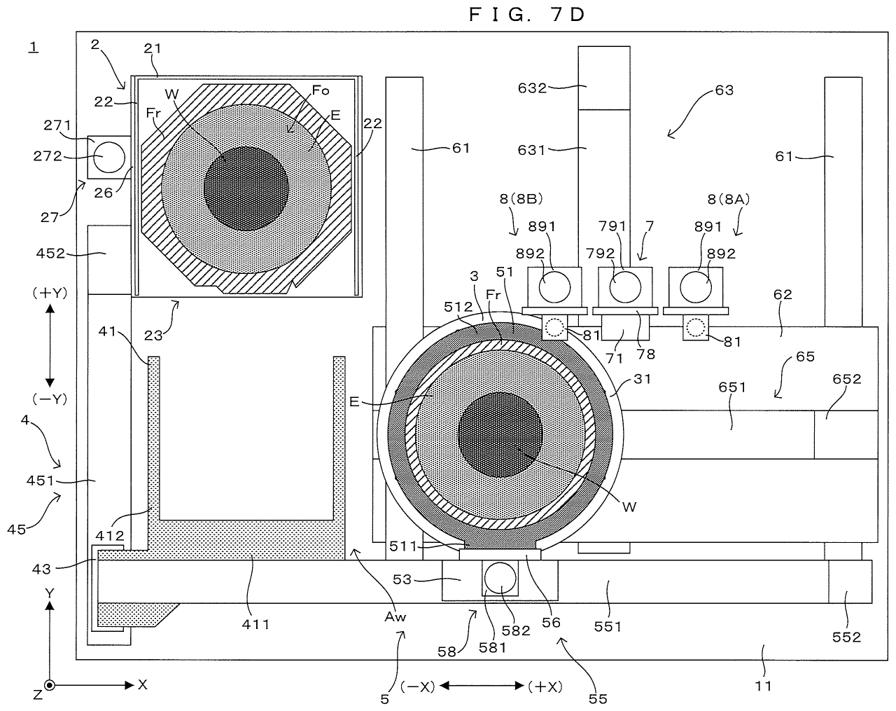

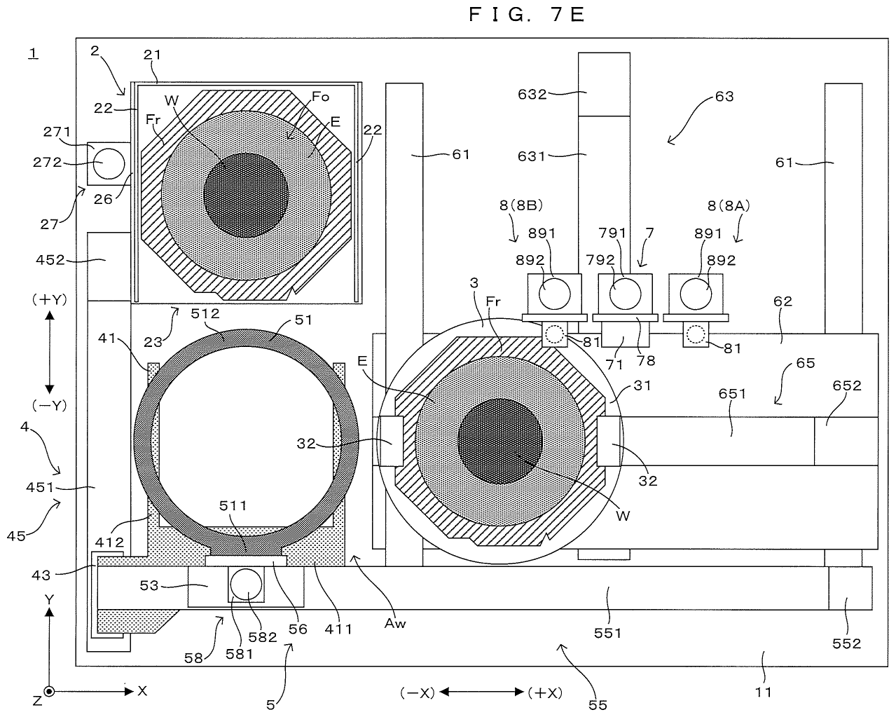

FIG. 5 is a flow chart showing an example of the take-out of the ring frame, FIG. 6 is a flow chart showing an example of the transfer of the ring frame, and FIGS. 7A to 7E are plan views schematically showing an example of an operation performed in accordance with the flow charts of FIGS. 5 and 6.

In Step S201 of FIG. 5, the control unit 100 confirms whether or not the lift hand 41 is empty, i.e. whether or not the ring frame Fr is not placed on the lift hand 41. Whether or not the lift hand 41 is empty can be confirmed based on a history or the like of operations performed by the lift hand 41. The flow chart of FIG. 5 is finished if the lift hand 41 is not empty (“NO” in Step S201), whereas advance is made to Step S201 if the lift hand 41 is empty (“YES” in Step S201).

In Step S202, the control unit 100 confirms whether or not at least a part of the lift hand 41 is located in the substrate storage cassette 21, in other words, located on the inner side (i.e. (+Y) side) of the substrate storage cassette 21 than the opening 23 of the substrate storage cassette 21. Whether or not at least a part of the lift hand 41 is located in the substrate storage cassette 21 can be confirmed, for example, based on the position of the lift hand 41 indicated by an output of an encoder of the Y-axis lift hand motor 452 for driving the lift hand 41 in the Y direction. Advance is made to Step S204 without performing Step S203 if the lift hand 41 is retracted toward the (−Y) side from the substrate storage cassette 21 (“NO” in Step S202), whereas advance is made to Step S203 if a part of the lift hand 41 is located in the substrate storage cassette 21 (“YES” in Step S202). In Step S203, the control unit 100 withdraws the lift hand 41 from the substrate storage cassette 21 toward the (−Y) side and retracts the lift hand 41 toward the (−Y) side of the substrate storage cassette 21 by driving the lift hand 41 toward the (−Y) side by the Y-axis lift hand motor 452.

In Step S204, the control unit 100 positions the slot 25 storing the ring frame Fr to be taken out at a position higher than the substrate insertion height 211 by a predetermined height by driving the substrate storage cassette 21 in the Z direction by the Z-axis cassette motor 272. This predetermined height is shorter than an interval between the slots 25 adjacent in the Z direction. In this way, the bottom surface of the ring frame Fr to be taken out is adjusted to a position higher than the lift hand 41 by the predetermined height.

In Step S205, as shown in FIG. 7A, the control unit 100 inserts the lift hand 41 into the substrate storage cassette 21 by driving the lift hand 41 toward the (+Y) side by the Y-axis lift hand motor 452. In this way, the lift hand 41 faces the ring frame Fr to be taken out across a gap from below.

In Step S206, the control unit 100 lowers the substrate storage cassette 21 in the Z direction by the Z-axis cassette motor 272. Therefore, the ring frame Fr to be taken out is placed on the lift hand 41 and moves upward with respect to the slot 25 (i.e. the pair of supporting projections 24 specifying the slot 25).

In Step S207, the control unit 100 withdraws the lift hand 41 to the substrate transfer region Aw provided outside the substrate storage cassette 21 by driving the lift hand 41 toward the (−Y) side by the Y-axis lift hand motor 452. In this way, as shown in FIG. 7B, the ring frame Fr placed on the lift hand 41 is located in the substrate transfer region Aw.

In Step S301 of FIG. 6, the control unit 100 causes the suction hand 51 to face the ring frame Fr supported on the lift hand 41 in the substrate transfer region Aw from above by adjusting the position in the X direction of the suction hand 51 by the X-axis suction hand motor 552 as shown in FIG. 7C. At this time, the control unit 100 adjusts the suction hand 51 to a position higher than the ring frame Fr by adjusting the height of the suction hand 51 by the Z-axis suction hand motor 582. Therefore, the suction hand 51 faces the ring frame Fr across a gap.

In Step S302, the control unit 100 brings the bottom surface 513 of the suction hand 51 into contact with the upper surface of the ring frame Fr by lowering the suction hand 51 facing the ring frame Fr by the Z-axis drive transmitter 581. In Step S303, the control unit 100 causes the suction pump 591 to generate a negative pressure in the suction holes provided in the bottom surface 513 of the suction hand 51 and the suction hand 51 sucks the ring frame Fr by this negative pressure. In this way, the ring frame Fr is held by the suction hand 51. In Step S304, the control unit 100 raises the suction hand 51 by the Z-axis suction hand motor 582. In this way, the suction hand 51 lifts up the ring frame Fr from the lift hand 41.

In Step S305, the control unit 100 causes the suction hand 51 to face from above the chuck stage 3 as a transfer destination of the ring frame Fr by driving the suction hand 51 toward the (+X) side by the X-axis suction hand motor 552 as shown in FIG. 7D. At this time, the control unit 100 adjusts the ring frame Fr held by the suction hand 51 to a position higher than the chuck stage 3 by adjusting the height of the suction hand 51 by the Z-axis suction hand motor 582. Therefore, the ring frame Fr held by the suction hand 51 faces the chuck stage 3 across a gap.

In Step S306, the control unit 100 places the ring frame Fr (and the tape E) held by the suction hand 51 on the suction plate 31 of the chuck stage 3 by lowering the suction hand 51 by the Z-axis suction hand motor 582. In Step S307, the control unit 100 releases the suction of the ring frame Fr by the suction hand 51 by stopping the suction pump 591.

In Step S308, the control unit 100 confirms whether or not the transfer destination of the ring frame Fr is the chuck stage 3. For example, if the transfer destination of the ring frame Fr is the lift hand 41 as in Step S104 to be described later, “NO” is determined in Step S308 and the flow chart of FIG. 6 is finished. Here, since the transfer destination of the ring frame Fr is the chuck stage 3, “YES” is determined in Step S308 and advance is made to Step S309.

In Step S309, the control unit 100 sandwiches the ring frame Fr placed on the suction plate 31 of the chuck stage 3 between the clampers 32 and the suction plate 31 to clamp the ring frame Fr by driving the clampers 32 by the clamper driver 691. Further, in Step S310, the control unit 100 causes the suction pump 591 to generate a negative pressure in the suction holes provided in the upper surface 311 of the suction plate 31 and the suction plate 31 sucks the tape E bonded to the ring frame Fr by this negative pressure. In this way, the ring frame Fr is held by the chuck stage 3. In Step S311, the control unit 100 raises the suction hand 51 by the Z-axis suction hand motor 582. This causes the suction hand 51 to retract upward from the ring frame Fr held on the chuck stage 3. In this way, as shown in FIG. 7E, the transfer of the ring frame Fr from the substrate storage cassette 21 to the chuck stage 3 is completed (Steps S101, S102 of FIG. 4).

In Step S103 of FIG. 4, substrate processing is performed to process the semiconductor substrate W held on the chuck stage 3 by the laser beam B and the laser beam B is irradiated to the plurality of planned dividing lines provided on the semiconductor substrate W. This substrate processing is described in detail later.

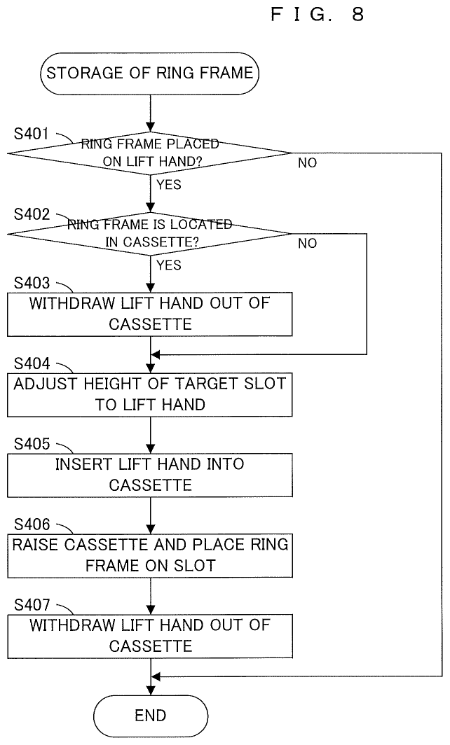

If the substrate processing is completed, Steps S104, S105 are performed. In Step S104, the suction hand 51 transfers the ring frame Fr from the chuck stage 3 to the lift hand 41 in the substrate transfer region Aw. In Step S105, the lift hand 41 stores the ring frame Fr into the substrate storage cassette 21 from the substrate transfer region Aw. In this way, the semiconductor substrate W held on the ring frame Fr is stored into the substrate storage cassette 21 from the substrate transfer region Aw after being transferred from the chuck stage 3 to the substrate transfer region Aw. Specifically, the transfer of the ring frame of FIG. 6 is performed in Step S104, the storage of the ring frame of FIG. 8 is performed in Step S105 and an operation opposite to the one shown in FIGS. 7A to 7E described above is performed. Here, FIG. 8 is a flow chart showing an example of the storage of the ring frame.

Since the operation of FIG. 6 performed in Step S104 is similar to the above operation of FIG. 6 performed in Step S102, description is centered on differences from the above operation and the description of common operation parts is omitted as appropriate. In Step S301 of FIG. 6, the control unit 100 causes the suction hand 51 to face the ring frame Fr placed on the chuck stage 3 from above by adjusting the position in the X direction of the suction hand 51 by the X-axis suction hand motor 552. Then, the control unit 100 lowers the suction hand 51 to the ring frame Fr (Step S302) and causes the suction hand 51 to suck the ring frame Fr (Step S303). Subsequently, the control unit 100 raises the suction hand 51 (Step S304). In this way, the suction hand 51 lifts up the ring frame Fr from the chuck stage 3.

In Step S305, the control unit 100 drives the suction hand 51 toward the (−X) side by the X-axis suction hand motor 552. At this time, the lift hand 41 is waiting on standby in the substrate transfer region Aw. In this way, the suction hand 51 faces from above the lift hand 41 in the substrate transfer region Aw as a transfer destination of the ring frame Fr. Then, the control unit 100 places the ring frame Fr held by the suction hand 51 on the lift hand 41 by lowering the suction hand 51 by the Z-axis suction hand motor 582 (Step S306). Then, the control unit 100 releases the suction of the ring frame Fr by the suction hand 51 by stopping the suction pump 591 (Step S307). In Step S308, the control unit 100 confirms whether or not the transfer destination of the ring frame Fr is the chuck stage 3. Since the transfer destination of the ring frame Fr is not the chuck stage 3, but the lift hand 41 here, “NO” is determined in Step S308 and the flow chart of FIG. 6 is finished.

In Step S401 of FIG. 8, the control unit 100 confirms whether or not the ring frame Fr has been placed on the lift hand 41. The placement of the ring frame Fr on the lift hand 41 can be confirmed, for example, based on a history of operations of the suction hand 51 for placing the ring frame Fr. If the placement of the ring frame Fr on the lift hand 41 is confirmed (“YES” in Step S401), the control unit 100 confirms whether or not at least a part of the lift hand 41 is located in the substrate storage cassette 21 (Step S402) as in Step S202 described above. Advance is made to Step S404 without performing Step S403 if the lift hand 41 is retracted toward the (−Y) side from the substrate storage cassette 21 (“NO” in Step S402), whereas advance is made to Step S403 if a part of the lift hand 41 is located in the substrate storage cassette 21 (“YES” in Step S402). In Step S403, the control unit 100 withdraws the lift hand 41 toward the (−Y) side of the substrate storage cassette 21 and retracts the lift hand 41 toward the (−Y) side from the substrate storage cassette 21 by driving the lift hand 41 toward the (−Y) side by the Y-axis lift hand motor 452.

In Step S404, the control unit 100 positions the slot 25 (in other words, the pair of supporting projections 24 specifying the slot 25) to which the ring frame Fr is to be stored at a position lower than the substrate insertion height 211 by a predetermined height by driving the substrate storage cassette 21 in the Z direction by the Z-axis cassette motor 272. In this way, the slot 25 for storage is adjusted to the position lower than the bottom surface of the ring frame Fr supported on the lift hand 41 by the predetermined height.

In Step S405, the control unit 100 inserts the lift hand 41 into the substrate storage cassette 21 by driving the lift hand 41 toward the (+Y) side by the Y-axis lift hand motor 452. In this way, the pair of supporting projections 24 specifying the slot 25 for storage face the ring frame Fr supported on the lift hand 41 across a gap from below.

In Step S406, the control unit 100 raises the substrate storage cassette 21 in the Z direction by the Z-axis cassette motor 272. In this way, the ring frame Fr is placed on the pair of supporting projections 24 specifying the slot 25 for storage and raised with respect to the lift hand 41. In Step S407, the control unit 100 withdraws the lift hand 41 to the outside of the substrate storage cassette 21 by driving the lift hand 41 toward the (−Y) side by the Y-axis lift hand motor 452.

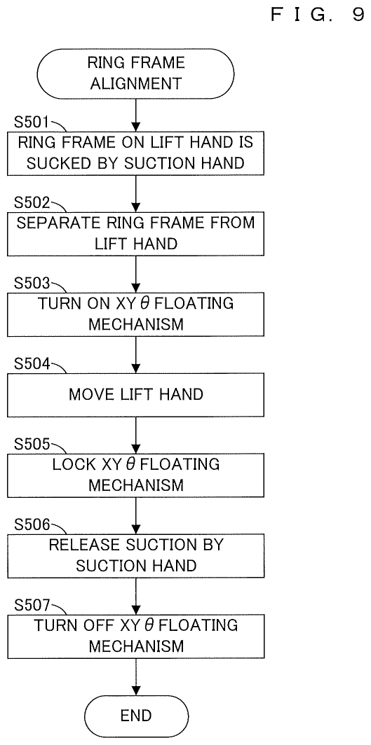

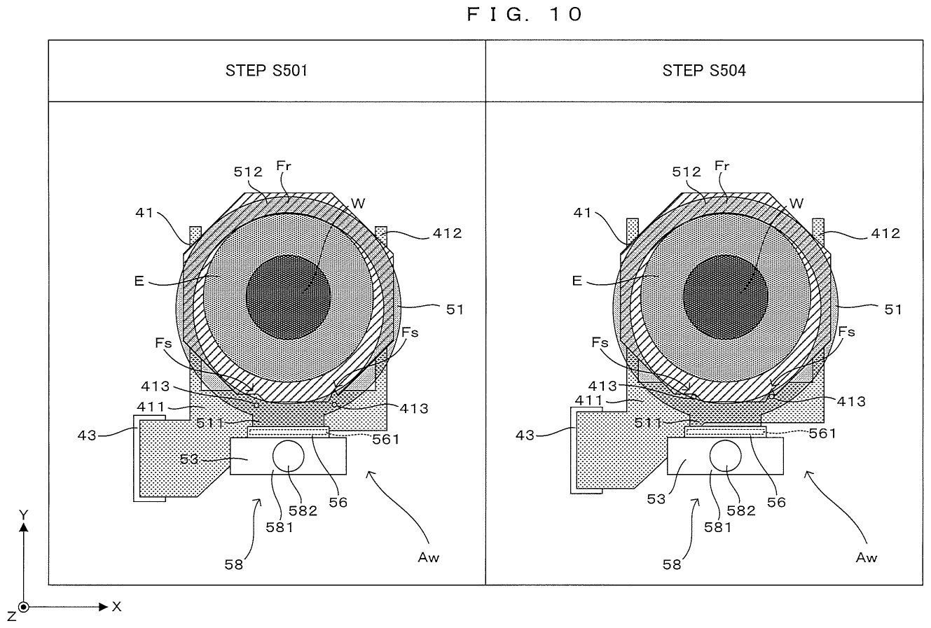

Note that, in taking out or storing the ring frame Fr from or into the substrate storage cassette 21, a ring frame alignment of aligning the ring frame Fr with respect to the lift hand 41 can be performed as appropriate. FIG. 9 is a flow chart showing an example of the ring frame alignment, and FIG. 10 shows plan views schematically showing an example of an operation performed in the ring frame alignment. Note that the flow chart of FIG. 9 is performed by a control of the control unit 100.

In FIG. 10, members (alignment projections 413 and the like) below the suction hand 51 are shown through the suction hand 51. That is, in this example, the lift hand 41 includes a plurality of the alignment projections 413 projecting upward from the base part 41. The plurality of these alignment projections 413 correspond to the plurality of slits Fs of the ring frame Fr. The ring frame alignment is performed using the alignment projections 413 and the slits Fs.

In this ring frame alignment, the ring frame Fr on the lift hand 41 is sucked by the suction hand 51 (Step S501). Then, the suction hand 51 holding the ring frame Fr is raised to separate the ring frame Fr upward from the lift hand 41 (Step S502). At this time, a separation height of the ring frame Fr from the lift hand 41 is so adjusted that the ring frame Fr is located at a height between the lower and upper ends of the alignment projections 413 in the Z direction.

In Step S503, an XYθ floating mechanism 561 built in the Z-axis slider 56 is turned on. This XYθ floating mechanism 561 selectively takes a floating state for floatingly supporting the suction hand 51 and a locking state for fixedly supporting the suction hand 51. Here, the floating support means the support of the suction hand 51 in a state where the suction hand 51 can move in the X direction, the Y direction and the 0 direction with respect to the XYθ floating mechanism 561, and the fixed support means the support of the suction hand 51 in a state where the suction hand 51 is fixed to the XYθ floating mechanism 561. If the XYθ floating mechanism 561 is turned on in Step S503, the XYθ floating mechanism 561 floatingly supports the suction hand 51 and the suction hand 51 becomes movable in the X direction, the Y direction and the θ direction with respect to the XYθ floating mechanism 561.

In Step S504, the lift hand 41 moves in the Y direction and the alignment projections 413 of the lift hand 41 are brought into contact with the peripheral edge of the ring frame Fr held by the suction hand 51. At this time, the suction hand 51 moves with respect to the XYθ floating mechanism 561 such that the alignment projections 413 follow the peripheral edge of the ring frame Fr. As a result, as shown in field of Step S504 of FIG. 10, the respective alignment projections 413 of the lift hand 41 are engaged with the respective slits Fs of the ring frame Fr and the ring frame Fr is positioned with respect to the lift hand 41.

In Step S505, the XYθ floating mechanism 561 is locked. In this way, the suction hand 51 is fixedly supported by the XYθ floating mechanism 561. Then, in Step S506, the suction of the ring frame Fr by the suction hand 51 is released and the ring frame Fr is placed on the lift hand 41. In Step S507, the XYθ floating mechanism 561 is turned off, and the suction hand 51 is supported by the Z-axis slider 56 while being fixed to the Z-axis slider 56. In this way, the ring frame Fr can be positioned with respect to the lift hand 41 (ring frame alignment).

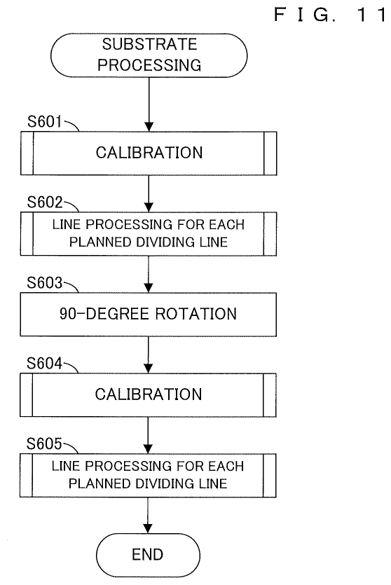

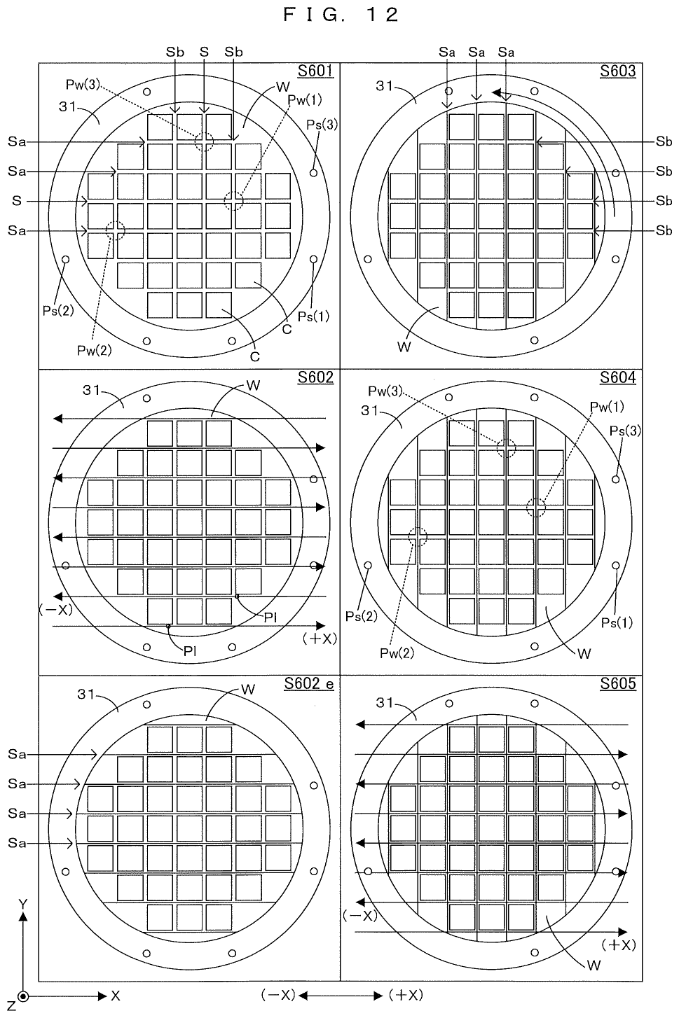

Next, the substrate processing is described in detail. FIG. 11 is a flow chart showing an example of the substrate processing, and FIG. 12 shows plan views schematically showing an example of an operation performed in accordance with the flow chart of FIG. 11. The flow chart of FIG. 11 is performed by a control of the control unit 100.

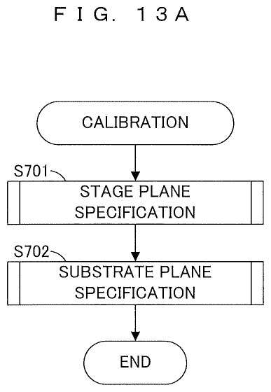

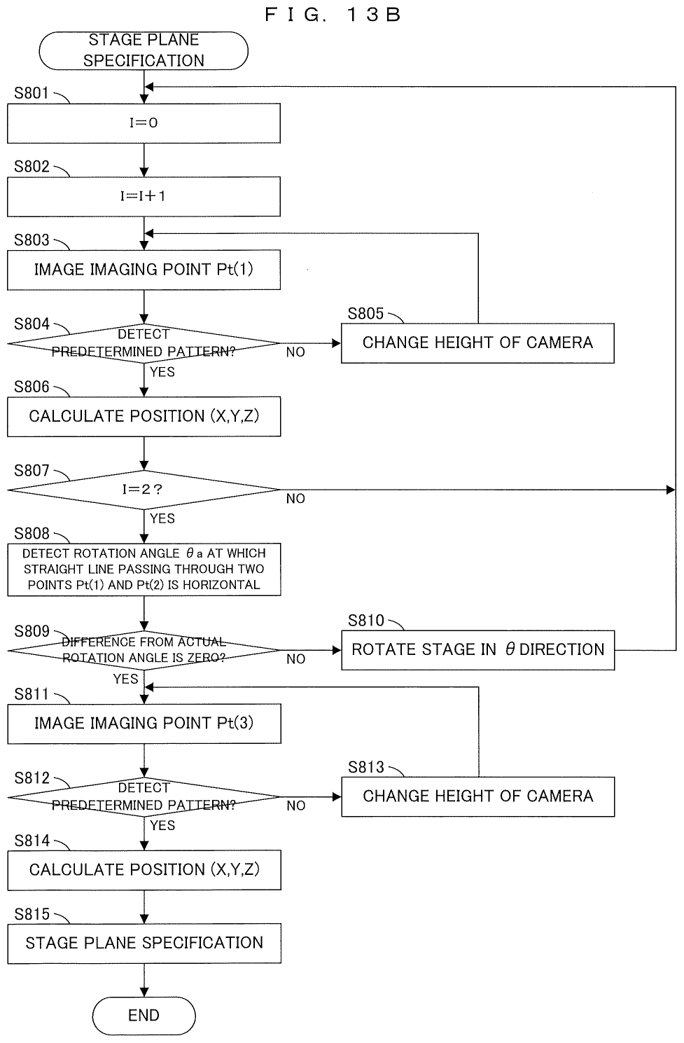

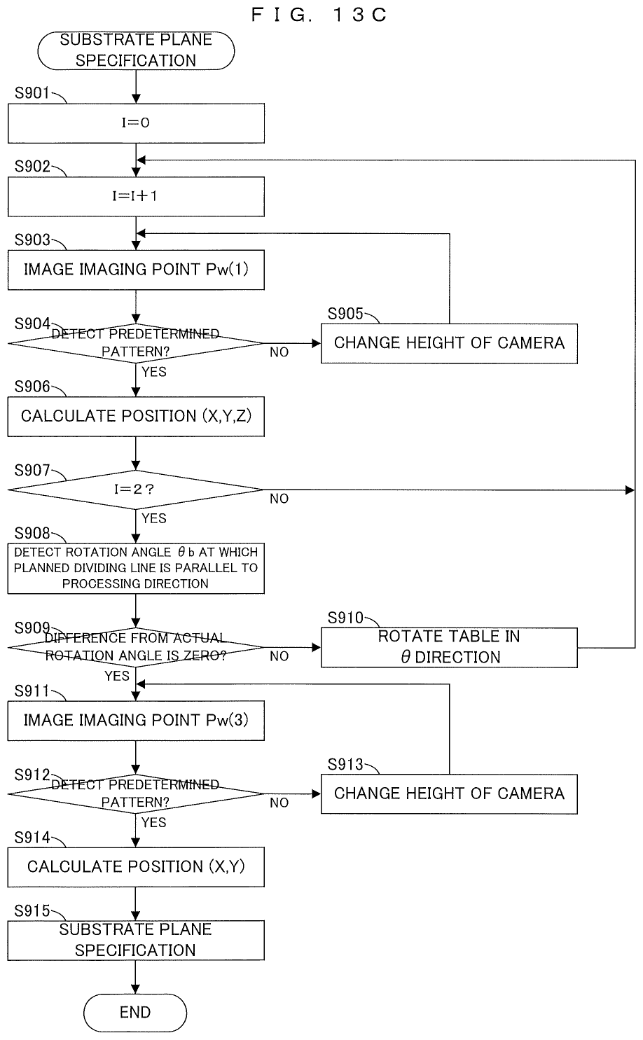

In Step S601 of the substrate processing of FIG. 11, calibration is performed to obtain a plane of the upper surface (back surface) of the semiconductor substrate W to be processed. FIG. 13A is a flow chart showing an example of the calibration, FIG. 13B is a flow chart showing an example of stage plane specification performed in the calibration of FIG. 13A, and FIG. 13C is a flow chart showing an example of substrate plane specification performed in the calibration of FIG. 13A. Note that, in the calibration of FIG. 13A, the suction plate 31 or the semiconductor substrate W is imaged as appropriate. In this description, it is assumed that imaging is performed by the imaging part 8B. However, the following operation can also be similarly performed even if imaging is performed by the imaging part 8A.

In Step S701 of the calibration of FIG. 13A, the stage plane specification (FIG. 13B) is performed. As shown in FIG. 13B, in the stage plane specification, a count value I for discriminating a plurality of (three) imaging points Ps(I) provided on the upper surface 311 of the suction plate 31 of the chuck stage 3 is reset to zero (Step S801), and the count value I is incremented by 1 (Step S802). The imaging point Ps(I) is, for example, a mark having a predetermined pattern.

In Step S803, the control unit 100 causes the imaging point Ps(I) to face the infrared camera 81 from below by adjusting the position of the chuck stage 3 by the XYθ drive table 6. In this way, the imaging point Ps(I) falls within a field of view of the infrared camera 81. In Step S803, the infrared camera 81 images this imaging point Ps(I) and obtains an image showing the imaging point Ps(I). In Step S804, the control unit 100 confirms whether or not the predetermined pattern of the imaging point Ps(I) can be detected form the image by an image processing such as pattern matching.

If a focus of the infrared camera 81 deviates from the imaging point Ps(I) and the predetermined pattern cannot be detected from the image (“NO” in Step S804), the control unit 100 changes a distance of the infrared camera 81 to the imaging point Ps(I) in the Z direction by driving the infrared camera 81 in the Z direction by the Z-axis camera motor 892 (Step S805). In this way, the focus of the infrared camera 81 is changed in the Z direction. Steps S803 to S805 are repeated until the focus of the infrared camera 81 coincides with the imaging point Ps(I) and the predetermined pattern is detected (“YES” in Step S804).

In Step S806, the control unit 100 calculates the position (X, Y, Z) of the imaging point Ps(I) based on the predetermined pattern detected from the image obtained by imaging the imaging point Ps(I). X- and Y-coordinates of the imaging point Ps(I) are calculated based on the position of the predetermined pattern included in the image. A Z-coordinate of the imaging point Ps(I) is calculated based on the position of the infrared camera 81 in the Z direction when the image, from which the predetermined pattern could be detected, was imaged.

In Step S807, it is confirmed whether or not the count value I has reached 2, i.e. the positions (X, Y, Z) of two imaging points Ps(1), Ps(2) have been obtained. If the count value I is less than 2 (“NO” in Step S807), return is made to Step S802 and Steps S802 to S806 are performed. If the count value I is 2 (“YES” in Step S807), advance is made to Step S808.

In Step S808, a rotation angle Ga for rotating the chuck stage 3 in the θ direction is so calculated that a straight line passing through the two imaging points Ps(1) and Ps(2) is horizontal. If a difference from the current rotation angle of the suction plane 31 (difference between an actual rotation angle and the rotation angle Ga) is not zero (“NO” in Step S809), the chuck stage 3 is rotated by the rotation angle Ga (Step S810) and return is made to Step S801. In this way, Steps S801 to S809 are performed.

If the difference from the current rotation angle of the suction plane 31 (difference between the actual rotation angle and the rotation angle Ga) is zero (“YES” in Step S809), advance is made to Step S811. In Step S811, the control unit 100 images the imaging point Ps(3) by the infrared camera 81 and obtains an image showing the imaging point Ps(3) in the same manner as in Step S803. In Step S812, the control unit 100 confirms whether or not a predetermined pattern included in the imaging point Ps(3) can be detected from this image by an image processing such as pattern matching.

If the predetermined pattern cannot be detected from the image (“NO” in Step S812), the control unit 100 changes a distance of the infrared camera 81 to the imaging point Ps(3) in the Z direction by driving the infrared camera 81 in the Z direction by the Z-axis camera motor 892 (Step S813). Steps S811 to S813 are repeated until the predetermined pattern is detected (“YES” in Step S812).

If the predetermined pattern can be detected in Step S812 (YES), the control unit 100 calculates the position (X, Y, Z) of the imaging point Ps(3) based on the predetermined pattern detected from the image obtained by imaging the imaging point Ps(3) (Step S814). In this way, the position (X, Y, Z) of each of the three imaging points Ps(1), Ps(2) and Ps(3) is obtained. In Step S815, a plane passing through these three positions (X, Y, Z) is specified as a plane representing the plane of the chuck stage 3, specifically the upper surface 311 of the suction plane 31.

In Step S702 of the calibration of FIG. 13A, the substrate plane specification (FIG. 13C) is performed. As shown in FIG. 13C, in the substrate plane specification, a count value I for discriminating a plurality of (three) imaging points Pw(I) of the semiconductor substrate W is reset to zero (Step S901), and the count value I is incremented by 1 (Step S902). The imaging points Pw(I) is, for example, an area having a predetermined pattern.

Specifically, as shown in FIG. 12, the semiconductor substrate W is demarcated in the form of a lattice by planned dividing lines S (Sa, Sb) orthogonal to each other. That is, the semiconductor substrate W is provided with a plurality of the planned dividing lines Sa parallel to each other and a plurality of the planned dividing lines Sb parallel to each other, and the planned dividing lines Sa and the planned dividing lines Sb are orthogonal to each other. In this way, a plurality of semiconductor chips C are arrayed in a lattice across the planned dividing lines Sa, Sb. In contrast, a region including an intersection of the planned dividing line Sa and the planned dividing line Sb (in other words, a point surrounded by the semiconductor chips C arranged on four corners) is set as the imaging point Pw(I). Note that, since the back surface of the semiconductor substrate W is facing upward as described above, the infrared camera 81 images the planned dividing lines Sa, Sb and the semiconductor chips C formed on the front surface of the semiconductor substrate W through the back surface of the semiconductor substrate W by infrared rays.

In Step S903, the control unit 100 causes the imaging point Pw(I) to face the infrared camera 81 from below by adjusting the position of the chuck stage 3 by the XYθ drive table 6. In this way, the imaging point Pw(I) falls within the field of view of the infrared camera 81. In Step S903, the infrared camera 81 images this imaging point Pw(I) and obtains an image showing the imaging point Pw(I). In Step S904, the control unit 100 confirms whether or not a predetermined pattern (e.g. an intersection pattern of the planned dividing lines Sa, Sb) included in the imaging point Pw(I) can be detected from this image by an image processing such as pattern matching.

If the focus of the infrared camera 81 deviates from the imaging point Pw(I) and the predetermined pattern cannot be detected from the image (“NO” in Step S904), the control unit 100 changes a distance of the infrared camera 81 to the imaging point Pw(I) in the Z direction by driving the infrared camera 81 in the Z direction by the Z-axis camera motor 892 (Step S905). In this way, the focus of the infrared camera 81 is changed in the Z direction. Steps S903 to S905 are repeated until the focus of the infrared camera 81 coincides with the imaging point Pw(I) and the predetermined pattern is detected (“YES” in Step S904).

Note that the plane (stage plane) representing the upper surface 311 of the suction plane 31 is specified by the previously performed stage plane specification (FIG. 13B). Accordingly, a height range in which the imaging point Pw(I) of the semiconductor substrate W placed on the suction plane 31 is present can be estimated based on this stage plane. Therefore, in Step S805, the height of the infrared camera 81 is so changed that the focus of the infrared camera 81 falls within a presence range of the imaging point Pw(I) estimated from the stage plane.

In Step S906, the control unit 100 calculates the position (X, Y, Z) of the imaging point Pw(I) based on the predetermined pattern detected from the image obtained by imaging the imaging point Pw(I). X- and Y-coordinates of the imaging point Pw(I) are calculated based on the position of the predetermined pattern included in the image. A Z-coordinate of the imaging point Pw(I) is calculated based on the position of the infrared camera 81 in the Z direction when the image, from which the predetermined pattern could be detected, was imaged.

In Step S907, it is confirmed whether or not the count value I has reached 2, i.e. the positions (X, Y, Z) of two imaging points Ps(1), Ps(2) have been obtained. If the count value I is less than 2 (“NO” in Step S907), return is made to Step S902 and Steps S902 to S906 are performed. If the count value I is 2 (“YES” in Step S902), advance is made to Step S908.

In Step S908, a rotation angle θb for rotating the chuck stage 3 in the θ direction is so calculated based on the two imaging points Pw(1), Pw(2) that the planned dividing lines Sa are parallel to the X direction (processing direction). If a difference from the current rotation angle of the suction plane 31 (difference between an actual rotation angle and the rotation angle θb) is not zero (“NO” in Step S909), the chuck stage 3 is rotated by the rotation angle θb (Step S910) and return is made to Step S901. In this way, Steps S901 to S909 are performed.

If the difference from the current rotation angle of the suction plane 31 (difference between the actual rotation angle and the rotation angle θb) is zero (“YES” in Step S909), advance is made to Step S911. In Step S911, the control unit 100 images the imaging point Pw(3) by the infrared camera 81 and obtain an image showing the imaging point Pw(3) in the same manner as in Step S903. In Step S912, the control unit 100 confirms whether or not a predetermined pattern included in the imaging point Pw(3) can be detected from this image by an image processing such as pattern matching.

If the predetermined pattern cannot be detected from the image (“NO” in Step S912), the control unit 100 changes a distance of the infrared camera 81 to the imaging point Pw(3) in the Z direction by driving the infrared camera 81 in the Z direction by the Z-axis camera motor 892 (Step S913). Steps S911 to S913 are repeated until the predetermined pattern is detected (“YES” in Step S912). At this time, a range for changing the height of the infrared camera 81 is set based on the stage plane as in the aforementioned case.

If the predetermined pattern can be detected in Step S912 (YES), the control unit 100 calculates the position (X, Y, Z) of the imaging point Pw(3) based on the predetermined pattern detected from the image obtained by imaging the imaging point Pw(3)(Step S914). In this way, the position (X, Y, Z) of each of the three imaging points Pw(1), Pw(2) and Pw(3) is obtained. In Step S915, a plane passing through these three positions (X, Y, Z) is specified as a plane representing the semiconductor substrate W.

Referring back to FIG. 11, description is continued. If the semiconductor substrate W is so positioned that the planned dividing lines Sa are parallel to the X direction and the plane representing the semiconductor substrate W is specified by performing the calibration described above (Step S601), line processing (Step S602) is performed for each planned dividing line Sa. That is, each of the plurality of planned dividing lines Sa is processed by the laser beam B by performing the line processing for irradiating the laser beam B to the laser irradiation position Lb while moving the laser irradiation position Lb in the X direction along the target planned dividing line Sa while changing the target planned dividing line Sa, out of the plurality of planned dividing lines Sa. Particularly, as shown in field of Step S602 of FIG. 12, the line processing of moving the laser irradiation position Lb toward the (+X) in the X direction and the line processing of moving the laser irradiation position Lb toward the (−X) side in the X direction are alternately performed.

At this time, a movement of the laser beam B toward the (+X) side with respect to the planned dividing line Sa is performed by driving the chuck stage 3 holding the semiconductor substrate W toward the (−X) side by the X-axis driver 65, and a movement of the laser beam B toward the (−X) side with respect to the planned dividing line Sa is performed by driving the chuck stage 3 holding the semiconductor substrate W toward the (+X) side by the X-axis driver 65. Further, the target planned dividing line Sa of the line processing is changed by driving the chuck stage 3 holding the semiconductor substrate W in the Y direction by the Y-axis driver 63. Further, the control unit 100 executes a control of adjusting the position in the Z direction of the infrared camera 81 by the Z-axis camera motor 892 based on the plane representing the semiconductor substrate W specified by the calibration of Step S601. In this way, a condensing position of the laser beam B is adjusted to the inside of the semiconductor substrate W and a modified layer is formed inside the semiconductor substrate W along the planned dividing lines Sa.

If the line processing for each of the plurality of planned dividing lines Sa is completed in this way (Step S602), the chuck stage 3 holding the semiconductor substrate W is rotated by 90° in the θ direction by the θ-axis table motor 66. In this way, a switch is performed from a state where the plurality of planned dividing lines Sa, to which the line processing had been performed, are positioned in parallel to the X direction (field of “S602_e” of FIG. 12) to a state where the plurality of planned dividing lines Sb are positioned in parallel to the X direction (field of “S603” of FIG. 12).

In Step S604, the calibration is performed as in Step S601 described above. Further, in Step S605, the line processing is performed for each of the plurality of planned dividing lines Sb as in Step S602 described above.

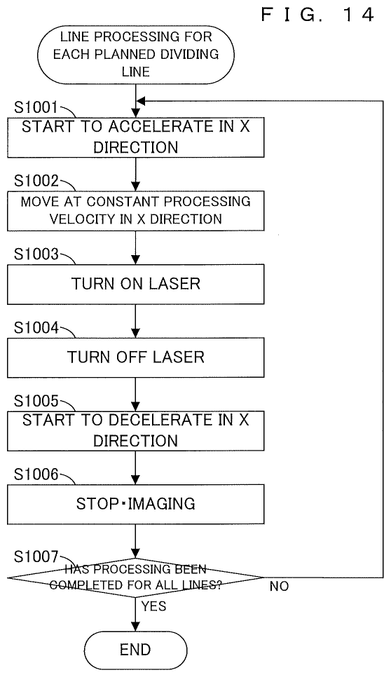

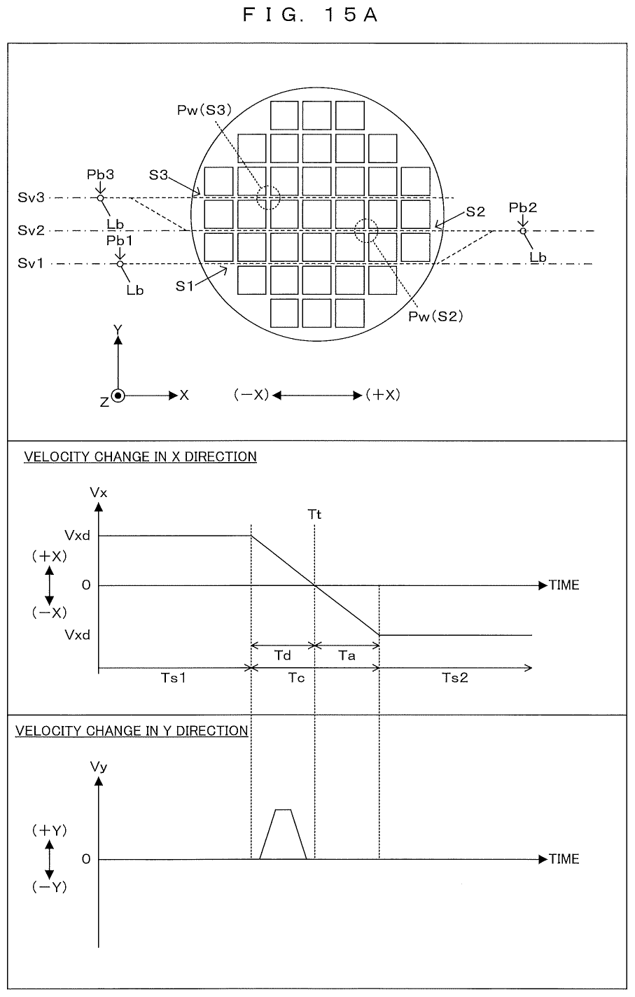

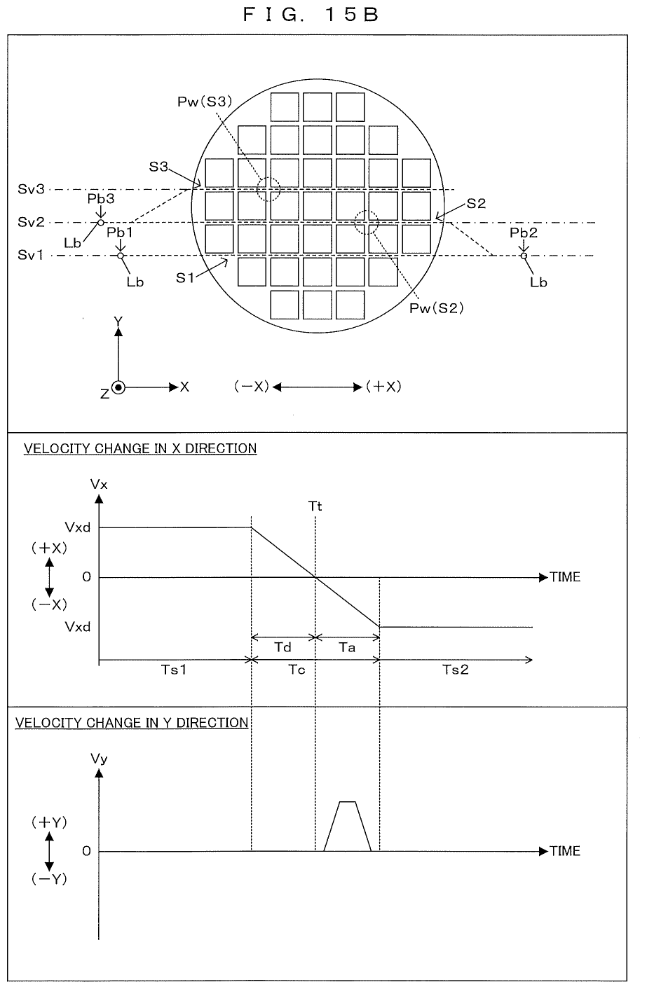

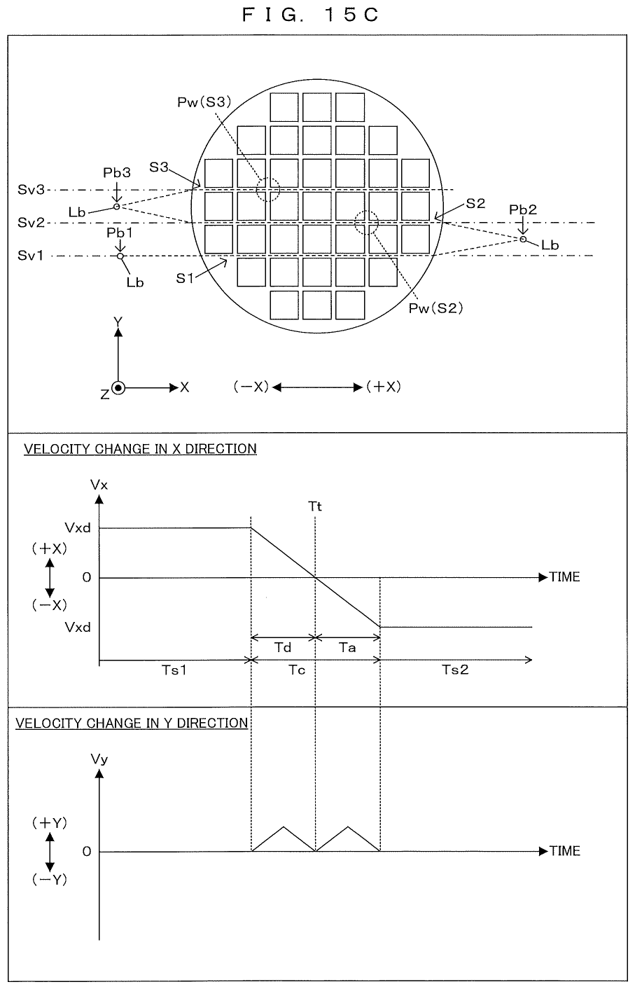

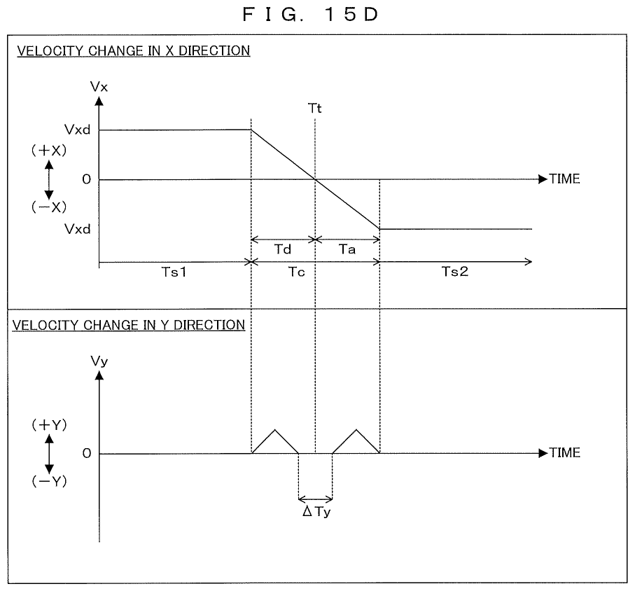

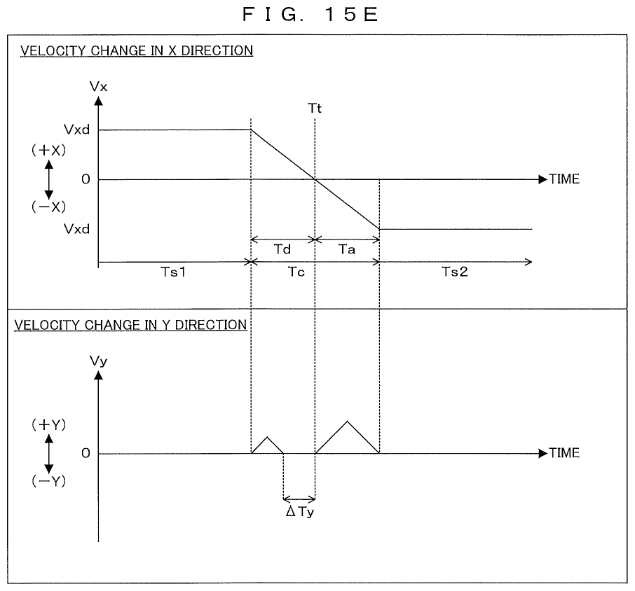

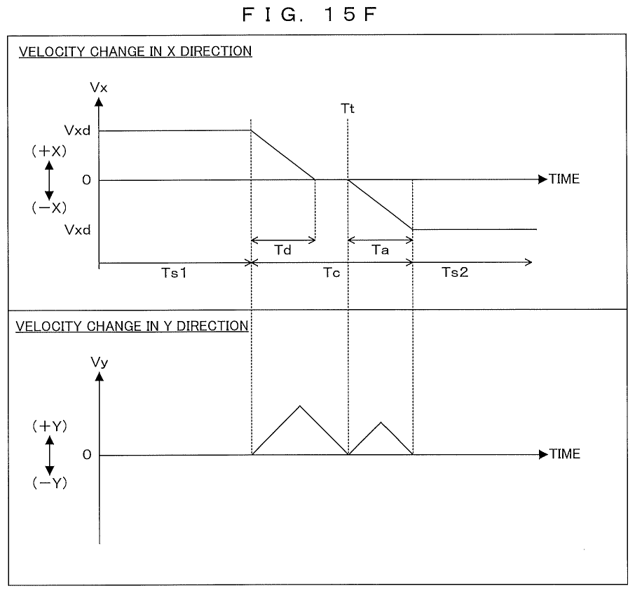

FIG. 14 is a flow chart showing a basic process of the line processing for each planned dividing line, and FIG. 15A shows charts schematically showing a first example of an operation performed in accordance with the flow chart of FIG. 14. In FIG. 15A, a trace of the laser irradiation position Lb relatively moving with respect to the semiconductor substrate W is shown by dotted line, and virtual straight lines Sv1, Sv2, Sv3 extended in parallel to the X direction along the planned dividing lines S1, S2, S3 between both outer sides of the planned dividing lines S1, S2, S3 are shown by one-dot chain line. Note that dotted lines representing the trace of the laser irradiation position Lb are preferentially shown in parts where the trace of the laser irradiation position Lb and the virtual straight lines Sv1, Sv2, Sv3 overlap.

In the example shown in FIG. 15A, the flow chart of FIG. 14 is started from a state where the laser irradiation position Lb is stopped at a position Pb1 on the (−X) side of the semiconductor substrate W in the X direction. This position Pb1 is a position provided on the virtual straight line Sv1 along the planned dividing line S1, in other words, facing the planned dividing line S1 from the X direction. However, the position of the laser irradiation position Lb when the flow chart of FIG. 14 is started is not limited to this example and can be changed as appropriate.

In Step S1001, the laser irradiation position Lb stopped at the position Pb1 starts to accelerate toward the (+X) side in the X direction and moves in parallel to the X direction. Thereby, the laser irradiation position Lb moves toward the (+X) side along the virtual straight line Sv1. If a velocity Vx of the laser irradiation position Lb increases to a processing velocity Vxd by the time the laser irradiation position Lb reaches an end of the semiconductor substrate W on the (−X) side, the laser irradiation position Lb moves at the constant processing velocity Vxd toward the (+X) side in the X direction (Step S1002).

Further, the laser light source 72 is turned on and the irradiation of the laser beam B to the laser irradiation position Lb from the processing head 71 is started in accordance with a timing at which the laser irradiation position Lb reaches the end of the semiconductor substrate Won the (−X) side (Step S1003). Further, the laser light source 72 is turned off and the irradiation of the laser beam B to the laser irradiation position Lb from the processing head 71 is finished in accordance with a timing at which the laser irradiation position Lb reaches an end of the semiconductor substrate W on the (+X) side (Step S1004). In this way, during a period from Step S1003 to Step S1004, the laser processing is performed for the planned dividing line S1 by irradiating the laser beam B to the laser irradiation position Lb while moving the laser irradiation position Lb toward the (+X) side along the planned dividing line S1 (line processing).

If the laser irradiation position Lb passes through the planned dividing line S1 toward the (+X) side, the laser irradiation position Lb starts to decelerate toward the (+X) side in the X direction (Step S1005) and stops at a position Pb2 on the (+X) side of the semiconductor substrate W in the X direction (Step S1006). This position Pb2 is a position provided on the virtual straight line Sv2 adjacent to the virtual straight line Sv1 in the Y direction, in other words, facing the planned dividing line S2 from the X direction. That is, in Steps S1005 to S1006, the laser irradiation position Lb moves in the Y direction from the virtual straight line Sv1 to the virtual straight line Sv2 in parallel with deceleration in the X direction.

A positional relationship of the imaging ranges Ri (FIG. 1) of the imaging parts 8A, 8B and the laser irradiation position Lb of the processing head 71 is fixed. Thus, in Steps S1001 to S1006, the imaging ranges Ri also relatively move with respect to the semiconductor substrate W as the laser irradiation position Lb relatively moves with respect to the semiconductor substrate W. With the laser irradiation position Lb stopped at the position Pb2, the imaging range Ri of the imaging part 8B stops at a position including at least an imaging point Pw(S2). This imaging point Pw(S2) is an intersection where the planned dividing line S2 and the planned dividing line S orthogonal to the line S2 intersect in the semiconductor substrate W. Accordingly, in Step S1006, the control unit 100 causes the imaging part 8B to image the imaging range Ri and obtains an image including the imaging point Pw(S2). Thereby, the control unit 100 can obtain an image showing the position of the unprocessed planned dividing line S2.

In Step S1007, it is confirmed whether or not the laser processing has been completed for the plurality of planned dividing lines S parallel to the X direction. If there is any unprocessed planned dividing line S, out of these planned dividing lines S (“NO” in Step S1007), return is made to Step S1001.

In the example of FIG. 15A, in Step S1001, the laser irradiation position Lb stopped at the position Pb2 starts to accelerate toward the (−X) side in the X direction and moves in parallel to the X direction. Thereby, the laser irradiation position Lb moves toward the (−X) side along the virtual straight line Sv2. If the velocity Vx of the laser irradiation position Lb increases to the processing velocity Vxd by the time the laser irradiation position Lb reaches the end of the semiconductor substrate W on the (+X) side, the laser irradiation position Lb moves at the constant processing velocity Vxd toward the (−X) side in the X direction (Step S1002).

Here, a position where the laser irradiation position Lb having passed through the planned dividing line S1 toward the (+X) side starts to decelerate (in other words, an X-coordinate at which the constant velocity movement toward (+X) side is finished) and a position where the laser irradiation position Lb accelerating toward the (−X) side toward the planned dividing line S finishes acceleration (in other words, an X-coordinate at which the constant velocity movement toward (−X) side is started) coincide. That is, the X-coordinate at which the constant velocity movement of the laser irradiation position Lb having passed through the planned dividing line Sn, to which the line processing is to be performed in the n^{th} turn, is finished and deceleration is started and the X direction at which the laser irradiation position Lb moving toward the planned dividing line Sn+1, to which the line processing is to be performed in the (n+1)^{th} turn, finishes the acceleration and starts the constant velocity movement coincide.

Further, the laser light source 72 is turned on and the irradiation of the laser beam B to the laser irradiation position Lb from the processing head 71 is started in accordance with a timing at which the laser irradiation position Lb reaches the end of the semiconductor substrate Won the (+X) side (Step S1003). Further, the laser light source 72 is turned off and the irradiation of the laser beam B to the laser irradiation position Lb from the processing head 71 is finished in accordance with a timing at which the laser irradiation position Lb reaches the end of the semiconductor substrate W on the (−X) side (Step S1004). In this way, during a period from Step S1003 to Step S1004, the laser processing is performed for the planned dividing line S2 by irradiating the laser beam B to the laser irradiation position Lb while moving the laser irradiation position Lb toward the (−X) side along the planned dividing line S2 (line processing).

If the laser irradiation position Lb passes through the planned dividing line S2 toward the (−X) side, the laser irradiation position Lb starts to decelerate toward the (−X) side in the X direction (Step S1005) and stops at a position Pb3 on the (−X) side of the semiconductor substrate W in the X direction (Step S1006). This position Pb3 is a position provided on the virtual straight line Sv3 adjacent to the virtual straight line Sv2 in the Y direction, in other words, facing the planned dividing line S3 from the X direction. That is, in Steps S1005 to S1006, the laser irradiation position Lb moves in the Y direction from the virtual straight line Sv2 to the virtual straight line Sv3 in parallel with deceleration in the X direction.

With the laser irradiation position Lb stopped at the position Pb3, the imaging range Ri of the imaging part 8A stops at a position including at least an imaging point Pw(S3). This imaging point Pw(S3) is an intersection of the planned dividing line S3 and the planned dividing line S orthogonal to this line S3 in the semiconductor substrate W. Accordingly, in Step S1006, the control unit 100 causes the imaging part 8A to image the imaging range Ri and obtains an image including the imaging point Pw(S3). In this way, the control unit 100 can obtain an image showing the position of the unprocessed planned dividing line S3.

Steps S1001 to S1007 are repeated until it is confirmed that the line processing has been completed for the plurality of planned dividing lines S (S1, S2, S3, . . . ) parallel to the X direction (“YES” in Step S1007).

Next, a velocity change of the laser irradiation position Lb is described with reference to “Velocity Change in X Direction” and “Velocity Change in Y Direction” of FIG. 15A. Here, the velocity Vx indicates a velocity to move the laser irradiation position Lb in the X direction with respect to the semiconductor substrate W, and a velocity Vy indicates a velocity to move the laser irradiation position Lb in the Y direction with respect to the semiconductor substrate W. Further, the processing velocity Vxd indicates a velocity to move the laser irradiation position Lb at a constant velocity in the X direction along the planned dividing line S (i.e. the velocity Vx), and is represented by an absolute value regardless of the movement toward the (+X) side or the movement toward the (−X) side.

In a line processing period Ts1 (Steps S1002 to S1004) during which the line processing of moving the laser beam B toward the (+X) side along the planned dividing line S1 is performed, the laser irradiation position Lb does not move in the Y direction while moving at the constant processing velocity Vxd in the X direction. Further, in a line processing period Ts2 (Steps S1002 to S1004) during which the line processing of moving the laser beam B toward the (−X) side along the planned dividing line S2 is performed, the laser irradiation position Lb does not move in the Y direction while moving at the constant processing velocity Vxd in the X direction.

In a switching period Tc (Steps S1005, S1006 and S1001) during which a switch is performed from the line processing period Ts1 to the line processing period Ts2, the following operation is performed. That is, the X-axis driver 65 (processing-axis driver) performs reverse drive to bring the laser irradiation position Lb to the planned dividing line S2 (second processing line) by accelerating the laser irradiation position Lb toward the (−X) side (Step S1001) after decelerating and stopping the laser irradiation position Lb, which has passed through the planned dividing line S1 (first processing line) toward the (+X) side (first side), toward the (+X) side in the X direction (processing direction) (Step S1005). In parallel with this reverse drive, the Y-axis driver 63 (feeding-axis driver) moves the laser irradiation position Lb in the Y direction (feeding direction) from the virtual straight line Sv1 (first virtual straight line) extended in the X direction to the outside of the planned dividing line S1 along the planned dividing line S1 to the virtual straight line Sv2 (second virtual straight line) extended in the X direction to the outside of the planned dividing line S2 along the planned dividing line S2 (second processing line).

Particularly, the switching period Tc includes a deceleration period Td (Step S1005) for decelerating the laser irradiation position Lb in the X direction and an acceleration period Ta (Step S1001) for accelerating the laser irradiation position Lb in the X direction, and a movement of the laser irradiation position Lb in the Y direction is performed during the deceleration period Td, out of the deceleration period Td and the acceleration period Ta. Specifically, the movement of the laser irradiation position Lb in the Y direction is started after the start of the deceleration period Td, and he movement of the laser irradiation position Lb in the Y direction is finished before the end of the deceleration period Td. Further, the laser irradiation position Lb does not move in the Y direction in the acceleration period Ta.

Here, a start point of the deceleration period Td indicates a point of time at which the deceleration of the laser irradiation position Lb in the X direction is started (in other words, a decrease of the absolute value of the velocity Vx from the processing velocity Vxd is started), and an end point of the deceleration period Td indicates a point of time at which the velocity of the laser irradiation position Lb in the X direction (in other words, the velocity Vx) becomes zero. A start point of the acceleration period Ta indicates a point of time at which the acceleration of the laser irradiation position Lb in the X direction is started (in other words, an increase of the absolute value of the velocity Vx from zero is started), and an end point of the acceleration period Ta indicates a point of time at which the acceleration of the laser irradiation position Lb in the X direction is finished (in other words, a point of time at which the absolute value of the velocity Vx becomes the processing velocity Vxd).

Further, in a stop period Tt provided on the way during a transition from the acceleration period Ta to the deceleration period Td, both the velocity Vx of the laser irradiation position Lb in the X direction and the velocity Vy thereof in the Y direction become zero and the laser irradiation position Lb is stopped at the position Pb2 with respect to the semiconductor substrate W. In this stop period Tt, the imaging ranges Ri of the imaging parts 8A, 8B are also stopped with respect to the semiconductor substrate W. Particularly, the imaging range Ri of the imaging part 8B is located on the (−X) side of the laser irradiation position Lb located on the (+X) side of the semiconductor substrate W and overlaps the semiconductor substrate W. Accordingly, the infrared camera 81 of the imaging part 8B images a part of the semiconductor substrate W overlapping the imaging range Ri in the stop period Tt (Step S1006).

FIG. 15B shows charts schematically showing a second example of the operation performed in accordance with the flow chart of FIG. 14. Notation in FIG. 15B is similar to that in FIG. 15A. Also in FIG. 15B, the laser processing is performed in turn for the planned dividing lines S1, S2, S3 in accordance with the flow chart of FIG. 14 as in FIG. 15A. However, FIG. 15B differs from FIG. 15A in the operation in the switching period Tc for changing the planned dividing line S to be laser processed. Accordingly, the following description is centered on differences from FIG. 15A and common operation parts are denoted by corresponding reference signs and description is omitted as appropriate.

If the laser irradiation position Lb passes through the planned dividing line S1 toward the (+X) side as the laser processing for the planned dividing line S1 is finished, the laser irradiation position Lb starts to decelerate toward the (+X) side in the X direction (Step S1005) and stops at a position Pb2 on the (+X) side of the semiconductor substrate W in the X direction (Step S1006). This position Pb2 is a position provided on the virtual straight line Sv1. Further, with the laser irradiation position Lb stopped at the position Pb2, the imaging range Ri of the imaging part 8B stops at a position including at least an imaging point Pw(S2). Accordingly, in Step S1006, the control unit 100 causes the imaging part 8B to image the imaging range Ri and obtains an image including the imaging point Pw(S2). In this way, the control unit 100 can obtain the image showing the position of the unprocessed planned dividing line S2.

Subsequently, the laser irradiation position Lb stopped at the position Pb2 starts to accelerate toward the (−X) side in the X direction (Step S1001). If the velocity Vx of the laser irradiation position Lb increases to the processing velocity Vxd by the time the laser irradiation position Lb reaches the end of the semiconductor substrate W on the (+X) side, the laser irradiation position Lb moves at the constant processing velocity Vxd toward the (−X) side in the X direction (Step S1002). Further, in a period from the start of acceleration to the start of constant movement at the processing velocity Vxd of the laser irradiation position Lb, the laser irradiation position Lb moves in the Y direction from the virtual straight line Sv1 to the virtual straight line Sv2. That is, in Steps S1001 to S1002, the laser irradiation position Lb moves in the Y direction from the virtual straight line Sv1 to the virtual straight line Sv2 in parallel with acceleration in the X direction. In this way, the laser irradiation position Lb reaches the planned dividing line S2 and the line processing for the planned dividing line S2 can be started.

If the laser irradiation position Lb passes through the planned dividing line S2 toward the (−X) side as the laser processing for the planned dividing line S2 is finished, the laser irradiation position Lb starts to decelerate toward the (−X) side in the X direction (Step S1005) and stops at a position Pb3 on the (−X) side of the semiconductor substrate W in the X direction (Step S1006). This position Pb3 is a position provided on the virtual straight line Sv2. Further, with the laser irradiation position Lb stopped at the position Pb3, the imaging range Ri of the imaging part 8A stops at a position including at least an imaging point Pw(S3). Accordingly, in Step S1006, the control unit 100 causes the imaging part 8A to image the imaging range Ri and obtains an image including the imaging point Pw(S3). In this way, the control unit 100 can obtain the image showing the position of the unprocessed planned dividing line S3.

Next, a velocity change of the laser irradiation position Lb is described with reference to “Velocity Change in X Direction” and “Velocity Change in Y Direction” of FIG. 15B. In a line processing period Ts1 (Steps S1002 to S1004) during which the line processing of moving the laser beam B toward the (+X) side along the planned dividing line S1 is performed, the laser irradiation position Lb does not move in the Y direction while moving at the constant processing velocity Vxd in the X direction. Further, in a line processing period Ts2 (Steps S1002 to S1004) during which the line processing of moving the laser beam B toward the (−X) side along the planned dividing line S2 is performed, the laser irradiation position Lb does not move in the Y direction while moving at the constant processing velocity Vxd in the X direction.

Further, in a switching period Tc (Steps S1005, S1006 and S1001) during which a switch is performed from the line processing period Ts1 to the line processing period Ts2, the laser irradiation position Lb is moved in the Y direction (feeding direction) from the virtual straight line Sv1 to the virtual straight line Sv2 in parallel with performing the reverse drive in the X direction as in the aforementioned case. Particularly, a movement of the laser irradiation position Lb in the Y direction is performed during an acceleration period Ta, out of a deceleration period Td and the acceleration period Ta included in the switching period Tc. Specifically, the movement of the laser irradiation position Lb in the Y direction is started after the start of the acceleration period Ta, and the movement of the laser irradiation position Lb in the Y direction is finished before the end of the acceleration period Ta. Further, the laser irradiation position Lb does not move in the Y direction in the deceleration period Td.

Further, in a stop period Tt provided on the way during a transition from the acceleration period Ta to the deceleration period Td, both the velocity Vx of the laser irradiation position Lb in the X direction and the velocity Vy thereof in the Y direction become zero and the laser irradiation position Lb is stopped at the position Pb2 with respect to the semiconductor substrate W. In this stop period Tt, the imaging ranges Ri of the imaging parts 8A, 8B are also stopped with respect to the semiconductor substrate W. Particularly, the imaging range Ri of the imaging part 8B is located on the (−X) side of the laser irradiation position Lb located on the (+X) side of the semiconductor substrate W and overlaps the semiconductor substrate W. Accordingly, the infrared camera 81 of the imaging part 8B images a part of the semiconductor substrate W overlapping the imaging range Ri in the stop period Tt (Step S1006).

FIG. 15C shows charts schematically showing a third example of the operation performed in accordance with the flow chart of FIG. 14. Notation in FIG. 15C is similar to that in FIG. 15A. Also in FIG. 15C, the laser processing is performed in turn for the planned dividing lines S1, S2, S3 in accordance with the flow chart of FIG. 14 as in FIG. 15A. However, FIG. 15C differs from FIG. 15A in the operation in the switching period Tc for changing the planned dividing line S to be laser processed. Accordingly, the following description is centered on differences from FIG. 15A and common operation parts are denoted by corresponding reference signs and description is omitted as appropriate.

If the laser irradiation position Lb passes through the planned dividing line S1 toward the (+X) side as the laser processing for the planned dividing line S1 is finished, the laser irradiation position Lb starts to decelerate toward the (+X) side in the X direction (Step S1005) and stops at a position Pb2 on the (+X) side of the semiconductor substrate W in the X direction (Step S1006). This position Pb2 is provided between the virtual straight lines Sv1 and Sv2 in the Y direction. That is, in Steps S1005 to S1006, the laser irradiation position Lb moves in the Y direction from the virtual straight line Sv1 to the position Pb2 in parallel with deceleration in the X direction. Further, with the laser irradiation position Lb stopped at the position Pb2, the imaging range Ri of the imaging part 8B stops at a position including at least an imaging point Pw(S2). Accordingly, in Step S1006, the control unit 100 causes the imaging part 8B to image the imaging range Ri and obtains an image including the imaging point Pw(S2). In this way, the control unit 100 can obtain the image showing the position of the unprocessed planned dividing line S2.

Subsequently, the laser irradiation position Lb stopped at the position Pb2 starts to accelerate toward the (−X) side in the X direction (Step S1001). If the velocity Vx of the laser irradiation position Lb increases to the processing velocity Vxd by the time the laser irradiation position Lb reaches the end of the semiconductor substrate W on the (+X) side, the laser irradiation position Lb moves at the constant processing velocity Vxd toward the (−X) side in the X direction (Step S1002). Further, in a period from the start of acceleration to the start of constant movement at the processing velocity Vxd of the laser irradiation position Lb, the laser irradiation position Lb moves in the Y direction from the position Pb2 to the virtual straight line Sv2. That is, in Steps S1001 to S1002, the laser irradiation position Lb moves in the Y direction from the position Pb2 to the virtual straight line Sv2 in parallel with acceleration in the X direction. In this way, the laser irradiation position Lb reaches the planned dividing line S2 and the line processing for the planned dividing line S2 can be started.

If the laser irradiation position Lb passes through the planned dividing line S2 toward the (−X) side as the laser processing for the planned dividing line S2 is finished, the laser irradiation position Lb starts to decelerate toward the (−X) side in the X direction (Step S1005) and stops at a position Pb3 on the (−X) side of the semiconductor substrate W in the X direction (Step S1006). This position Pb3 is provided between the virtual straight line Sv2 and the virtual straight line Sv3. That is, in Steps S1005 to S1006, the laser irradiation position Lb moves in the Y direction from the virtual straight line Sv2 to the position Pb3 in parallel with deceleration in the X direction. Further, with the laser irradiation position Lb stopped at the position Pb3, the imaging range Ri of the imaging part 8A stops at a position including at least the imaging point Pw(S3). Accordingly, in Step S1006, the control unit 100 causes the imaging part 8A to image the imaging range Ri and obtains an image including the imaging point Pw(S3). In this way, the control unit 100 can obtain the image showing the position of the unprocessed planned dividing line S3.

Next, a velocity change of the laser irradiation position Lb is described with reference to “Velocity Change in X Direction” and “Velocity Change in Y Direction” of FIG. 15C. In a line processing period Ts1 (Steps S1002 to S1004) during which the line processing of moving the laser beam B toward the (+X) side along the planned dividing line S1 is performed, the laser irradiation position Lb does not move in the Y direction while moving at the constant processing velocity Vxd in the X direction. Further, in a line processing period Ts2 (Steps S1002 to S1004) during which the line processing of moving the laser beam B toward the (−X) side along the planned dividing line S2 is performed, the laser irradiation position Lb does not move in the Y direction while moving at the constant processing velocity Vxd in the X direction.

Further, in a switching period Tc (Steps S1005, S1006 and S1001) during which a switch is performed from the line processing period Ts1 to the line processing period Ts2, the laser irradiation position Lb is moved in the Y direction (feeding direction) from the virtual straight line Sv1 to the virtual straight line Sv2 in parallel with performing the reverse drive in the X direction as in the aforementioned case. Particularly, this movement of the laser irradiation position Lb is performed by way of the position Pb2.

That is, the laser irradiation position Lb moves in the Y direction from the virtual straight line Sv1 to the position Pb2 in a deceleration period Td, out of the deceleration period Td and an acceleration period Ta included in the switching period Tc, and moves in the Y direction from the position Pb2 to the virtual straight line Sv2 in the acceleration period Ta. Specifically, the laser irradiation position Lb starts to move from the virtual straight line Sv1 to the position Pb2 simultaneously with the start of the deceleration period Td, and reaches the position Pb2 simultaneously with the end of the deceleration period Td. Further, the laser irradiation position Lb starts to move from the position Pb2 to the virtual straight line Sv2 simultaneously with the start of the acceleration period Ta, and reaches the virtual straight line Sv2 simultaneously with the end of the acceleration period Ta.

Further, in a stop period Tt provided on the way during a transition from the acceleration period Ta to the deceleration period Td, both the velocity Vx of the laser irradiation position Lb in the X direction and the velocity Vy thereof in the Y direction become zero and the laser irradiation position Lb is stopped at the position Pb2 with respect to the semiconductor substrate W. In this stop period Tt, the imaging ranges Ri of the imaging parts 8A, 8B are also stopped with respect to the semiconductor substrate W. Particularly, the imaging range Ri of the imaging part 8B is located on the (−X) side of the laser irradiation position Lb located on the (+X) side of the semiconductor substrate W and overlaps the semiconductor substrate W. Accordingly, the infrared camera 81 of the imaging part 8B images a part of the semiconductor substrate W overlapping the imaging range Ri in the stop period Tt (Step S1006).

Note that, the specific manner of moving the laser irradiation position Lb from the position Pb2 to the virtual straight line Sv2 in the Y direction after moving the laser irradiation position Lb from the virtual straight line Sv1 to the position Pb2 in the Y direction in the switching period Tc is not limited to the example of FIG. 15C, and the movement can be performed in manners shown in FIG. 15D, FIG. 15E and FIG. 15F.

FIG. 15D shows charts schematically showing a fourth example of the operation performed in accordance with the flow chart of FIG. 14, FIG. 15E shows charts schematically showing a fifth example of the operation performed in accordance with the flow chart of FIG. 14 and FIG. 15F shows charts schematically showing a sixth example of the operation performed in accordance with the flow chart of FIG. 14. Notation in FIGS. 15D to 15F is similar to that in FIG. 15C. FIGS. 15D to 15F differ from FIG. 15C in a movement mode of the laser irradiation position Lb in the switching period Tc.

Accordingly, the following description is centered on differences from FIG. 15C and common operation parts are denoted by corresponding reference signs and description is omitted as appropriate.

In the fourth example shown in FIG. 15D, the laser irradiation position Lb starts to move in the Y direction from the virtual straight line Sv1 to the position Pb2 simultaneously with the start of the deceleration period Td, and reaches the position Pb2 and stops at the position Pb2 in the Y direction (i.e. the velocity Vy is zero) before the end of the deceleration period Td. However, after the laser irradiation position Lb reaches the position Pb2 in the Y direction, the deceleration period Td continues and the laser irradiation position Lb continues to move in the X direction. Further, the laser irradiation position Lb starts to move in the Y direction from the position Pb2 to the virtual straight line Sv2 after the start of the acceleration period Ta and reaches the virtual straight line Sv2 simultaneously with the end of the acceleration period Ta. That is, in a period ΔTy from the midway of the deceleration period Td to the midway of the acceleration period Ta, the laser irradiation position Lb is stopped in the Y direction (i.e. the velocity Vy is zero).

In the fifth example shown in FIG. 15E, the laser irradiation position Lb starts to move in the Y direction from the virtual straight line Sv1 to the position Pb2 simultaneously with the start of the deceleration period Td, and reaches the position Pb2 and stops at the position Pb2 in the Y direction (i.e. the velocity Vy is zero) before the end of the deceleration period Td. However, after the laser irradiation position Lb reaches the position Pb2 in the Y direction, the deceleration period Td continues and the laser irradiation position Lb continues to move in the X direction. Further, the laser irradiation position Lb starts to move in the Y direction from the position Pb2 to the virtual straight line Sv2 simultaneously with the start of the acceleration period Ta, and reaches the virtual straight line Sv2 simultaneously with the end of the acceleration period Ta. That is, in a period ΔTy from the midway of the deceleration period Td to the start of the acceleration period Ta, the laser irradiation position Lb is stopped in the Y direction (i.e. the velocity Vy is zero).

In the fifth example shown in FIG. 15F, the laser irradiation position Lb starts to move in the Y direction from the virtual straight line Sv1 to the position Pb2 simultaneously with the start of the deceleration period Td. However, the laser irradiation position Lb has not reached the position Pb2 in the Y direction at the end point of the deceleration period Td. Note that, at the end point of the deceleration period Td, the position (i.e. X-coordinate) of the laser irradiation position Lb and the position (i.e. X-coordinate) of the position Pb2 coincide in the X direction. Accordingly, the laser irradiation position Lb continues to move in the Y direction toward the position Pb2 also after the end of the deceleration period Ta. Further, the laser irradiation position Lb is stopped in the X direction (i.e. the velocity Vx is zero) while the laser irradiation position Lb is moving in the Y direction toward the position Pb2 after the end of the deceleration period Td. The acceleration period Ta is started and the laser irradiation position Lb starts to move in the Y direction from the position Pb2 to the virtual straight line Sv2 at the same time as the laser irradiation position Lb reaches the position Pb2. Further, the laser irradiation position Lb reaches the virtual straight line Sv2 simultaneously with the end of the acceleration period Ta.

FIG. 15G shows charts schematically showing a seventh example of the operation performed in accordance with the flow chart of FIG. 14. Notation in FIG. 15G is similar to that in FIG. 15A. Also in FIG. 15G, the laser processing is performed in turn for the planned dividing lines S1, S2, S3 in accordance with the flow chart of FIG. 14 as in FIG. 15A. However, FIG. 15G differs from FIG. 15A in the operation in the switching period Tc for changing the planned dividing line S to be laser processed. Accordingly, the following description is centered on differences from FIG. 15A and common operation parts are denoted by corresponding reference signs and description is omitted as appropriate.

If the laser irradiation position Lb passes through the planned dividing line S1 toward the (+X) side as the laser processing for the planned dividing line S1 is finished, the laser irradiation position Lb starts to decelerate toward the (+X) side in the X direction (Step S1005) and stops at a position Pb2 on the (+X) side of the semiconductor substrate Win the X direction (Step S1006). This position Pb2 is provided outside a zone between the virtual straight line Sv1 and the virtual straight line Sv2 (on a side opposite to the virtual straight line Sv1 with respect to the virtual straight line Sv2) in the Y direction. That is, in Steps S1005 to S1006, the laser irradiation position Lb moves in the Y direction from the virtual straight line Sv1 to the position Pb2 beyond the virtual straight line Sv2 in parallel with deceleration in the X direction. Further, with the laser irradiation position Lb stopped at the position Pb2, the imaging range Ri of the imaging part 8B stops at a position including at least an imaging point Pw(S3). Accordingly, in Step S1006, the control unit 100 causes the imaging part 8B to image the imaging range Ri and obtains an image including the imaging point Pw(S3). In this way, the control unit 100 can obtain the image showing the position of the unprocessed planned dividing line S3.

Subsequently, the laser irradiation position Lb stopped at the position Pb2 starts to accelerate toward the (−X) side in the X direction (Step S1001). If the velocity Vx of the laser irradiation position Lb increases to the processing velocity Vxd by the time the laser irradiation position Lb reaches the end of the semiconductor substrate W on the (+X) side, the laser irradiation position Lb moves at the constant processing velocity Vxd toward the (−X) side in the X direction (Step S1002). Further, in a period from the start of acceleration to the start of constant movement at the processing velocity Vxd of the laser irradiation position Lb, the laser irradiation position Lb moves in the Y direction from the position Pb2 to the virtual straight line Sv2. That is, in Steps S1001 to S1002, the laser irradiation position Lb moves in the Y direction from the position Pb2 to the virtual straight line Sv2 in parallel with acceleration in the X direction. In this way, the laser irradiation position Lb reaches the planned dividing line S2 and the line processing for the planned dividing line S2 can be started.

If the laser irradiation position Lb passes through the planned dividing line S2 toward the (−X) side as the laser processing for the planned dividing line S2 is finished, the laser irradiation position Lb starts to decelerate toward the (−X) side in the X direction (Step S1005) and stops at a position Pb3 on the (−X) side of the semiconductor substrate Win the X direction (Step S1006). This position Pb3 is provided outside a zone between the virtual straight line Sv2 and the virtual straight line Sv3 (on a side opposite to the virtual straight line Sv2 with respect to the virtual straight line Sv3) in the Y direction. That is, in Steps S1005 to S1006, the laser irradiation position Lb moves in the Y direction from the virtual straight line Sv2 to the position Pb2 beyond the virtual straight line Sv3 in parallel with deceleration in the X direction. Further, with the laser irradiation position Lb stopped at the position Pb3, the imaging range Ri of the imaging part 8A stops at a position including at least an imaging point Pw(S4). Accordingly, in Step S1006, the control unit 100 causes the imaging part 8A to image the imaging range Ri and obtains an image including the imaging point Pw(S4). In this way, the control unit 100 can obtain the image showing the position of an unprocessed planned dividing line S4.

Next, a velocity change of the laser irradiation position Lb is described with reference to “Velocity Change in X Direction” and “Velocity Change in Y Direction” of FIG. 15G. In a line processing period Ts1 (Steps S1002 to S1004) during which the line processing of moving the laser beam B toward the (+X) side along the planned dividing line S1 is performed, the laser irradiation position Lb does not move in the Y direction while moving at the constant processing velocity Vxd in the X direction. Further, in a line processing period Ts2 (Steps S1002 to S1004) during which the line processing of moving the laser beam B toward the (−X) side along the planned dividing line S2 is performed, the laser irradiation position Lb does not move in the Y direction while moving at the constant processing velocity Vxd in the X direction.

Further, in a switching period Tc (Steps S1005, S1006 and S1001) during which a switch is performed from the line processing period Ts1 to the line processing period Ts2, the laser irradiation position Lb is moved in the Y direction (feeding direction) from the virtual straight line Sv1 to the virtual straight line Sv2 in parallel with performing the reverse drive in the X direction as in the aforementioned case. Particularly, this movement of the laser irradiation position Lb is made by way of the position Pb2 provided outside the zone between the virtual straight line Sv1 and the virtual straight line Sv2 in the Y direction. That is, the laser irradiation position Lb moves in the Y direction from the virtual straight line Sv1 to the position Pb2 beyond the virtual straight line Sv2 in a deceleration period Td, out of the deceleration period Td and an acceleration period Ta included in the switching period Tc, and moves in the Y direction from the position Pb2 to the virtual straight line Sv2 in the acceleration period Ta. Specifically, the laser irradiation position Lb starts to move from the virtual straight line Sv1 to the position Pb2 simultaneously with the start of the deceleration period Td, and reaches the position Pb2 simultaneously with the end of the deceleration period Td. Further, the laser irradiation position Lb starts to move from the position Pb2 to the virtual straight line Sv2 simultaneously with the start of the acceleration period Ta and reaches the virtual straight line Sv2 simultaneously with the end of the acceleration period Ta.

Further, in a stop period Tt provided on the way during a transition from the acceleration period Ta to the deceleration period Td, both the velocity Vx of the laser irradiation position Lb in the X direction and the velocity Vy thereof in the Y direction become zero and the laser irradiation position Lb is stopped at the position Pb2 with respect to the semiconductor substrate W. In this stop period Tt, the imaging ranges Ri of the imaging parts 8A, 8B are also stopped with respect to the semiconductor substrate W. Particularly, the imaging range Ri of the imaging part 8B is located on the (−X) side of the laser irradiation position Lb located on the (+X) side of the semiconductor substrate W and overlaps the semiconductor substrate W. Accordingly, the infrared camera 81 of the imaging part 8B images a part of the semiconductor substrate W overlapping the imaging range Ri in the stop period Tt (Step S1006).

In the above example, the position Pb2 is provided on the side opposite to the virtual straight line Sv1 with respect to the virtual straight line Sv2 in the Y direction. However, the position Pb2 may be provided on a side opposite to the virtual straight line Sv2 with respect to the virtual straight line Sv1 in the Y direction. In this case, the laser irradiation position Lb moves in the Y direction from the virtual straight line Sv1 to the position Pb2 in the deceleration period Td, and moves in the Y direction from the position Pb2 to the virtual straight line Sv2 beyond the virtual straight line Sv1 in the acceleration period Ta. A similar change can be made also for the position Pb3.

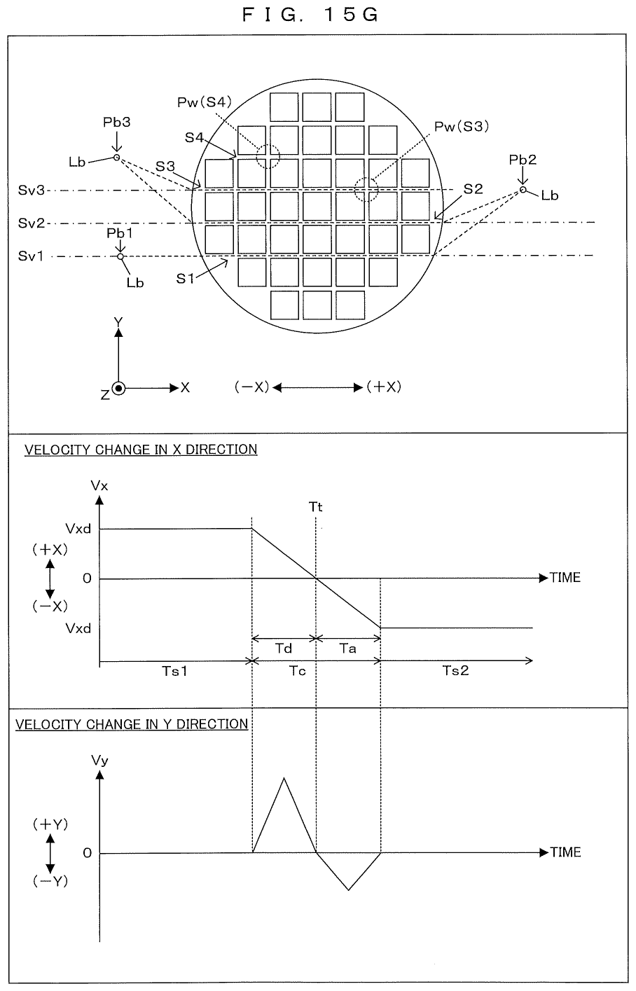

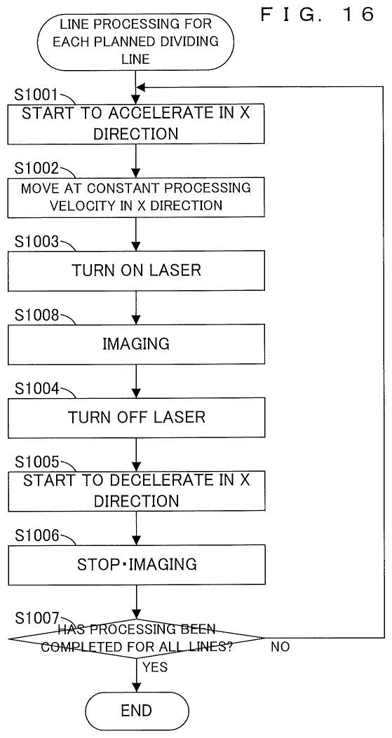

FIG. 16 is a flow chart showing a first application example of the line processing for each planned dividing line, and FIG. 17 is a chart schematically showing an example of an operation performed in accordance with the flow chart of FIG. 16. Notation in FIG. 17 is similar to that in FIGS. 15A to 15G. The example of FIG. 16 differs from the example of FIG. 14 in the presence of Step S1008 of imaging the semiconductor substrate W during the line processing, but other Steps S1001 to S1007 are common. Accordingly, in the example of FIG. 16, any one of the operations (first example to seventh example) shown in FIGS. 15A to 15G is performed. Note that, although a trace of the laser irradiation position Lb in the switching period Tc is not shown in FIG. 17, the laser irradiation position Lb can move along the trace shown in any one of FIGS. 15A to 15G.

Step S1008 of FIG. 16 is performed as follows. That is, the semiconductor substrate W is imaged during a movement of the laser irradiation position Lb along the planned dividing line S1 (Step S1008). Specifically, the imaging range Ri (i.e. the imaging range Ri of the imaging part 8A) located on a moving side (i.e. the (+X) side), toward which the laser irradiation position Lb is moving, relative to the laser irradiation position Lb moving toward the (+X) side is imaged. In this way, an image including an imaging point Pw(S11) on the moving side of the laser irradiation position Lb relative to the laser irradiation position Lb is obtained. In this way, an image showing the position of an unprocessed part, out of the planned dividing line S1 being line processed, can be obtained.

That is, in a period during which Steps S1003, S1108 and S1104 are performed, the image of the unprocessed part, out of the planned dividing line S1 to be line processed, is captured in parallel with performing the line processing for the planned dividing line S1.

Further, the semiconductor substrate W is imaged during a movement of the laser irradiation position Lb along the planned dividing line S2 (Step S1008). Specifically, the imaging range Ri (i.e. the imaging range Ri of the imaging part 8B) located on a moving side (i.e. the (−X) side), toward which the laser irradiation position Lb is moving, relative to the laser irradiation position Lb moving toward the (−X) side is imaged. In this way, an image including an imaging point Pw(S21) on the moving side of the laser irradiation position Lb relative to the laser irradiation position Lb is obtained. In this way, an image showing the position of an unprocessed part, out of the planned dividing line S2 being line processed, can be obtained.

That is, in the period during which Steps S1003, S1108 and S1104 are performed, the image of the unprocessed part, out of the planned dividing line S2 to be line processed, is captured in parallel with performing the line processing for the planned dividing line S2.

Furthermore, the semiconductor substrate W is imaged during a movement of the laser irradiation position Lb along the planned dividing line S3 (Step S1008). Specifically, the imaging range Ri (i.e. the imaging range Ri of the imaging part 8A) located on a moving side (i.e. the (+X) side), toward which the laser irradiation position Lb is moving, relative to the laser irradiation position Lb moving toward the (+X) side is imaged. In this way, an image including an imaging point Pw(S31) on the moving side of the laser irradiation position Lb relative to the laser irradiation position Lb is obtained. In this way, an image showing the position of an unprocessed part, out of the planned dividing line S3 being line processed, can be obtained.

That is, in the period during which Steps S1003, S1108 and S1104 are performed, the image of the unprocessed part, out of the planned dividing line S3 to be line processed, is captured in parallel with performing the line processing for the planned dividing line S3.

Steps S1001 to S1007 are repeated until it is confirmed that the line processing has been completed for the plurality of planned dividing lines S (S1, S2, S3, . . . ) parallel to the X direction (“YES” in Step S1007).

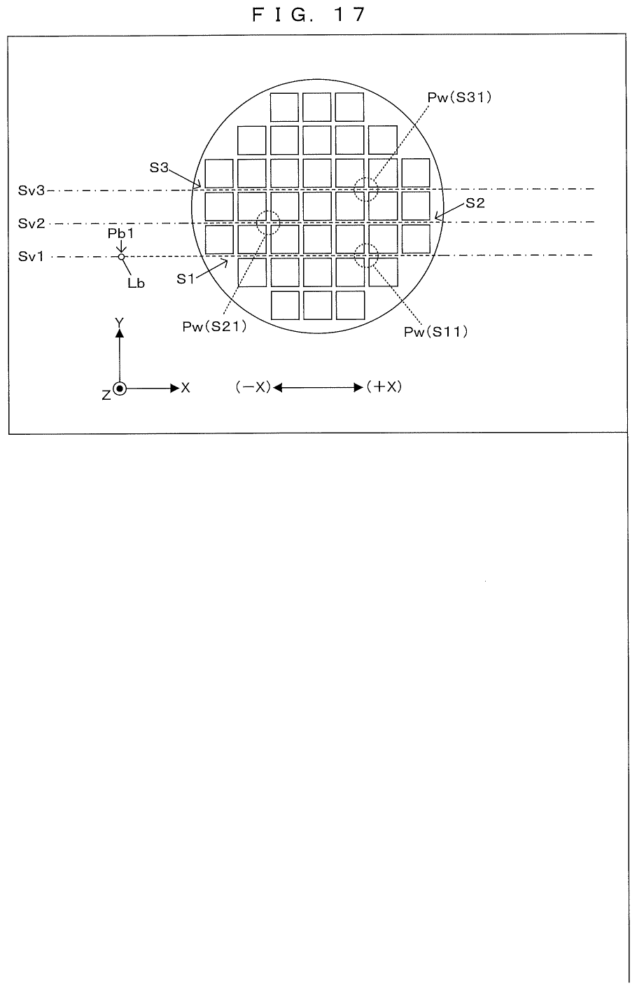

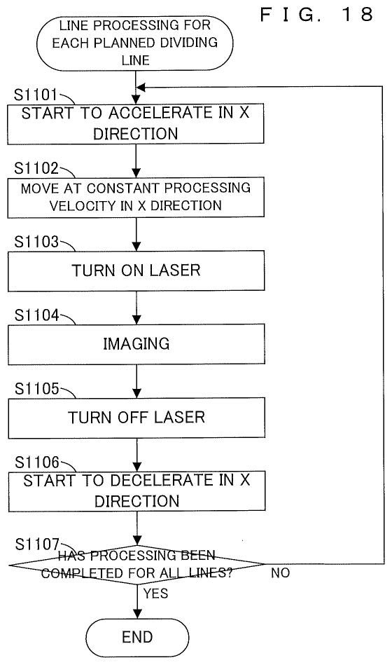

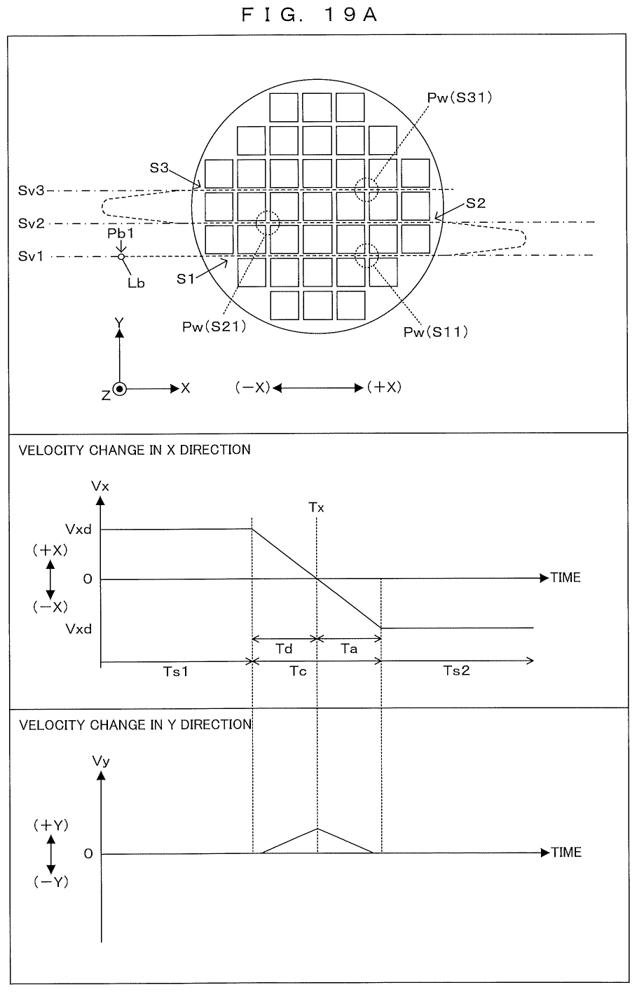

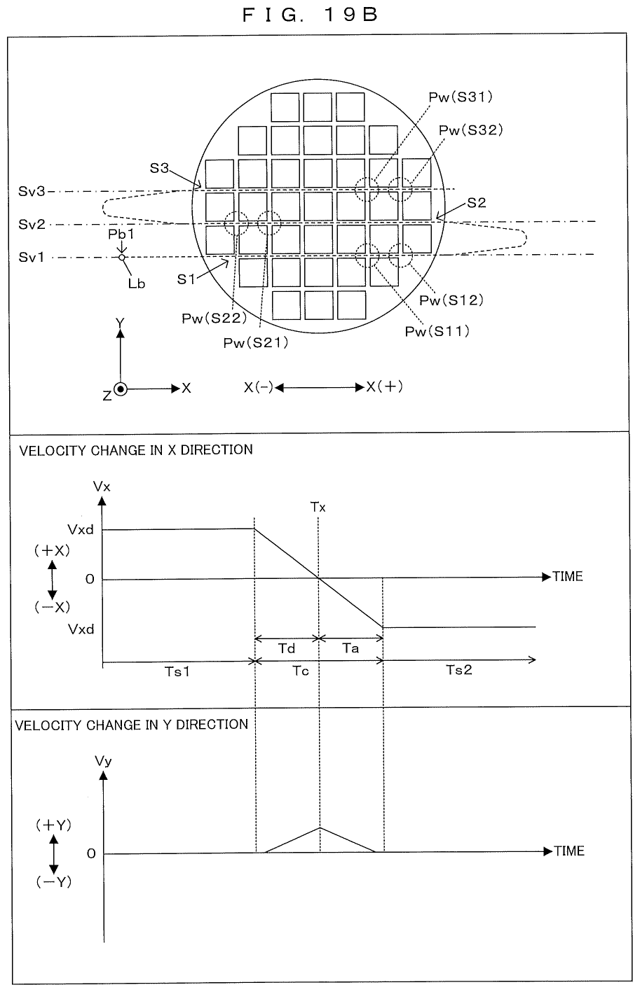

FIG. 18 is a flow chart showing a second application example of the line processing for each planned dividing line, and FIG. 19A shows charts schematically showing a first example of an operation performed in accordance with the flow chart of FIG. 18. In FIG. 19A, a trace of the laser irradiation position Lb relatively moving with respect to the semiconductor substrate W is shown by dotted line, and the virtual straight lines Sv1, Sv2, Sv3 extending in parallel to the X direction along the planned dividing lines S1, S2, S3 between both outer sides of the planned dividing lines S1, S2, S3 are shown by one-dot chain line. Note that dotted lines representing the trace of the laser irradiation position Lb are preferentially shown in parts where the trace of the laser irradiation position Lb and the virtual straight lines Sv1, Sv2, Sv3 overlap.

In the example shown in FIG. 19A, the flow chart of FIG. 18 is started from a state where the laser irradiation position Lb is stopped at a position Pb1 on the (−X) side of the semiconductor substrate W in the X direction. This position Pb1 is a position provided on the virtual straight line Sv1 along the planned dividing line S1, in other words, facing the planned dividing line S1 from the X direction. However, the position of the laser irradiation position Lb when the flow chart of FIG. 18 is started is not limited to this example and can be changed as appropriate.

In Step S1101, the laser irradiation position Lb stopped at the position Pb1 starts to accelerate toward the (+X) side in the X direction and moves in parallel to the X direction. In this way, the laser irradiation position Lb moves toward the (+X) side along the virtual straight line Sv1. If the velocity Vx of the laser irradiation position Lb increases to the processing velocity Vxd by the time the laser irradiation position Lb reaches the end of the semiconductor substrate W on the (−X) side, the laser irradiation position Lb moves at the constant processing velocity Vxd toward the (+X) side in the X direction (Step S1102).

Further, the laser light source 72 is turned on and the irradiation of the laser beam B to the laser irradiation position Lb from the processing head 71 is started in accordance with a timing at which the laser irradiation position Lb reaches the end of the semiconductor substrate W on the (−X) side (Step S1103). In this way, the laser beam B is irradiated to the laser irradiation position Lb moving toward the (+X) side in the X direction along the planned dividing line S1, whereby the planned dividing line S1 is processed (line processing).

Further, in this example, the semiconductor substrate W is imaged during the movement of the laser irradiation position Lb along the planned dividing line S1 (Step S1104). Specifically, the imaging range Ri (i.e. the imaging range Ri of the imaging part 8A) located on a moving side (i.e. the (+X) side), toward which the laser irradiation position Lb is moving, relative to the laser irradiation position Lb moving toward the (+X) side is imaged. In this way, an image including an imaging point Pw(S11) on the moving side of the laser irradiation position Lb relative to the laser irradiation position Lb is obtained. In this way, an image showing the position of an unprocessed part, out of the planned dividing line S1 being line processed, can be obtained.

Then, the laser light source 72 is turned off and the irradiation of the laser beam B to the laser irradiation position Lb from the processing head 71 is finished in accordance with a timing at which the laser irradiation position Lb reaches the end of the semiconductor substrate Won the (+X) side (Step S1105). In this way, in a period from Step S1103 to Step S1105, the image of the unprocessed part, out of the planned dividing line S1 to be line processed, is captured in parallel with performing the line processing for the planned dividing line S1.

If the laser irradiation position Lb passes through the planned dividing line S1 toward the (+X) side, the laser irradiation position Lb starts to decelerate toward the (+X) side in the X direction (Step S1106). In Step S1107, it is confirmed whether or not the laser processing has been completed for the plurality of planned dividing lines S parallel to the X direction. If there is any unprocessed planned dividing line S, out of these planned dividing lines S (“NO” in Step S1107), return is made to Step S1101.

As a result, the laser irradiation position Lb accelerates toward the (−X) side in the X direction (Step S1101) after the velocity Vx in the X direction of the laser irradiation position Lb decelerated toward the (+X) side in the X direction becomes zero. If the velocity Vx of the laser irradiation position Lb increases to the processing velocity Vxd by the time the laser irradiation position Lb reaches the end of the semiconductor substrate W on the (+X) side, the laser irradiation position Lb moves at the constant processing velocity Vxd toward the (−X) side in the X direction (Step S1102).

As just described, also in the example of FIGS. 18 and 19A, the reverse drive is performed in the X direction as in the aforementioned case. Further, in parallel with this reverse drive, the laser irradiation position Lb moves in the Y direction from the virtual straight line Sv1 to the virtual straight line Sv2. In this way, the laser irradiation position Lb reaches the planned dividing line S2 by moving to the virtual straight line Sv2 in the Y direction by the time the velocity Vx in the X direction of the laser irradiation position Lb increases to the processing velocity Vxd.

However, in this example, a movement mode in the Y direction of the laser irradiation position Lb is different from the aforementioned one. That is, the laser irradiation position Lb continuously moves in the Y direction from a planned dividing line Sb1 to a planned dividing line Sb2 (continuous feed drive) in parallel with the reverse drive for decelerating, stopping and accelerating the laser irradiation position Lb in the X direction. Particularly, the continuous feed drive of the laser irradiation position Lb in the Y direction is performed throughout the before and after the time at which a timing at which the velocity Vx of the laser irradiation position Lb in the X direction becomes zero due to the reverse drive. Therefore, a timing at which both the velocity Vx in the X direction of the laser irradiation position Lb and the velocity Vy thereof in the Y direction become zero does not exist in this example.

The laser light source 72 is turned on and the irradiation of the laser beam B to the laser irradiation position Lb from the processing head 71 is started in accordance with a timing at which the laser irradiation position Lb reaches the end of the semiconductor substrate W on the (+X) side (Step S1103). In this way, the laser beam B is irradiated to the laser irradiation position Lb moving toward the (−X) side in the X direction along the planned dividing line S2 and the planned dividing line S2 is processed (line processing).

Further, in this example, the semiconductor substrate W is imaged during the movement of the laser irradiation position Lb along the planned dividing line S2 (Step S1104). Specifically, the imaging range Ri (i.e. the imaging range Ri of the imaging part 8B) located on a moving side (i.e. the (−X) side), toward which the laser irradiation position Lb is moving, relative to the laser irradiation position Lb moving toward the (−X) side is imaged. In this way, an image including an imaging point Pw(S21) on the moving side of the laser irradiation position Lb relative to the laser irradiation position Lb is obtained. In this way, an image showing the position of an unprocessed part, out of the planned dividing line S2 being line processed, can be obtained.

The laser light source 72 is turned off and the irradiation of the laser beam B to the laser irradiation position Lb from the processing head 71 is finished in accordance with a timing at which the laser irradiation position Lb reaches the end of the semiconductor substrate Won the (−X) side (Step S1105). In this way, in a period from Step S1103 to Step S1105, the image of the unprocessed part, out of the planned dividing line S2 to be line processed, is captured in parallel with performing the line processing for the planned dividing line S2.

If the laser irradiation position Lb passes through the planned dividing line S2 toward the (−X) side, the laser irradiation position Lb starts to decelerate toward the (−X) side in the X direction (Step S1106). In Step S1107, it is confirmed whether or not the line processing has been completed for the plurality of planned dividing lines S parallel to the X direction. If there is any unprocessed planned dividing line S, out of these planned dividing lines S (“NO” in Step S1107), return is made to Step S1101.

As a result, the laser irradiation position Lb accelerates toward the (+X) side in the X direction (Step S1101) after the velocity Vx in the X direction of the laser irradiation position Lb decelerated toward the (−X) side in the X direction becomes zero. If the velocity Vx of the laser irradiation position Lb increases to the processing velocity Vxd by the time the laser irradiation position Lb reaches the end of the semiconductor substrate W on the (−X) side, the laser irradiation position Lb moves at the constant processing velocity Vxd toward the (+X) side in the X direction (Step S1102).

At this time, as in the aforementioned case, the continuous feed drive in the Y direction is performed for the laser irradiation position Lb in parallel with the reverse drive in the X direction. In this way, the laser irradiation position Lb reaches the planned dividing line S3 by moving to the virtual straight line Sv3 in the Y direction by the time the velocity Vx in the X direction of the laser irradiation position Lb increases to the processing velocity Vxd.

The laser light source 72 is turned on and the irradiation of the laser beam B to the laser irradiation position Lb from the processing head 71 is started in accordance with a timing at which the laser irradiation position Lb reaches the end of the semiconductor substrate Won the (−X) side (Step S1103). In this way, the laser beam B is irradiated to the laser irradiation position Lb moving toward the (+X) side in the X direction along the planned dividing line S3 and the planned dividing line S3 is processed (line processing).

Further, in this example, the semiconductor substrate W is imaged during the movement of the laser irradiation position Lb along the planned dividing line S3 (Step S1104). Specifically, the imaging range Ri (i.e. the imaging range Ri of the imaging part 8A) located on a moving side (i.e. the (+X) side), toward which the laser irradiation position Lb is moving, relative to the laser irradiation position Lb moving toward the (+X) side is imaged. In this way, an image including an imaging point Pw(S31) on the moving side of the laser irradiation position Lb relative to the laser irradiation position Lb is obtained. In this way, an image showing the position of an unprocessed part, out of the planned dividing line S3 being line processed, can be obtained.

Then, the laser light source 72 is turned off and the irradiation of the laser beam B to the laser irradiation position Lb from the processing head 71 is finished in accordance with a timing at which the laser irradiation position Lb reaches the end of the semiconductor substrate Won the (+X) side (Step S1105). In this way, in a period from Step S1103 to Step S1105, the image of the unprocessed part, out of the planned dividing line S3 to be line processed, is captured in parallel with performing the line processing for the planned dividing line S3.

Next, a velocity change of the laser irradiation position Lb is described with reference to “Velocity Change in X Direction” and “Velocity Change in Y Direction” of FIG. 19A. In a line processing period Ts1 (Steps S1103 to S1105) during which the line processing of moving the laser beam B toward the (+X) side along the planned dividing line S1 is performed, the laser irradiation position Lb does not move in the Y direction while moving at the constant processing velocity Vxd in the X direction. Further, in a line processing period Ts2 (Steps S1103 to S1105) during which the line processing of moving the laser beam B toward the (−X) side along the planned dividing line S2 is performed, the laser irradiation position Lb does not move in the Y direction while moving at the constant processing velocity Vxd in the X direction.

Further, in a switching period Tc (Steps S1106, S1101) during which a switch is performed from the line processing period Ts1 to the line processing period Ts2, the following operation is performed. That is, the X-axis driver 65 (processing-axis driver) performs the reverse drive to bring the laser irradiation position Lb to the planned dividing line S2 (second processing line) by accelerating the laser irradiation position Lb toward the (−X) side (Step S1101) after decelerating and stopping the laser irradiation position Lb, which has passed through the planned dividing line S1 (first processing line) toward the (+X) side (first side), toward the (+X) side in the X direction (processing direction) (Step S1106). In parallel with this reverse drive, the Y-axis driver 63 (feeding-axis driver) performs the continuous feed drive to continuously move the laser irradiation position Lb in the Y direction (feeding direction) from the virtual straight line Sv1 (first virtual straight line) extended in the X direction to the outside of the planned dividing line S1 along the planned dividing line S1 to the virtual straight line Sv2 (second virtual straight line) extended in the X direction to the outside of the planned dividing line S2 along the planned dividing line S2.

Particularly, the control unit 100 controls the X-axis driver 65 and the Y-axis driver 63 such that the Y-axis driver 63 starts the continuous feed drive before the X-axis driver 65 stops the laser irradiation position Lb in the X direction by the reverse drive and the Y-axis driver 63 finishes the continuous feed drive after the X-axis driver 65 stops the laser irradiation position Lb in the X direction by the reverse drive. In this way, the Y-axis driver 63 moves the laser irradiation position Lb in the Y direction throughout the before and after the time at which the movement of the laser irradiation position Lb in the X direction is stopped due to the reverse drive (in other words, in a period during which the X-axis driver 65 stops the laser irradiation position Lb in the X direction by the reverse drive).

In other words, the switching period Tc includes a deceleration period Td (Step S1006) for decelerating the laser irradiation position Lb in the X direction and an acceleration period Ta (Step S1001) for accelerating the laser irradiation position Lb in the X direction. In contrast, the Y-axis driver 63 continuously performs the movement of the laser irradiation position Lb in the Y direction (i.e. perform the movement without stopping the laser irradiation position Lb in the Y direction) throughout the before and after the time at which a transition period Tx from the deceleration period Td to the acceleration period Ta. Note that the laser irradiation position Lb is stopped in the X direction (i.e. the velocity Vx is zero) during the transition period Tx.

FIG. 19B shows charts schematically showing a second example of the operation performed in accordance with the flow chart of FIG. 18. FIG. 19B differs from FIG. 19A in the number of times of imaging the semiconductor substrate W in parallel with the line processing. That is, in the example of FIG. 19B, the imaging range Ri (i.e. the imaging range Ri of the imaging part 8A) located on a moving side (i.e. the (+X) side), toward which the laser irradiation position Lb is moving, relative to the laser irradiation position Lb moving toward the (+X) side to perform the line processing for the planned dividing line S1 is imaged a plurality of times (twice in this example) (Step S1104). In this way, two images respectively including two imaging points Pw(S11), Pw(S12) on the moving side of the laser irradiation position Lb relative to the laser irradiation position Lb are obtained. In this way, images showing the positions of unprocessed parts, out of the planned dividing line S1 being line processed, can be obtained.

Similarly, the imaging range Ri (i.e. the imaging range Ri of the imaging part 8B) located on a moving side (i.e. the (−X) side), toward which the laser irradiation position Lb is moving, relative to the laser irradiation position Lb moving toward the (−X) side to perform the line processing for the planned dividing line S2 is imaged a plurality of times (twice in this example) (Step S1104). In this way, two images respectively including two imaging points Pw(S21), Pw(S22) on the moving side of the laser irradiation position Lb relative to the laser irradiation position Lb are obtained. In this way, images showing the positions of unprocessed parts, out of the planned dividing line S2 being line processed, can be obtained. Further, imaging is similarly performed a plurality of times also in the line processing for the planned dividing line S3 (Step S1104).

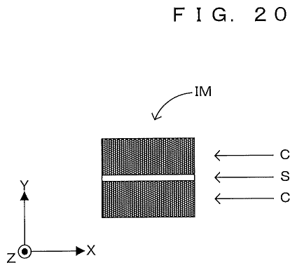

FIG. 20 is a diagram schematically showing an example of an image of the semiconductor substrate obtained in Step S1008 of FIG. 16 or Step S1104 of FIG. 18. In the above examples, a region including an intersection of two planned dividing lines S orthogonal to each other is imaged to obtain an image IM. At this time, since the image IM is obtained while the imaging range Ri is moved in the X direction with respect to the semiconductor substrate W, a luminance is shown to be averaged in the X direction in the image IM. As a result, a high-luminance region having a high luminance and extending in parallel to the X direction in correspondence with the planned dividing line S and low-luminance regions having a luminance lower than the high-luminance region and extending in parallel to the X direction in correspondence with the semiconductor chips C appear. Particularly, in the Y direction, the high-luminance region is sandwiched by two low-luminance regions. Therefore, the control unit 100 can confirm the position in the Y direction of the planned dividing line S based on the high-luminance region corresponding to the planned dividing line S.

In the embodiment described above using FIGS. 16 to 20, the image of the part of the semiconductor substrate W overlapping the imaging range Ri is obtained by imaging the imaging range Ri relatively moving with respect to the semiconductor substrate W during the execution of the line processing (Steps S1003 to S1004, S1103 to S1105) of processing the planned dividing line S by irradiating the laser beam B to the laser irradiation position Lb while moving the laser irradiation position Lb along the planned dividing line S (Steps S1008, S1104). That is, the execution period of the line processing is effectively utilized to image the semiconductor substrate W. In this way, the semiconductor substrate W can be efficiently imaged in the laser processing technique for processing the planned dividing line S by irradiating the laser beam B to the planned dividing line S.

Further, the imaging part 8 images the imaging range Ri provided on a downstream side in the moving direction of the laser irradiation position Lb with respect to the planned dividing line S in the line processing (Steps S1003 to S1004, S1103 to S1105). In such a configuration, an image of an unprocessed side of the position being processed by the laser beam B (i.e. the laser irradiation position Lb) can be obtained. Therefore, the control unit 100 can recognize an influence of the processing by the laser beam B on the unprocessed part of the semiconductor substrate W based on this image.

In the example of FIG. 19B, the imaging part 8 images the imaging range Ri a plurality of times in a period during which the line processing (Steps S1003 to S1004, S1103 to S1105) is performed once (Steps S1008, S1104). In such a configuration, a plurality of images of the semiconductor substrate W can be obtained, effectively utilizing the execution period of the line processing.

In the examples shown in FIGS. 18, 19A and 19B, the line processing (first line processing) of processing the planned dividing line S1 (first processing line) and the line processing (second line processing) of processing the planned dividing line S2 (second processing line) are performed in turn, using the X-axis driver 65 for relatively moving the laser irradiation position Lb in the X direction with respect to the semiconductor substrate W and the Y-axis driver 63 (feeding-axis driver) for relatively moving the laser irradiation position Lb in the Y direction with respect to the semiconductor substrate W. Further, in the switching period Tc between the line processing for the planned dividing line S1 and the line processing for the planned dividing line S2, the X-axis driver 65 and the Y-axis driver 63 perform the following operation to move the laser irradiation position Lb having passed through the planned dividing line S1 toward the planned dividing line S2. That is, the X-axis driver 65 performs the reverse drive for bringing the laser irradiation position Lb to the planned dividing line S2 by accelerating the laser irradiation position Lb toward the (−X) side after decelerating and stopping the laser irradiation position Lb, which has passed through the planned dividing line S1 toward the (+X) side, toward the (+X) side in the X direction. Further, the Y-axis driver 63 moves the laser irradiation position Lb in the Y direction from the virtual straight line Sv1 extended in the X direction to the outside of the planned dividing line S1 along the planned dividing line S1 to the virtual straight line Sv2 extended in the X direction to the outside of the planned dividing line S2 along the planned dividing line S2.

Particularly, the Y-axis driver 63 performs the continuous feed drive for continuously moving the laser irradiation position Lb in the Y direction from the virtual straight line Sv1 to the virtual straight line Sv2 in the switching period Tc. Then, the control unit 100 controls the X-axis driver 65 and the Y-axis driver 63 such that the Y-axis driver 63 starts the continuous feed drive before the X-axis driver 65 stops the laser irradiation position Lb by the reverse drive and the Y-axis driver 63 finishes the continuous feed drive after the X-axis driver 65 stops the laser irradiation position Lb by the reverse drive. That is, the Y-axis driver 63 moves the laser irradiation position Lb in the Y direction throughout the before and after the time at which a movement of the laser irradiation position Lb in the X direction is stopped due to the reverse drive (in other words, in a period during which the X-axis driver 65 stops the laser irradiation position Lb by the reverse drive). As just described, in the switching period Tc, both a period of decelerating the laser processing position Lb toward the (+X) side in the X direction and a period for accelerating the laser irradiation position Lb toward the (−X) side in the X direction are effectively utilized to move the laser irradiation position Lb in the Y direction. As a result, it is possible to suppress an influence of the switching period Tc of switching the moving direction of the laser beam B on a time required to complete the processing of the semiconductor substrate W. Moreover, since the execution period of the line processing is effectively utilized to image the semiconductor substrate W as described above, it is possible to suppress a time to switch the planned dividing line S to be line processed, efficiently image the semiconductor substrate W and quickly complete the processing of the semiconductor substrate W.

Further, the imaging part 8 images the imaging range Ri including at least the planned dividing line S during the execution of the line processing (FIG. 20). A part equivalent to the planned dividing line S appears to extend in the X direction due to contrast between both sides of the planned dividing line S and the planned dividing line S in the Y direction in an image IM obtained by such imaging. Therefore, the control unit 100 can precisely recognize an influence of the laser processing on the position in the Y direction of the planned dividing line S based on the position in the Y direction of this part.

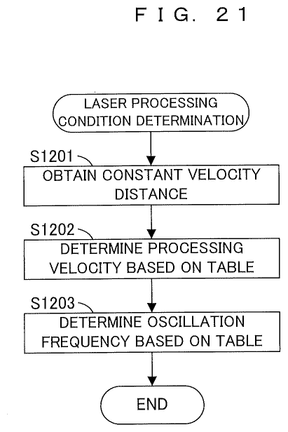

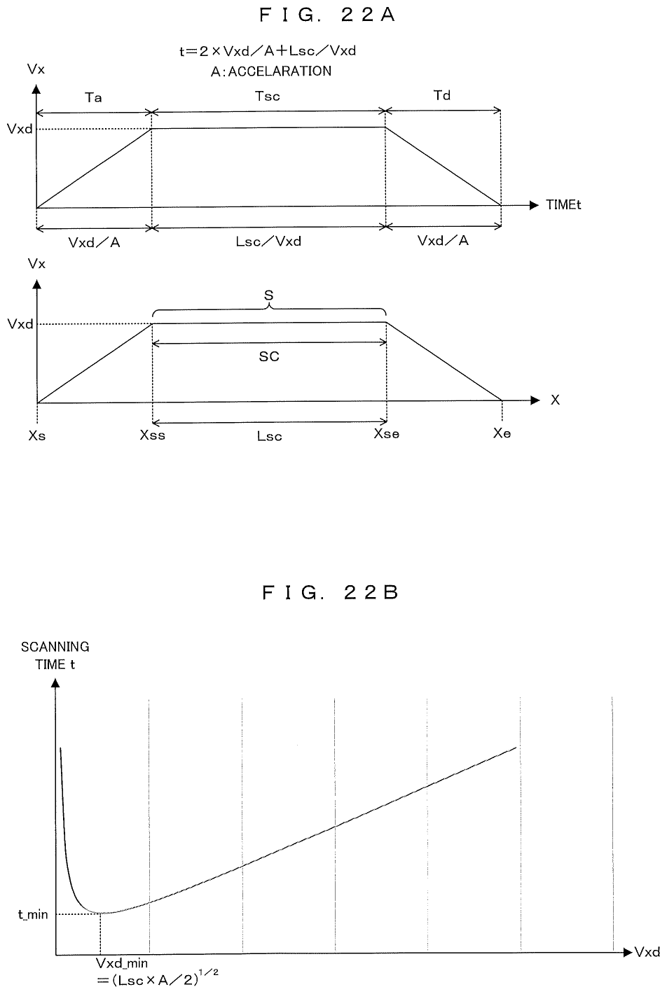

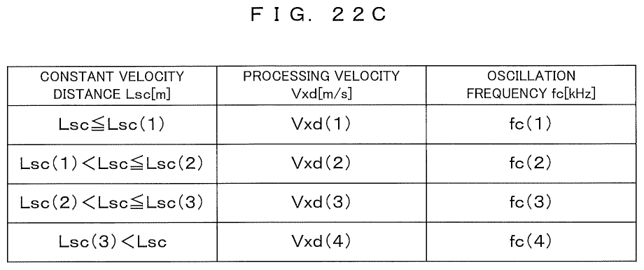

FIG. 21 is a flow chart showing an example of a determination method of laser processing conditions in the line processing, FIG. 22A show charts showing parameters relating to the determination of laser processing conditions, FIG. 22B is a graph showing a time impact of the laser processing condition, and FIG. 22C is a table showing an example of a table to be referred to in the determination of the laser processing conditions of FIG. 21. This table is stored in the storage 190 in advance.

FIG. 22A show an upper chart showing a relationship of the velocity Vx of the laser irradiation position Lb moving in the X direction and time and a lower chart showing a relationship of the velocity Vx of the laser irradiation position Lb moving in the X direction and the position in the X direction (i.e. X-coordinate) of the laser irradiation position Lb in a line processing.

As shown in the lower chart, to perform the line processing for the planned dividing line S, an irradiation position scan is performed to irradiate the laser beam B to the laser irradiation position Lb overlapping the planned dividing line S while moving the laser irradiation position Lb in the X direction from a start point Xs on one side of the planned dividing line S to an end point Xe on the other side (side opposite to the one side) of the planned dividing line S. That is, in the irradiation position scan, the laser beam B is irradiated from the processing head 71 to the laser irradiation position Lb overlapping the planned dividing line S while the laser irradiation position Lb is moved in the X direction from the start point Xs to the end point Xe by the X-axis driver 65. In this way, the aforementioned line processing is performed in accordance with the irradiation position scan.

In this irradiation position scan, a constant velocity zone SC is set for the planned dividing line S. This constant velocity zone SC is located between the start point Xs and the end point Xe in the X direction and set to include the planned dividing line S. In this example, both ends of the constant velocity zone SC coincide with both ends of the planned dividing line S in the X direction, in other words, the constant velocity zone SC coincides with the planned dividing line S. However, a setting mode of the constant velocity zone SC is not limited to this example and the constant velocity zone SC may be set by adding offsets outside the both ends of the planned dividing line S. In this case, the constant velocity zone SC becomes longer than the planned dividing line S. A length of the offset may be a predetermined fixed value or may be a value obtained by multiplying a length of the planned dividing line S by a predetermined scale factor (e.g. 1%). The length of such a constant velocity zone SC is set according to that of the planned dividing line S. Specifically, the longer the planned dividing line S, the longer the constant velocity zone SC (in other words, the shorter the planned dividing line S, the shorter the constant velocity zone SC).

In this irradiation position scan, the laser irradiation position Lb moves in the X direction from the start point Xs provided on one side of the constant velocity zone SC to the end point X3 provided on the other side of the constant velocity zone SC. Further, in the acceleration period Ta during which the laser irradiation position Lb moves in the X direction from the start point Xs to an end Xss on the one side of constant velocity zone SC in the X direction, the laser irradiation position Lb accelerates at an acceleration A in the X direction and the velocity Vx in the X direction of the laser irradiation position Lb increases from zero to the processing velocity Vxd. Further, in a constant velocity period Tsc (coinciding with the line processing period Ts in this example) during which the laser irradiation position Lb moves in the X direction from the end Xss on the one side of the constant velocity zone SC to an end Xse on the other side of the constant velocity zone SC, the laser irradiation position Lb moves at the constant processing velocity Vxd in the X direction. Further, in the deceleration period Tb during which the laser irradiation position Lb moves in the X direction from the end Xse on the other side of the constant velocity zone SC to the end point Xe, the laser irradiation position Lb decelerates at the acceleration A in the X direction and the velocity Vx in the X direction of the laser irradiation position Lb decreases from the processing velocity Vxd to zero.

At this time, the acceleration period Ta is a period (Vxd/A) required to increase the velocity Vx from zero to the processing velocity Vxd at the acceleration A, the constant velocity period Tsc is a period (Lsc/Vxd) required to move a constant velocity distance Lsc, which is the length of the constant velocity zone SC, at the processing velocity Vxd, and the deceleration period Td is a period (Vxd/A) required to decrease the velocity Vx from the processing velocity Vxd to the zero at the acceleration A. Therefore, a scanning time t required for the irradiation position scan is:

t=2×Vxd/A+Lsc/Vxd.

Thus, a relationship shown in FIG. 22B is satisfied between the processing velocity Vxd and the scanning time t. That is, the scanning time t has a minimum value when the processing velocity Vxd is Vxd_min (=(LscxA/2)^{1/2}). Therefore, the line processing can be efficiently performed by setting the processing velocity Vxd according to the length (constant velocity distance Lsc) of the constant velocity zone SC.

However, in the case of changing the processing velocity Vxd, a frequency of the laser beam B emitted from the laser light source 72 needs to be changed. Specifically, as the processing velocity Vxd is increased, the frequency of the laser beam B needs to be increased. In contrast, the frequency of the laser beam B can be changed only stepwise and cannot be continuously changed. Accordingly, the table of FIG. 22C is used. This table specifies a relationship of the constant velocity distance Lsc (length of the planned dividing line S in this example), the processing velocity Vxd and the frequency fc of the laser beam B. Specifically, the following laser processing conditions are set in the table. If the constant velocity distance Lsc is less than or equal to Lsc(1), the processing velocity Vxd is set to Vxd(1) and the frequency of the laser beam B is set to fc(1). If the constant velocity distance Lsc is more than Lsc(1) and less than or equal to Lsc(2), the processing velocity Vxd is set to Vxd(2) and the frequency of the laser beam B is set to fc(2).

That is, in the laser processing condition determination of FIG. 21, the length (constant velocity distance Lsc) of the constant velocity zone SC set for the planned dividing line S to be line processed is obtained (Step S1201). Then, the processing velocity Vxd is determined (Step S1202) and the frequency fc of the laser beam B is determined (Step S1203) based on the constant velocity distance Lsc obtained in Step S1201 and the table of FIG. 22C. The irradiation position scan is performed according to the laser processing conditions (processing velocity Vxd and frequency fc) determined by FIG. 21 in this way.

The irradiation position scan is performed in turn for the plurality of planned dividing lines S parallel to the X direction. In other words, a plurality of the irradiation position scans are performed for the planned dividing lines S different from each other. In contrast, the laser processing condition determination of FIG. 21 is performed for each of the plurality of irradiation position scans. In each irradiation position scan, bthe laser irradiation position Lb is moved and the laser beam B is irradiated according to the laser processing conditions determined for each irradiation position scan.

Particularly, if the semiconductor substrate W formed with the plurality of planned dividing lines S parallel to the X direction is circular as in the above example, the further from a center of a circle in the Y direction, the shorter the planned dividing line S becomes, and shorter the constant velocity distance Lsc set for the planned dividing line S also becomes. That is, the constant velocity distance Lsc set for the irradiation position scan differs depending on the position in the Y direction of the planned dividing line S, for which the irradiation position scan is performed. Accordingly, it is proper to perform the laser processing condition determination for each irradiation position scan performed in turn for the plurality of planned dividing lines S.

Note that the laser processing condition determination can be performed at an arbitrary timing before the start of the irradiation position scan which is a target of the laser processing condition determination. For example, the laser processing condition determination may be performed for all of the plurality of irradiation position scans before the plurality of irradiation position scans respectively corresponding to the plurality of planned dividing lines S parallel to the X direction are started. Alternatively, in the case of performing the next irradiation position scan following one irradiation position scan, the laser processing condition determination may be performed for the next irradiation position scan during the execution of the one irradiation position scan.

Note that, as shown in FIG. 22C, the processing velocity Vxd is adjusted by selecting one, out of a plurality of discrete processing velocities Vxd(1), Vxd(2), Vxd(3) and Vxd(4), and the oscillation frequency fc is adjusted by selecting one, out of a plurality of discrete oscillation frequencies fc(1), fc(2), fc(3) and fc(4). That is, in the laser processing condition determination, the processing velocity Vxd and the oscillation frequency fc are selected based on to which of a plurality of (four) ranges shown in FIG. 22C the constant velocity distance Lsc belongs. At this time, if the ranges, to which the constant velocity distance Lsc belongs, are the same between two laser irradiation position scans successively performed when the processing velocity Vxd and the oscillation frequency fc are adjusted by performing the laser processing condition determination for each of the plurality of irradiation position scans, the processing velocity Vxd and the oscillation frequency fc are maintained. On the other hand, if the ranges, to which the constant velocity distance Lsc belongs, are different between two laser irradiation position scans successively performed, the processing velocity Vxd and the oscillation frequency fc are changed (in other words, switched). That is, the adjustment of the processing velocity Vxd includes the maintaining of the processing velocity Vxd and the change (switch) of the processing velocity Vxd, and the adjustment of the oscillation frequency fc includes the maintaining of the oscillation frequency fc and the change (switch) of the oscillation frequency fc.

As just described, in the above embodiment, the laser processing apparatus 1 corresponds to an example of a “laser processing apparatus” of the disclosure, the chuck stage 3 corresponds to an example of a “supporting member” of the disclosure, the Y-axis driver 63 corresponds to an example of a “feeding-axis driver” of the disclosure, the X-axis driver 65 corresponds to an example of a “processing-axis driver” of the disclosure, the processing head 71 corresponds to an example of a “processing head” of the disclosure, the imaging part 8 corresponds to an example of an “imaging part” of the disclosure, the control unit 100 corresponds to an example of a “control unit” of the disclosure, the control unit 100 corresponds to an example of a “computer” of the disclosure, the laser processing program 191 corresponds to an example of a “laser processing program” of the disclosure, the recording medium 192 corresponds to an example of a “recording medium” of the disclosure, the laser beam B corresponds to an example of a “laser beam” of the disclosure, the laser irradiation position Lb corresponds to an example of a “laser irradiation position” of the disclosure, the imaging range Ri corresponds to an example of an “imaging range” of the disclosure, the planned dividing line S corresponds to an example of a “processing line” of the disclosure, the virtual straight line Sv corresponds to an example of a “virtual straight line” of the disclosure, the switching period Tc corresponds to an example of a “switching period” of the disclosure, the semiconductor substrate W corresponds to an example of a “processing object” of the disclosure, the X direction corresponds to an example of a “processing direction” of the disclosure, the Y direction corresponds to an example of a “feeding direction” of the disclosure, and the (+X) side and (−X) side correspond to examples of a “first side” and a “second side” of the disclosure or the “second side” and the “first side” of the disclosure.

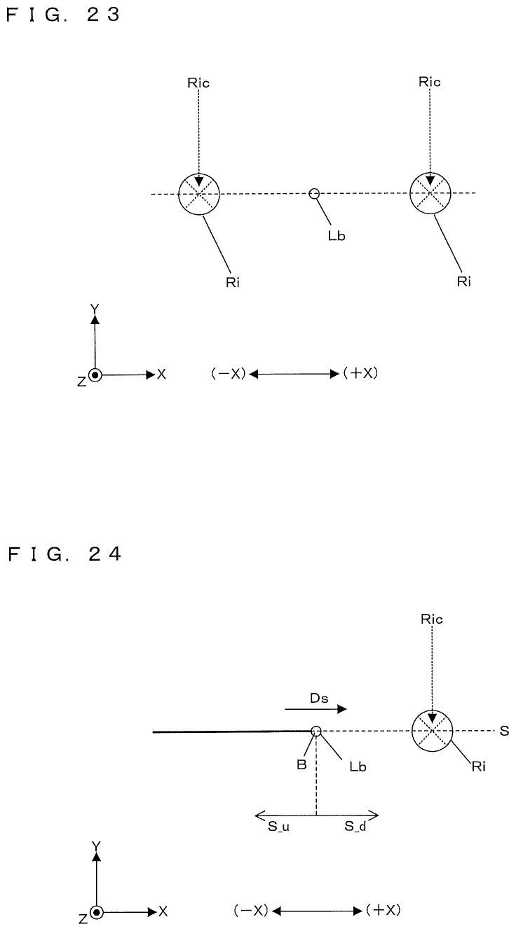

The detailed operation described using FIGS. 16 to 20 to image the imaging ranges Ri moving in the X direction according to the execution of the line processing by the infrared camera 81 may be modified as follows. FIG. 23 is a plan view schematically showing a positional relationship of the laser irradiation position and the imaging ranges in the detailed operation of imaging the imaging ranges, and FIG. 24 is a plan view schematically showing an imaging object in the detailed operation of imaging the imaging range.

As shown in FIG. 23, in the plan view, the imaging parts 8 (8A, 8B) and the processing head 71 are so arrayed in the X direction that centers Ric of the imaging ranges Ri of the imaging parts 8 (8A, 8B) and a focus (i.e. the laser irradiation position Lb) of the laser beam B irradiated by the processing head 71 are arranged in parallel to the X direction. Further, as described above, the imaging range Ri on the downstream side in the moving direction of the laser irradiation position Lb, out of the two imaging ranges Ri, is imaged by the infrared camera 81.

That is, as shown in FIG. 24, the laser beam B irradiated to the laser irradiation position Lb moves in a scanning direction Ds parallel to the X direction, and the imaging range Ri moves in the scanning direction Ds on the downstream side of the laser irradiation position Lb in the scanning direction Ds. Here, out of the planned dividing line S, a downstream side of the laser irradiation position Lb in the scanning direction Ds is an unprocessed part S_d not processed by the irradiation of the laser beam B, and an upstream side of the laser irradiation position Lb in the scanning direction Ds is a processed part S_u processed by the irradiation of the laser beam B. Therefore, the imaging range Ri on the downstream side of the laser irradiation position Lb in the scanning direction Ds includes the unprocessed part S_d of the planned dividing line S, and the laser processing control calculator 120 (control unit) can obtain the image IM of the unprocessed part S_d of the planned dividing line S by imaging this imaging range Ri.

Particularly, the laser processing control calculator 120 causes the infrared camera 81 to perform exposure through a period (crossing period) during which the planned dividing line S crosses the imaging range Ri on the downstream side (in other words, the unprocessed part S_d) of the laser irradiation position Lb in the scanning direction Ds (panning operation). Here, that the planned dividing line S crosses the imaging range Ri indicates a state where the both ends of the planned dividing line S are located outside the imaging range Ri while the planned dividing line S is overlapping the imaging range Ri.

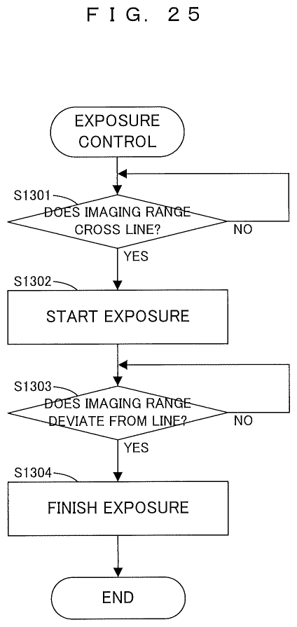

FIG. 25 is a flow chart showing an example of a camera exposure control. The flow chart of FIG. 25 is performed by the laser processing control calculator 120 controlling the infrared camera 81 via the camera controller 122A, 122B, and performed in parallel with the line processing for the planned dividing line S. In Step S1301, it is judged whether or not the planned dividing line S (i.e. the unprocessed part S_d of the planned dividing line S) has crossed the imaging range Ri on the downstream side in the scanning direction Ds (referred to as a “downstream imaging range Ri” as appropriate), out of the two imaging ranges Ri of the two infrared cameras 81.

At a timing at which the planned dividing line S crosses the downstream imaging range Ri (“YES” in Step S1301), the infrared camera 81 imaging the downstream imaging range Ri starts exposure (Step S1302). In Step S1303, it is judged whether or not the downstream imaging range Ri has deviated from the unprocessed part S_d of the planned dividing line S, i.e. is no longer crossed. At a timing at which the downstream imaging range Ri deviates from the unprocessed part S_d of the planned dividing line S (“YES” in Step S1303), the exposure of the infrared camera 81 imaging this imaging range Ri is finished (Step S1304).

As just described, the imaging range Ri moving in the scanning direction Ds according to a movement of the laser irradiation position Lb is imaged by the infrared camera 81. Particularly, the exposure of the infrared camera 81 imaging this imaging range Ri is continued through the crossing period (period of Steps S1301 to S303) during which the imaging range Ri is crossing the planned dividing line S on the downstream side of the laser irradiation position Lb in the scanning direction Ds. Therefore, the image IM having accumulated light from the imaging range Ri through the crossing period (referred to as a “panned image” as appropriate) is obtained. Specifically, the infrared camera 81 obtains the panned image IM by accumulating light (infrared rays) detected by a built-in solid-state imaging element. Note that, a period during which the exposure is continued coincides with the crossing period in this example, but may be, for example, a period including the crossing period and longer than the crossing period.

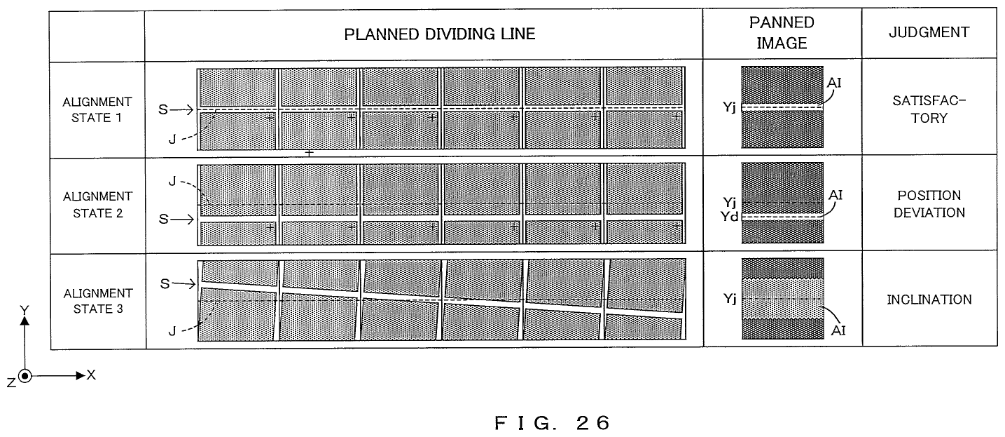

FIG. 26 is a table schematically showing information obtainable from panned images captured by the panning operation. In FIG. 26, the planned dividing line S, the panned image IM obtained by imaging the planned dividing line S with the panning operation and the information (determination) obtainable from the panned image IM are associated and shown about each of three alignment states 1 to 3 different from each other. Further, in FIG. 26, a trace J of the laser irradiation position Lb relatively moving in the X direction with respect to the semiconductor substrate W (in other words, a trace J of the center Ric of the imaging range Ri) is shown by broken line. Particularly, a cumulative line image AI obtained by accumulating the light from the planned dividing line S appears in the image IM, and information is obtained based on this cumulative line image AI.

In the alignment state 1, the planned dividing line S is parallel to the X direction and coincides with the trace J. Thus, in the panned image IM, the cumulative line image AI extends in parallel to the X direction at a position Yj (Y-coordinate) of the trace J in the Y direction and has a narrow width (width in the Y direction) and a high luminance. It can be determined from such a cumulative line image AI that the position of the planned dividing line S is satisfactory.

In the alignment state 2, the planned dividing line S deviates from the trace J in the Y direction while being parallel to the X direction. Thus, in the panned image IM, the cumulative line image AI extends in the X direction at a position Yd deviated from a position Yj of the trace J in the Y direction and has a narrow width and a high luminance. It can be determined from such a cumulative line image AI that a position deviation having a deviation amount (Yd−Yj) in the Y direction has occurred between the planned dividing line S and the trace J.

In the alignment state 3, the planned dividing line S extends obliquely to the X direction. Thus, the cumulative line image AI has a thick width and a low luminance in the image IM. It can be determined from such a cumulative line image AI that the planned dividing line S is inclined with respect to the trace J.

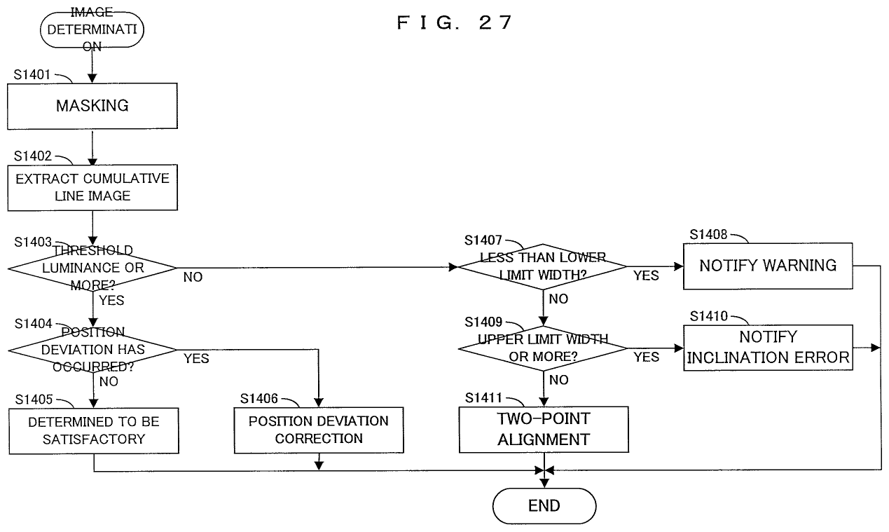

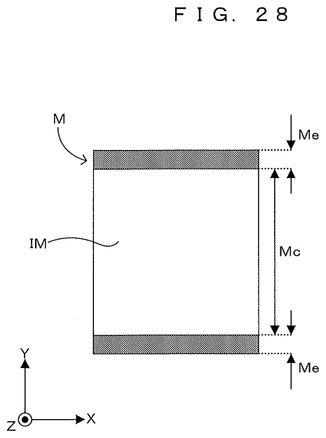

Based on such a knowledge, the laser processing control calculator 120 makes determination shown in FIG. 27 for the panned image IM. FIG. 27 is a flow chart showing an example of image determination performed for the panned image, and FIG. 28 is a diagram schematically showing a mask used in the image determination of FIG. 27.

In Step S1401, masking is performed for the panned image IM. A mask M (FIG. 28) used in the masking functions to conceal end parts Me on both sides of the panned image IM in the Y direction and extract a central part Mc between these end parts Me. The end parts Me extend in parallel to the X direction, and the central part Mc has a rectangular shape. In Step S1402, the cumulative line image AI is extracted from the central part Mc, out of the panned image IM. Specifically, the cumulative line image AI can be extracted by binarizing each pixel value (luminance) of the cumulative line image AI by a predetermined threshold. Further, image processings such as closing and opening may be performed in combination as appropriate.

In Step S1403, it is judged whether or not the luminance (e.g. an average or median value of the luminance) of the cumulative line image AI is equal to or more than a threshold luminance. If the luminance of the cumulative line image AI is equal to or more than the threshold luminance (“YES” in Step S1403), the panned image IM can be estimated to fall under a processing result 1 or 2, out of the alignment states 1 to 3 shown in FIG. 26.

Accordingly, in Step S1404, it is judged whether or not a position deviation has occurred between the position Yj of the trace J and the cumulative line image AI in the Y direction. Specifically, no position deviation is judged to have occurred (NO) if a distance between the position Yj of the trace J and the cumulative line image AI in the Y direction is less than a threshold distance, whereas a position deviation is judged to have occurred (YES) if this distance is equal to or more than the threshold distance. If no position deviation has occurred (“NO” in Step S1404), it is determined to be satisfactory (Step S1405) and the line processing for the semiconductor substrate W is continued.

In contrast, if the position deviation has occurred (“YES” in Step S1404), the position of the planned dividing line S with respect to the trace J of the laser irradiation position Lb is corrected (position deviation correction) in the line processing performed after the line processing performed in parallel with the imaging of the panned image IM. Specifically, the planned dividing line S to be line processed after the planned dividing line S (imaged planned dividing line S) imaged in the panned image IM and the position of the laser irradiation position Lb are corrected in the Y direction by a position deviation amount (=Yd−Yj) in the Y direction. With the position deviation corrected in this way, the line processing for this planned dividing line S is started. In this way, the line processing for this planned dividing line S can be started by the laser irradiation position Lb located at a proper position in the Y direction. Note that, if the position deviation correction is too late for the next planned dividing line S to be line processed after the imaged planned dividing line S, the position deviation correction may be performed for the planned dividing line S to be line processed after the next planned dividing line S.

If the luminance of the cumulative line image AI is less than the threshold luminance in Step S1403 (“NO” in Step S1403), the panned image IM can be estimated to fall under the alignment state 3, out of the alignment states 1 to 3 illustrated in FIG. 26. Accordingly, in Step S1407, it is judged whether or not the width in the Y direction of the cumulative line image AI is less than a lower limit width. If the width of the cumulative line image AI is less than the lower limit width (“YES” in Step S1407), an abnormality different from each alignment state shown in FIG. 26 is thought to have occurred. Thus, the laser processing control calculator 120 notifies a warning to a user by means of a display or a buzzer (Step S1408).

On the other hand, if the width of the cumulative line image AI is equal to or more than the lower limit width (“NO” in Step S1407), the planned dividing line S is estimated to be inclined with respect to the trace J of the laser irradiation position Lb as illustrated in the alignment state 3. Accordingly, in Step S1409, it is judged whether or not the width in the Y direction of the cumulative line image AI is equal to or more than an upper limit width. If the width of the cumulative line image AI is equal to or more than the upper limit width (“YES” in Step S1409), the inclination of the laser irradiation line G is excessive. Thus, the laser processing control calculator 120 notifies an inclination error to the user by means of the display or the buzzer (Step S1410).

In contrast, if the width of the cumulative line image AI is less than the upper limit width (“NO” in Step S1409), two-point alignment is performed (Step S1411). In this two-point alignment, the positions (X-coordinates, Y-coordinates) of predetermined two points on the semiconductor substrate W are calculated based on a result of imaging these two points by the infrared camera 81. Further, an angle deviation of the semiconductor substrate W in the θ direction is calculated based on the positions of these two points, and a rotation angle of the semiconductor substrate W in the θ direction is adjusted based on this angle deviation. In this way, the planned dividing line S of the semiconductor substrate W is adjusted to be parallel to the X direction.

As just described, in the modification described above, the center Ric of the imaging range Ri of the imaging part 8 and the focus of the laser beam B irradiated to the laser irradiation position Lb are arranged in the X direction. Therefore, a state immediately before the laser beam B is irradiated can be precisely grasped by the image IM of the imaging range Ri.

Further, during the execution of the line processing for one planned dividing line S (target line), out of the plurality of planned dividing lines S, the imaging part 8 obtains the image IM by whole period imaging (panning operation) for causing the infrared camera 81 to continue exposure through the period during which the unprocessed part S_d of this one planned dividing line S is crossing the imaging range Ri. In such a configuration, the information (cumulative line image AI) obtained by accumulating the luminance of the image IM of the imaging range Ri in the X direction can be obtained.

In such a panned image, the accumulated luminance may reach a dynamic range of the infrared camera 81 (solid-state imaging element) and the luminance of the image IM may saturate. Accordingly, the imaging part 8 adjusts an illumination intensity of light to be irradiated to the imaging range Ri from this imaging part 8. Specifically, an illumination intensity Lc is so adjusted that an exposure time Tc and the illumination intensity Lc in the panning operation satisfy the following relational expression for an exposure time TO and an illumination intensity L0 in still imaging for imaging the semiconductor substrate W by the infrared camera 81 with the infrared camera 81 kept stationary with respect to the semiconductor substrate W:

Lc=T0×L0/Tc.

In this way, the luminance saturation of the image IM can be suppressed.

Further, it is determined whether or not the laser irradiation position Lb relative to the planned dividing line S is proper based on the panned image IM obtained by the panning operation (whole period imaging) (FIG. 27). In such a configuration, whether or not the laser irradiation position Lb is proper can be confirmed based on the panned image IM.

Further, the laser processing control calculator 120 determines whether or not the laser irradiation position Lb relative to the planned dividing line S is proper based on the central part Mc except the both end parts Me in the Y direction (orthogonal direction), out of the panned image IM. In such a configuration, whether or not the laser irradiation position Lb is proper can be confirmed with unnecessary information appearing in the both end parts Me in the Y direction of the panned image IM excluded.

Further, the laser processing control calculator 120 obtains the position deviation amount (Yd−Yj) in the Y direction of the laser irradiation position Lb from one planned dividing line S and corrects the laser irradiation position Lb based on the position deviation amount (Yd−Ys) when the line processing is performed after the line processing for the one planned dividing line S (Step S1406) if the occurrence of the position deviation in the Y direction of the laser irradiation position Lb from the one planned dividing line S (target line) is confirmed based on the panned image IM (“YES” in Step S1404). In this way, the position deviation of the laser irradiation position Lb can be corrected in the Y direction and the line processing can be properly performed.

Further, the laser processing control calculator 120 performs the alignment to correct the inclination (Step S1411) if the inclination of the trace J of the laser irradiation position Lb with respect to one planned dividing line S (target line) is confirmed based on the panned image IM. In such a configuration, the line processing can be properly performed by correcting the inclination of the laser irradiation position Lb with respect to the planned dividing line S.

Note that the disclosure is not limited to the above embodiment and various changes can be made for the aforementioned embodiment without departing from the gist of the disclosure. Specifically, the following changes can be made.

Further, although the imaging part 8 images the intersection of the two planned dividing lines S orthogonal to each other in the above examples, an object to be imaged by the imaging part 8 is not limited to this and may be, for example, an alignment mark or the like attached to the semiconductor chip C.

Further, the specific configuration for relatively moving the laser irradiation position Lb with respect to the semiconductor substrate W is not limited to the XYθ drive table 6 and may be, for example, a driving mechanism for driving the processing head 71 in the X direction and the Y direction.

Further, the number of the imaging parts 8 is not limited to two and may be, for example, one.

Further, the individually separated semiconductor chips C may be manufactured by the laser processing method (substrate processing of FIG. 11 or the like) described above (semiconductor chip manufacturing method). In this semiconductor chip manufacturing method, a modified layer is formed by performing the line processing for the planned dividing lines S of the semiconductor substrate W by the above laser processing method (laser processing step). Subsequently, each of the plurality of semiconductor chips C is separated by stretching and expanding the tape E holding the semiconductor substrate W (expanding step).

What is claimed is:

1. A laser processing apparatus, comprising:
a supporting member configured to support a processing object having a plurality of processing lines parallel to each other such that the processing lines are parallel to a predetermined processing direction;
a processing head configured to irradiate a laser beam to a predetermined laser irradiation position;
a processing-axis driver configured to relatively move the laser irradiation position in the processing direction with respect to the processing object by driving at least one of the supporting member and the processing head in the processing direction;
a controller configured to perform a line processing of processing the processing line by irradiating the laser beam to the laser irradiation position by the processing head while moving the laser irradiation position along the processing line by the processing-axis driver; and
an imager configured to image predetermined imaging range relatively moving with respect to the processing object integrally with the laser irradiation position as the laser irradiation position relatively moves with respect to the processing object,
the imager being configured to obtain an image of a part of the processing object overlapping the imaging range by imaging the imaging range relatively moving with respect to the processing object during execution of the line processing.

2. The laser processing apparatus according to claim 1, wherein:
the imager is configured to image the imaging range provided on a downstream side in a moving direction of the laser irradiation position with respect to the processing line in the line processing.

3. The laser processing apparatus according to claim 1, wherein:
the imager is configured to image the imaging range a plurality of times during a period of performing the line processing once.

4. The laser processing apparatus according to claim 1, further comprising:
a feeding-axis driver configured to relatively move the laser irradiation position in a feeding direction orthogonal to the processing direction with respect to the processing object by driving at least one of the supporting member and the processing head in the feeding direction, wherein:
the processing line to be line processed, out of the plurality of processing lines, is changed by the feeding-axis driver moving the laser irradiation position in the feeding direction with respect to the processing object,
the controller is configured to perform in turn a first line processing of processing a first processing line, out of the plurality of processing lines, by the line processing of moving the laser irradiation position toward a first side in the processing direction and a second line processing of processing a second processing line different from the first processing line, out of the plurality of processing lines, by the line processing of moving the laser irradiation position toward a second side opposite to the first side in the processing direction,
the processing-axis driver is configured to perform reverse drive for bringing the laser irradiation position to the second processing line by accelerating the laser irradiation position toward the second side after decelerating and stopping the laser irradiation position, which has passed through the first processing line toward the first side, toward the first side in the processing direction and the feeding-axis driver performs continuous feed drive for continuously moving the laser irradiation position in the feeding direction from a first virtual straight line extended in the processing direction to outside of the first processing line along the first processing line to a second virtual straight line extended in the processing direction to outside of the second processing line along the second processing line in a switching period from end of the first line processing to start of the second line processing, and
the controller is configured to cause the feeding-axis driver to move the laser irradiation position in the feeding direction throughout the before and after the time at which a movement of the laser irradiation position in the processing direction is stopped due to the reverse drive by controlling the processing-axis driver and the feeding-axis driver such that the feeding-axis driver starts the continuous feed drive before the processing-axis driver stops the laser irradiation position by the reverse drive and the feeding-axis driver finishes the continuous feed drive after the processing-axis driver stops the laser irradiation position by the reverse drive.

5. The laser processing apparatus according to claim 1, wherein
the imager is configured to image the imaging range including at least the processing line during the execution of the line processing.

6. The laser processing apparatus according to claim 1, wherein:
a center of the imaging range of the imager and a focus of the laser beam to be irradiated to the laser irradiation position are arranged in the processing direction.

7. The laser processing apparatus according to claim 6, wherein:
the imager is configured to obtain the image by whole period imaging for causing a camera to continue exposure through a crossing period during which an unprocessed part not processed with irradiation of the laser beam in one target line crosses the imaging range during the execution of the line processing for the one target line, out of the plurality of processing lines.

8. The laser processing apparatus according to claim 7, wherein:
an exposure time Tc and an illumination intensity Lc in the whole period imaging satisfy the following relational expression for an exposure time T0 and an illumination intensity L0 when the camera images the processing object stationary with respect to the camera:
Lc=T0×L0/Tc.

9. The laser processing apparatus according to claim 7, wherein:
the controller is configured to determine whether or not the laser irradiation position for the processing line is proper based on the image obtained by the whole period imaging.

10. The laser processing apparatus according to claim 9, wherein:
the controller is configured to determine whether or not the laser irradiation position for the processing line is proper based on a central part of the image except both end parts in an orthogonal direction orthogonal to the processing direction.

11. The laser processing apparatus according to claim 9, wherein:
if an occurrence of a position deviation of the laser irradiation position from the one target line in an orthogonal direction orthogonal to the processing direction is confirmed based on the image, the controller is configured to obtain a position deviation amount in the orthogonal direction of the laser irradiation position from the one target line and correct the laser irradiation position in the orthogonal direction based on the position deviation amount when the line processing is performed after the one target line.

12. The laser processing apparatus according to claim 9, wherein:
if inclination of a trace of the laser irradiation position with respect to the one target line is confirmed based on the image, the controller is configured to perform an alignment of correcting the inclination.

13. A laser processing method, comprising:
supporting a processing object having a plurality of processing lines parallel to each other by a supporting member such that the processing lines are parallel to a predetermined processing direction;
performing a line processing of processing the processing line by irradiating a laser beam to a laser irradiation position by a processing head for irradiating the laser beam to a predetermined laser irradiation position while moving the laser irradiation position along the processing line by a processing-axis driver for relatively moving the laser irradiation position in the processing direction with respect to the processing object by driving at least one of the processing head and the supporting member in the processing direction; and
obtaining an image of a part of the processing object overlapping an imaging range by an imaging part imaging the imaging range relatively moving with respect to the processing object during execution of the line processing, the imaging part imaging a predetermined imaging range relatively moving with respect to the processing object integrally with the laser irradiation position as the laser irradiation position relatively moves with respect to the processing object.

14. A non-transitory computer readable medium of instructions storing a laser processing program for causing a computer to carry out the laser processing method according to claim 13.

15. (canceled)

16. A semiconductor chip manufacturing method, comprising:
processing a semiconductor substrate, having a plurality of semiconductor chips demarcated by processing lines and arrayed in the semiconductor substrate, by the laser processing method according to claim 13; and
separating each of the plurality of semiconductor chips by expanding a tape holding the semiconductor substrate by an adhesive force, processed by the laser processing method.

17. A semiconductor chip, manufactured by:
processing a semiconductor substrate, having a plurality of semiconductor chips demarcated by processing lines and arrayed in the semiconductor substrate, by the laser processing method according to claim 13; and
separating each of the plurality of semiconductor chips by expanding a tape holding the semiconductor substrate by an adhesive force, processed by the laser processing method.

18. The laser processing apparatus according to claim 2, wherein:
the imager is configured to image the imaging range a plurality of times during a period of performing the line processing once.

19. The laser processing apparatus according to claim 2, further comprising:
a feeding-axis driver configured to relatively move the laser irradiation position in a feeding direction orthogonal to the processing direction with respect to the processing object by driving at least one of the supporting member and the processing head in the feeding direction, wherein:
the processing line to be line processed, out of the plurality of processing lines, is changed by the feeding-axis driver moving the laser irradiation position in the feeding direction with respect to the processing object,
the controller is configured to perform in turn a first line processing of processing a first processing line, out of the plurality of processing lines, by the line processing of moving the laser irradiation position toward a first side in the processing direction and a second line processing of processing a second processing line different from the first processing line, out of the plurality of processing lines, by the line processing of moving the laser irradiation position toward a second side opposite to the first side in the processing direction,
the processing-axis driver is configured to perform reverse drive for bringing the laser irradiation position to the second processing line by accelerating the laser irradiation position toward the second side after decelerating and stopping the laser irradiation position, which has passed through the first processing line toward the first side, toward the first side in the processing direction and the feeding-axis driver performs continuous feed drive for continuously moving the laser irradiation position in the feeding direction from a first virtual straight line extended in the processing direction to outside of the first processing line along the first processing line to a second virtual straight line extended in the processing direction to outside of the second processing line along the second processing line in a switching period from end of the first line processing to start of the second line processing, and
the controller is configured to cause the feeding-axis driver to move the laser irradiation position in the feeding direction throughout the before and after the time at which a movement of the laser irradiation position in the processing direction is stopped due to the reverse drive by controlling the processing-axis driver and the feeding-axis driver such that the feeding-axis driver starts the continuous feed drive before the processing-axis driver stops the laser irradiation position by the reverse drive and the feeding-axis driver finishes the continuous feed drive after the processing-axis driver stops the laser irradiation position by the reverse drive.

20. The laser processing apparatus according to claim 2, wherein
the imager is configured to image the imaging range including at least the processing line during the execution of the line processing.
